(19) United States
(12) Patent Application Publication
(10) Pub. No.: US 2023/0225209 A1
(43) Pub. Date: Jul. 13, 2023

(54) ORGANIC ELECTROLUMINESCENT DEVICE AND DISPLAY APPARATUS

(71) Applicant: KUNSHAN GO-VISIONOX OPTO-ELECTRONICS CO., LTD, Kunshan (CN)

(72) Inventors: Guomeng LI, Kunshan (CN); Yuewei ZHANG, Kunshan (CN); Mengzhen LI, Kunshan (CN); Chunliang YAO, Kunshan (CN); Bin LIU, Kunshan (CN); Jin XU, Kunshan (CN)

(73) Assignee: KUNSHAN GO-VISIONOX OPTO-ELECTRONICS CO., LTD, Kunshan (CN)

(21) Appl. No.: 18/187,225

(22) Filed: Mar. 21, 2023

Related U.S. Application Data
(63) Continuation of application No. PCT/CN2021/115212, filed on Aug. 30, 2021.

(30) Foreign Application Priority Data
Dec. 15, 2020 (CN) 202011480750.5

(51) Int. Cl. H10K 85/60; C09K 11/06

(52) U.S. Cl. CPC H10K 85/658; C09K 11/06; H10K 85/654; H10K 85/6572; C09K 2211/1014; H10K 50/121

(57) ABSTRACT

An organic electroluminescent device and a display apparatus. The organic electroluminescent device includes a first electrode, a second electrode and an organic layer disposed between the first electrode and the second electrode, where the organic layer includes an emission layer (EML), the EML includes a host material, a thermally activated delayed fluorescence (TADF) sensitizer and a fluorescent dye, and the fluorescent dye is selected from a compound represented by Formula (1).

### CROSS-REFERENCE TO RELATED APPLICATION

This is a continuation of International Patent Application NO. PCT/CN2021/115212, filed on Aug. 30, 2021, which claims priority to a Chinese patent application No. 202011480750.5 filed on Dec. 15, 2020, disclosure of which is incorporated herein by reference in its entirety.

### TECHNICAL FIELD

The present disclosure relates to the technical field of organic electroluminescence and, in particular, to an organic electroluminescent device and a display apparatus.

### BACKGROUND

Thermally activated sensitized fluorescence (TASF) means that when a thermally activated delayed fluorescence (TADF) material is used as a sensitizer, the energy of a host material is transferred to the TADF material, and the triplet energy of the TADF material is returned to the singlet through a reverse intersystem crossing (RISC) process, thereby transferring the energy to a doped fluorescent dye to emit light. In this manner, the complete energy transfer from the host material to dye molecules can be achieved so that a traditional fluorescent doped dye can also break through the internal quantum efficiency limit of 25%.

However, in a TASF light-emitting device, there often exists a problem of serious dye carrier capture, and a relatively high drive voltage, serious efficiency roll-off and a relatively short service life of the device.

Therefore, it is urgent to develop a new TASF device in the art, which reduces the drive voltage and improves the device efficiency and the service life.

### SUMMARY

The present disclosure provides an organic electroluminescent device. The electroluminescent device has a relatively low drive voltage, relatively high device efficiency and a relatively long service life.

In an aspect, the present disclosure provides an organic electroluminescent device. The organic electroluminescent device comprises a first electrode, a second electrode and an organic layer disposed between the first electrode and the second electrode.

The organic layer comprises an emission layer (EML), the EML comprises a host material, a TADF sensitizer and a fluorescent dye, and the fluorescent dye is selected from a compound represented by Formula (1).

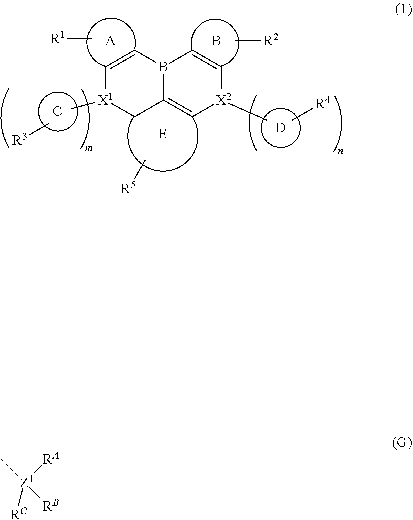

In the above Formula (1), the rings A, B, C, D and E each independently represent an aromatic ring or a heteroaromatic ring, and two adjacent rings are capable of being fused to form a five-membered ring or a six-membered ring containing X¹ or X²; X¹ and X² are each independently selected from one of O, S, N, C or Si; m is 0, 1 or 2, and n is 0, 1 or 2; and R¹, R², R³, R⁴ and R⁵ each independently represent from mono substitution to the maximum permissible substitution and are each independently selected from one or a combination of at least two of hydrogen, C₁ to C₁₀ chain alkyl, C₃ to C₁₀ cycloalkyl, C₁ to C₁₀ alkoxy, halogen, cyano, nitro, hydroxyl, ester, silicyl, amino, substituted or unsubstituted C₆ to C₃₀ arylamino, substituted or unsubstituted C₃ to C₃₀ heteroarylamino, substituted or unsubstituted C₆ to C₃₀ aryl or substituted or unsubstituted C₃ to C₃₀ heteroaryl, and at least one of R¹, R², R³, R⁴ or R⁵ is Formula (G).

In Formula (G), Z¹ is selected from C or Si; R^{A}, R^{B} and R^{C} are each independently selected from one of C₁ to C₁₀ chain alkyl, C₃ to C₁₀ cycloalkyl, substituted or unsubstituted C₆ to C₃₀ aryl or substituted or unsubstituted C₃ to C₃₀ heteroaryl; at least one of R^{A}, R^{B} or R^{C} is substituted or unsubstituted C₆ to C₃₀ aryl or substituted or unsubstituted C₃ to C₃₀ heteroaryl, and at least one of R^{A}, R^{B} or R^{C} is C₁ to C₁₀ chain alkyl or C₃ to C₁₀ cycloalkyl.

When a substituent is present in the above groups, the substituent is selected from one or a combination of at least two of halogen, cyano, carboxy, C₁ to C₁₂ alkyl, C₃ to C₁₂ cycloalkyl, C₂ to C₁₀ alkenyl, C₁ to C₆ alkoxy or thioalkoxy, C₆ to C₃₀ monocyclic aryl or fused-ring aryl or C₃ to C₃₀ monocyclic heteroaryl or fused-ring heteroaryl.

In an embodiment, the fluorescent dye is selected from a compound represented by Formula (2) below.

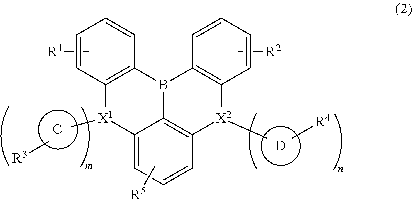

In Formula (2), the rings C, D, X¹, X², R¹, R², R³, R⁴, R⁵, m and n are defined the same as those in general Formula (1).

In an embodiment, the fluorescent dye is selected from a compound represented by Formula (3) below.

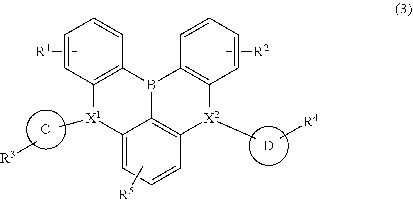

In Formula (3), the rings C, D, R², R³, R⁴, R⁵, m and n are defined the same as those in the general Formula (1), and X¹ and X² are each independently selected from O, S or N, and at least one of X¹ and X² is N.

In an embodiment, the fluorescent dye is selected from any one or a combination of at least two of the compounds represented by the following Formulas (I), (II), (III), (IV), (V), (VI), (VII) or (VIII):

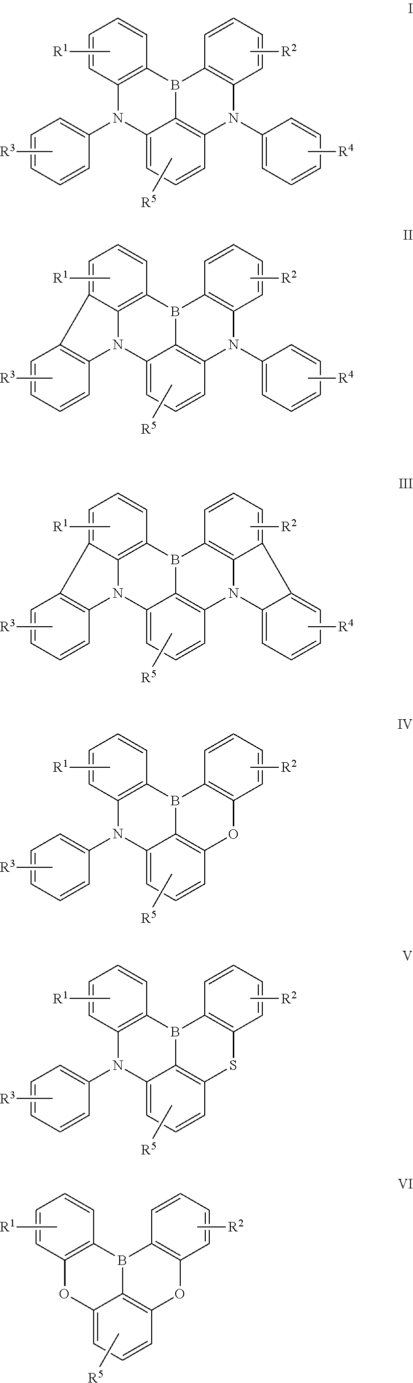

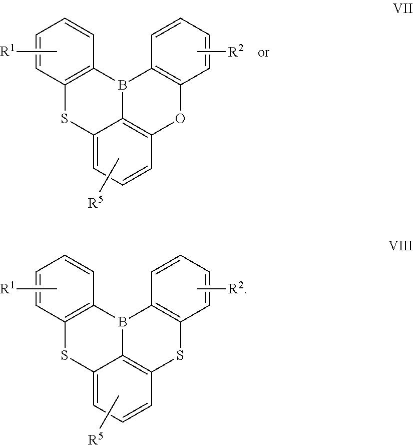

In Formulas (I), (II), (III), (IV), (V), (VI), (VII) and (VIII), R¹, R², R³, R⁴ and R⁵ are defined the same as those in the general Formula (1).

In an embodiment, the fluorescent dye is selected from any one or a combination of at least two of the compounds represented by Formulas (I), (II) or (III).

In an embodiment, Formula (G) is the following Formula (G1):

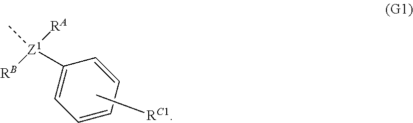

In Formula (G1), at least one of R^{A} and R^{B} is C₁ to C₁₀ chain alkyl or C₃ to C₁₀ cycloalkyl; and

R^{C1} is selected from one of hydrogen, C₁ to C₁₀ chain alkyl, C₃ to C₁₀ cycloalkyl, C₁ to C₁₀ alkoxy, substituted or unsubstituted C₆ to C₃₀ arylamino, substituted or unsubstituted C₃ to C₃₀ heteroarylamino, substituted or unsubstituted C₆ to C₃₀ aryl or substituted or unsubstituted C₃ to C₃₀ heteroaryl.

In an embodiment, Formula (G) is one of the following Formulas a, b, c or d:

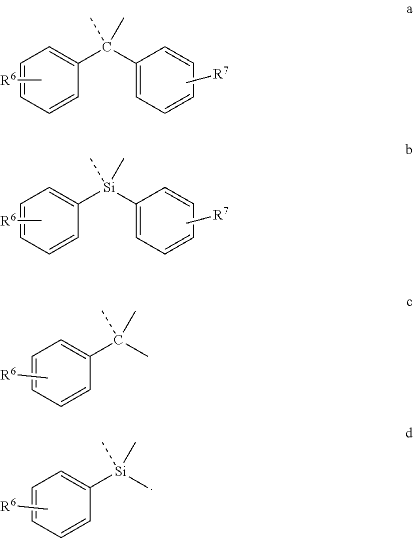

In Formulas a, b, c and d, R⁶ and R⁷ are each independently selected from one or a combination of at least two of hydrogen, deuterium, halogen, C₁ to C₁₀ chain alkyl or C₃ to C₁₀ cycloalkyl.

In another aspect, the present disclosure provides a display apparatus. The display apparatus comprises the organic electroluminescent device according to one of the objects.

Compared with the existing art, the present disclosure has the beneficial effects described below.

The present disclosure provides a new TASF device using the compound represented by Formula (1) as the fluorescent dye. A boron atom contained in the fluorescent dye has a resonance effect with O, S, N, C or Si atoms in the same ring so that the fluorescent dye has characteristics of a narrow spectrum and TADF emission. In addition, the fluorescent dye contains a substitution of a quaternary carbon or quaternary silicon group, and it is ensured that the group has at least one alkyl, so that while the transmission capability is ensured, the molecular spacing can be further increased, the quenching caused by the stacking can be suppressed, the efficiency roll-off can be further reduced, and the device service life can be prolonged. In the present disclosure, the fluorescent dye having the specific structure is used in combination with the host material and the sensitizer to form the EML so that the TASF device can have relatively high efficiency, a relatively long service life and a relatively low drive voltage.

### BRIEF DESCRIPTION OF THE DRAWINGS

FIG. 1 is a structure diagram of an organic electroluminescent device according to an embodiment and a comparative example of the present disclosure.

FIG. 2 is a graph illustrating a comparison of external quantum efficiency-brightness between devices of embodiment three and comparative example two.

FIG. 3 is a graph illustrating brightness decay of devices of embodiment three and comparative example two at a brightness of 1000 cd/m².

### DETAILED DESCRIPTION

For ease of understanding the present disclosure, embodiments of the present disclosure are listed below. Those skilled in the art are to understand that the embodiments described herein are merely used for understanding the present disclosure and are not to be construed as specific limitations to the present disclosure.

At present, in a TADF electroluminescent device, there often exists a problem of serious dye carrier capture, and a relatively high drive voltage, serious efficiency roll-off and a relatively short service life of the device. Through researches, the inventors have found that one of the main reasons for the above problems is that in an EML of the device, an energy gap of a host material and an energy gap of a sensitizer material are each greater than that of a fluorescent dye, resulting in certain problems of carrier capture and quenching of the fluorescent dye itself.

To solve the problems, the present disclosure provides an organic electroluminescent device. The organic electroluminescent device comprises a first electrode, a second electrode and an organic layer disposed between the first electrode and the second electrode.

The organic layer comprises an EML, the EML comprises a host material, a TADF sensitizer and a fluorescent dye, and the fluorescent dye is selected from a compound represented by Formula (1).

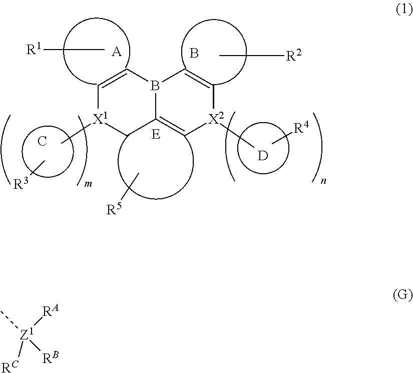

In the above Formula (1), the rings A, B, C, D and E each independently represent an aromatic ring or a heteroaromatic ring, and two adjacent rings are capable of being fused to form a five-membered ring or a six-membered ring containing X¹ or X²; X¹ and X² are each independently selected from one of O, S, N, C or Si; m is 0, 1 or 2, and n is 0, 1 or 2; and R¹, R², R³, R⁴ and R⁵ each independently represent from mono substitution to the maximum permissible substitution and are each independently selected from one or a combination of at least two of hydrogen, C₁ to C₁₀ chain alkyl, C₃ to C₁₀ cycloalkyl, C₁ to C₁₀ alkoxy, halogen, cyano, nitro, hydroxyl, ester, silicyl, amino, substituted or unsubstituted C₆ to C₃₀ arylamino, substituted or unsubstituted C₃ to C₃₀ heteroarylamino, substituted or unsubstituted C₆ to C₃₀ aryl or substituted or unsubstituted C₃ to C₃₀ heteroaryl, and at least one of R¹, R², R³, R⁴ and R⁵ is Formula (G).

In Formula (G), Z¹ is selected from C or Si; R^{A}, R^{B} and R^{C} are each independently selected from one of C₁ to C₁₀ chain alkyl, C₃ to C₁₀ cycloalkyl, substituted or unsubstituted C₆ to C₃₀ aryl or substituted or unsubstituted C₃ to C₃₀ heteroaryl, at least one of R^{A}, R^{B} and R^{C} is substituted or unsubstituted C₆ to C₃₀ aryl or substituted or unsubstituted C₃ to C₃₀ heteroaryl, and at least one of R^{A}, R^{B} and R^{C} is C₁ to C₁₀ chain alkyl or C₃ to C₁₀ cycloalkyl.

When a substituent is present in the above groups R^{A}, R^{B} and R^{C}, the substituent is selected from one or a combination of at least two of halogen, cyano, carboxy, C₁ to C₁₂ alkyl, C₃ to C₁₂ cycloalkyl, C₂ to C₁₀ alkenyl, C₁ to C₆ alkoxy or thioalkoxy, C₆ to C₃₀ monocyclic aryl or fused-ring aryl or C₃ to C₃₀ monocyclic heteroaryl or fused-ring heteroaryl.

In Formula (1), when X¹ is selected from O or S, m is 0; when X² is selected from O or S, n is 0.

It is to be noted that in the present disclosure, the maximum permissible substitution means that the number of substituents is the maximum number of substitutions on the premise that the substituted group satisfies a requirement for chemical bonds.

In the present disclosure, the expression of Ca to Cb represents that the number of carbon atoms in a backbone of the group is a to b, and unless otherwise specified, the number of carbon atoms generally does not comprise the number of carbon atoms in a substituent of the group.

In the present disclosure, the “substituted group” refers to a selection range of substituents when the “substituted or unsubstituted” group is substituted. The number of substituents is not specifically limited, as long as the requirement for compound bonds is satisfied. Exemplarily, the number of substituents is one, two, three, four or five, and when the number of substituents is two or more, the two or more substituents can be the same or different.

In the present disclosure, the expression of the ring structure crossed by “—” represents that a linkage site is at any position on the ring structure where the bonding can be formed.

In the present disclosure, substituted or unsubstituted C₆ to C₃₀ aryl is preferably C₆ to C₂₀ aryl, more preferably a group selected from the group consisting of phenyl, biphenyl, terphenyl, naphthyl, anthryl, phenanthryl, indenyl, fluorenyl and a derivative thereof, fluoranthenyl, triphenylene, pyrenyl, perylenyl, chrysenyl and naphthacenyl. Specifically, biphenyl is selected from 2-biphenyl, 3-biphenyl and 4-biphenyl; terphenyl comprises p-terphenyl-4-yl, p-terphenyl-3-yl, p-terphenyl-2-yl, m-terphenyl-4-yl, m-terphenyl-3-yl and m-terphenyl-2-yl; naphthyl comprises 1-naphthyl and 2-naphthyl; anthryl is selected from 1-anthryl, 2-anthryl and 9-anthryl; fluorenyl is selected from 1-fluorenyl, 2-fluorenyl, 3-fluorenyl, 4-fluorenyl and 9-fluorenyl; the fluorenyl derivative is selected from 9,9′-dimethylfluorene, 9,9′-spirobifluorene and benzofluorene; pyrenyl is selected from 1-pyrenyl, 2-pyrenyl and 4-pyrenyl; and naphthacenyl is selected from 1-naphthacenyl, 2-naphthacenyl and 9-naphthacenyl.

The heteroatom described in the present disclosure generally refers to an atom or an atomic group selected from N, O, S, P, Si and Se, preferably selected from N, O and S. The atomic name described in the present disclosure comprises various isotopes corresponding thereto, for example, hydrogen (H) comprises ¹H (protium or H), ²H (deuterium or D) and the like; and carbon (C) comprises ¹²C, ¹³C and the like.

In the present disclosure, substituted or unsubstituted C₃ to C₃₀ heteroaryl is preferably C₄ to C₂₀ heteroaryl, more preferably nitrogen-containing heteroaryl, oxygen-containing heteroaryl, sulfur-containing heteroaryl or the like, and in a specific example, the substituted or unsubstituted C₃ to C₃₀ heteroaryl comprises furanyl, thienyl, pyrrolyl, benzofuranyl, benzothienyl, isobenzofuranyl, indolyl, dibenzofuranyl, dibenzothienyl and carbazolyl and a derivative thereof, where the carbazolyl derivative comprises 9-phenylcarbazole, 9-naphthylcarbazolebenzocarbazole, dibenzocarbazole or indolocarbazole.

In the present disclosure, the above C₁ to C₂₀ chain alkyl is preferably C₁ to C₁₀ chain alkyl, more preferably C₁ to C₆ chain alkyl, such as methyl, ethyl, n-propyl, n-butyl, n-hexyl, n-octyl, isopropyl, isobutyl and tert-butyl.

In the present disclosure, C₃ to C₁₂ cycloalkyl comprises monocycloalkyl and polycycloalkyl, preferably C₁ to C₁₀ alkyl and C₃ to C₁₀ cycloalkyl.

The present disclosure provides a new TASF device using the compound represented by Formula (1) as the fluorescent dye. A boron atom contained in the fluorescent dye has a resonance effect with O, S, N, C or Si atoms in the same ring so that the fluorescent dye has characteristics of a narrow spectrum and TADF emission. In addition, the fluorescent dye contains a substitution of a quaternary carbon or quaternary silicon group, and it is ensured that the group has at least one alkyl, so that while the transmission capability is ensured, the molecular spacing can be further increased, the quenching caused by the stacking can be suppressed, the efficiency roll-off can be further reduced, and the device service life can be prolonged. In the present disclosure, the fluorescent dye having the specific structure is used in combination with the host material and the sensitizer to form the EML so that the TASF device can have relatively high efficiency, a relatively long service life and a relatively low drive voltage.

In an optional embodiment, the ring A and the ring C are fused to form a five-membered ring or a six-membered ring containing X¹; or, the ring B and the ring D are fused to form a five-membered ring or a six-membered ring containing X². Alternatively, the ring A and the ring C are fused to form a five-membered ring or a six-membered ring containing X¹, and the ring B and the ring D are fused to form a five-membered ring or a six-membered ring containing X².

In an optional embodiment, the rings A, B, C, D and E are each independently selected from a five to eight-membered aryl ring or a five to eight-membered heteroaryl ring.

In an optional embodiment, the rings A, B, C, D and E are each independently selected from a six-membered aryl ring or a five-membered heteroaryl ring.

In an optional embodiment, the rings A, B, C, D and E are each independently selected from one of substituted or unsubstituted C₆ to C₃₀ aryl or substituted or unsubstituted C₃ to C₃₀ heteroaryl.

In an optional embodiment, the rings A, B, C, D and E are each independently selected from the following substituted or unsubstituted groups: a benzene ring, a furan ring, a thiophene ring, a naphthalene ring, a phenanthrene ring or a carbazole ring.

In an optional embodiment, the fluorescent dye is selected from a compound represented by Formula (2) below.

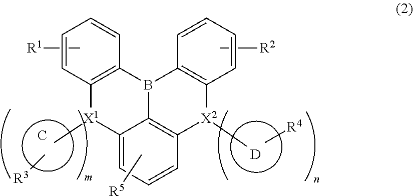

In Formula (2), the rings C, D, X¹, X², R¹, R², R³, R⁴, R⁵, m and n are defined the same as those in the general Formula (1).

In an embodiment, the fluorescent dye is selected from a compound represented by Formula (3) below.

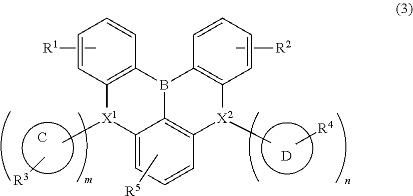

In Formula (3), the rings C, D, R², R³, R⁴, R⁵, m and n are defined the same as those in the general Formula (1), X¹ and X² are each independently selected from O, S or N, and at least one of X¹ and X² is N.

In an optional embodiment, the fluorescent dye is selected from any one or a combination of at least two of the compounds represented by the following Formulas (I), (II), (III), (IV), (V), (VI), (VII) or (VIII):

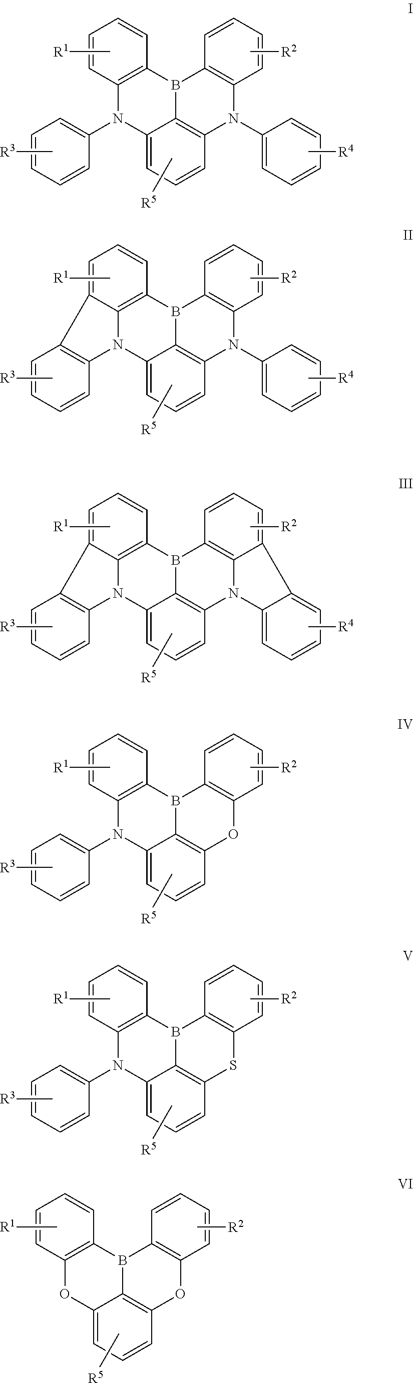

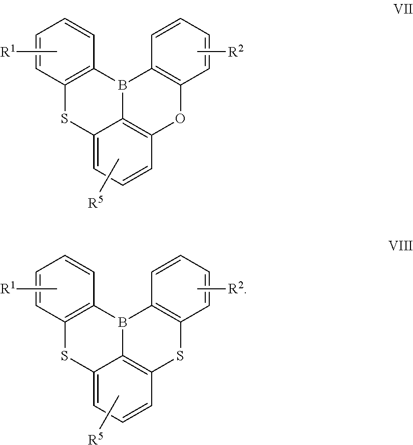

In the above Formulas (I), (II), (III), (IV), (V), (VI), (VII) and (VIII), R¹, R², R³, R⁴ and R⁵ are defined the same as those in the general Formula (1).

In an embodiment, the fluorescent dye is selected from any one or a combination of at least two of the compounds represented by Formulas (I), (II) or (III).

In the present disclosure, a parent nucleus of the fluorescent dye contain two N atoms, which form a B—N resonance structure with a B atom. The fluorescent dye having the structure has the characteristics of a narrower spectrum and more excellent TADF emission and can further improve the performance of the TASF device when used in combination with the host material and the sensitizer.

In an optional embodiment, Formula (G) is the following Formula (G1):

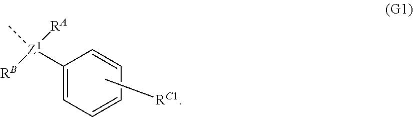

In Formula (G1), at least one of R^{A} or R^{B} is C₁ to C₁₀ chain alkyl or C₃ to C₁₀ cycloalkyl; and R^{C1} is selected from one of hydrogen, C₁ to C₁₀ chain alkyl, C₃ to C₁₀ cycloalkyl, C₁ to C₁₀ alkoxy, substituted or unsubstituted C₆ to C₃₀ arylamino, substituted or unsubstituted C₃ to C₃₀ heteroarylamino, substituted or unsubstituted C₆ to C₃₀ aryl, or substituted or unsubstituted C₃ to C₃₀ heteroaryl.

In the present disclosure, a substituent in the fluorescent dye contains at least one benzene ring. Such structure has a characteristic of improving steric hindrance and can further improve the performance of the TASF device when used in combination with the host material and the sensitizer.

In an optional embodiment, at least one of R^{A} or R^{B} is selected from methyl, ethyl, n-propyl, isopropyl, n-butyl, isobutyl, sec-butyl, tert-butyl, 2-methylbutyl, n-pentyl, sec-pentyl, cyclopentyl, neopentyl, n-hexyl, cyclohexyl, neohexyl, n-heptyl, cycloheptyl, n-octyl or cyclooctyl, and R^{C1} is selected from hydrogen, deuterium, methyl, ethyl, n-propyl, isopropyl, n-butyl, isobutyl, sec-butyl, phenyl, naphthyl, anthryl, thienyl, pyrrolyl, indolyl, carbazolyl or pyridyl.

In an optional embodiment, Formula (G) is one of the following Formulas a, b, c or d:

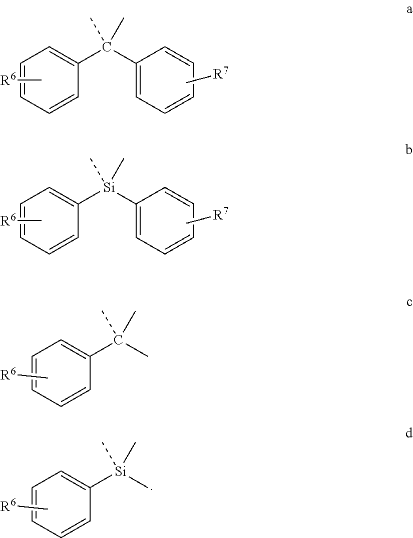

In the above Formulas a, b, c and d, R⁶ and R⁷ are each independently selected from one or a combination of at least two of hydrogen, deuterium, halogen, C₁ to C₁₀ chain alkyl or C₃ to C₁₀ cycloalkyl.

In an optional embodiment, Formula (G) is selected from Formula a or Formula c.

In the present disclosure, the fluorescent dye contains an aryl-substituted quaternary carbon group. The fluorescent dye having the structure has a moderate molecular weight and a moderate steric hindrance effect ability, and can further improve the performance of the device when used in combination with the host material and the sensitizer. In addition, the dye is not large in overall molecular weight after introduction, and is easy to evaporate.

In an optional embodiment, R⁶ and R⁷ are each independently selected from hydrogen, or each independently selected from one of the following groups:

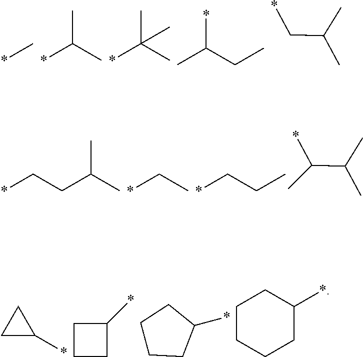

In an optional embodiment, R⁶ and R⁷ are each independently selected from hydrogen.

In an optional embodiment, R¹, R², R³, R⁴ and R⁵ are each independently selected from hydrogen, or each independently selected from one of the following groups:

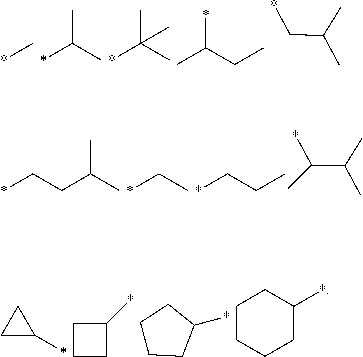

In an optional embodiment, the fluorescent dye is selected from any one or a combination of at least two of the following compounds M1 to M144:

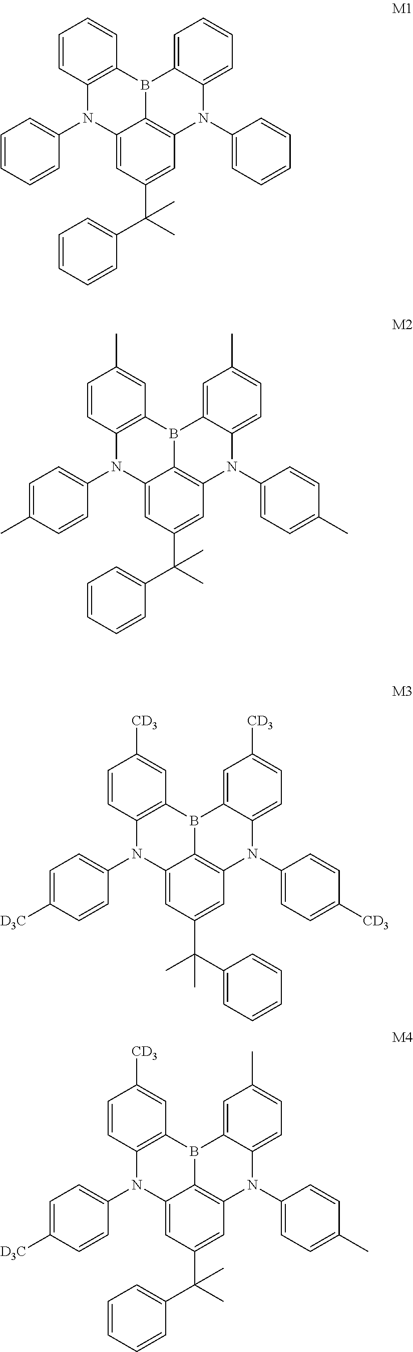

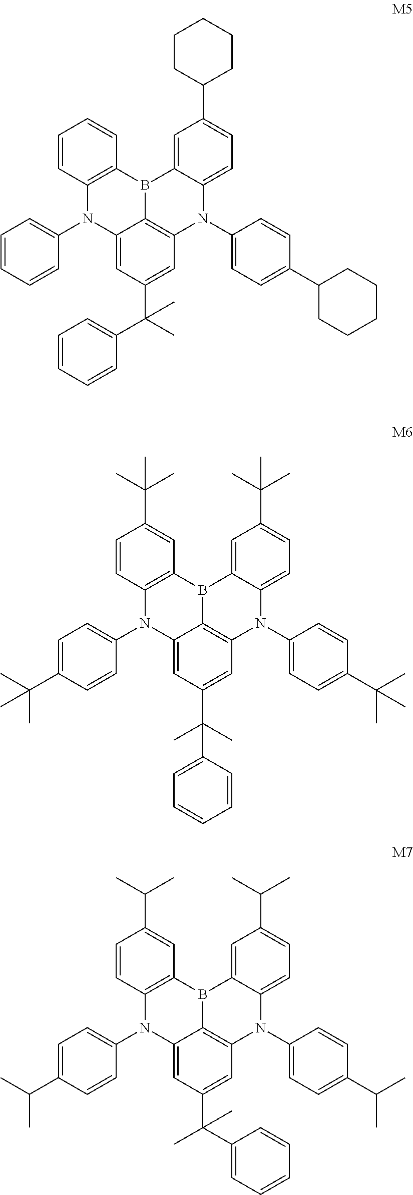

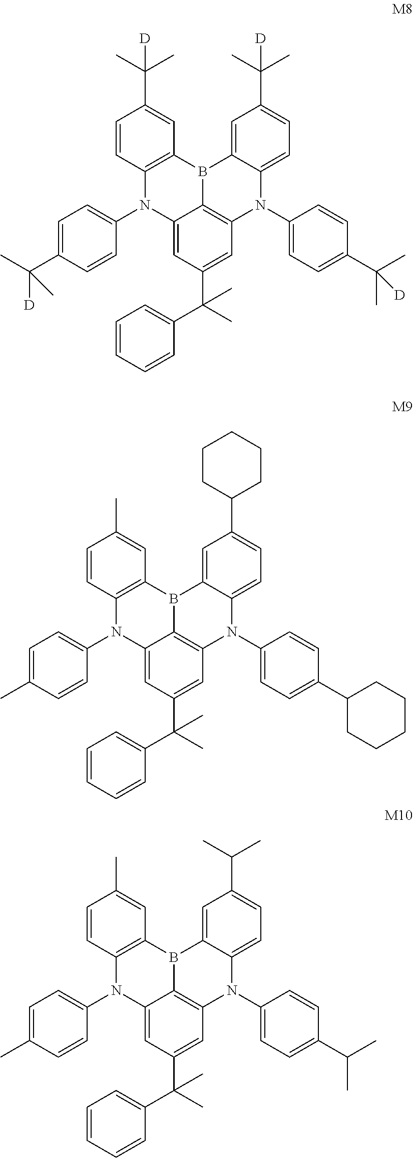

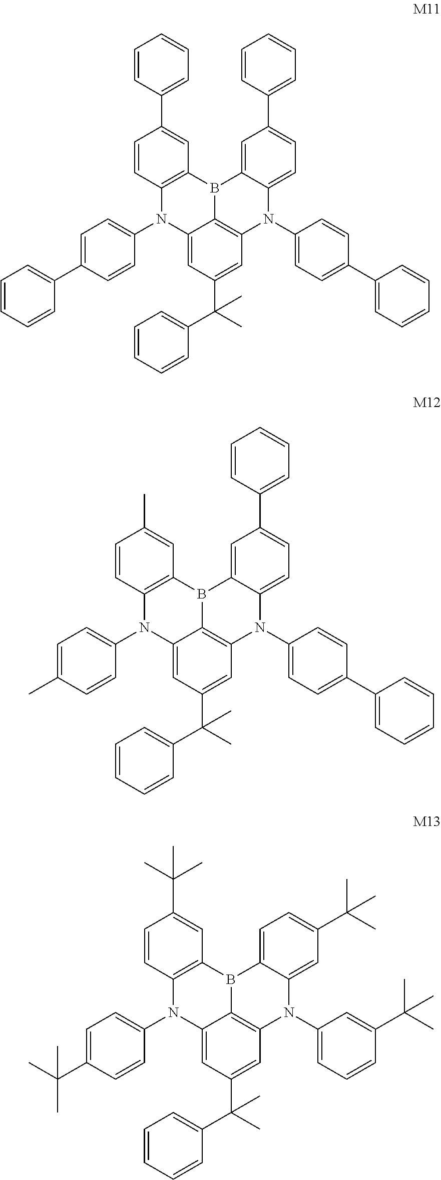 [SMILES: CC(C)(c1ccccc1)c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1 ; Cc1ccc(N2c3ccc(C)cc3B3c4cc(-c5ccccc5)ccc4N(c4ccc(-c5ccccc5)cc4)c4cc(C(C)(C)c5ccccc5)cc2c43)cc1 ; CC(C)(C)c1ccc(N2c3ccc(C(C)(C)C)cc3B3c4ccc(C(C)(C)C)cc4N(c4cccc(C(C)(C)C)c4)c4cc(C(C)(C)c5ccccc5)cc2c43)cc1]

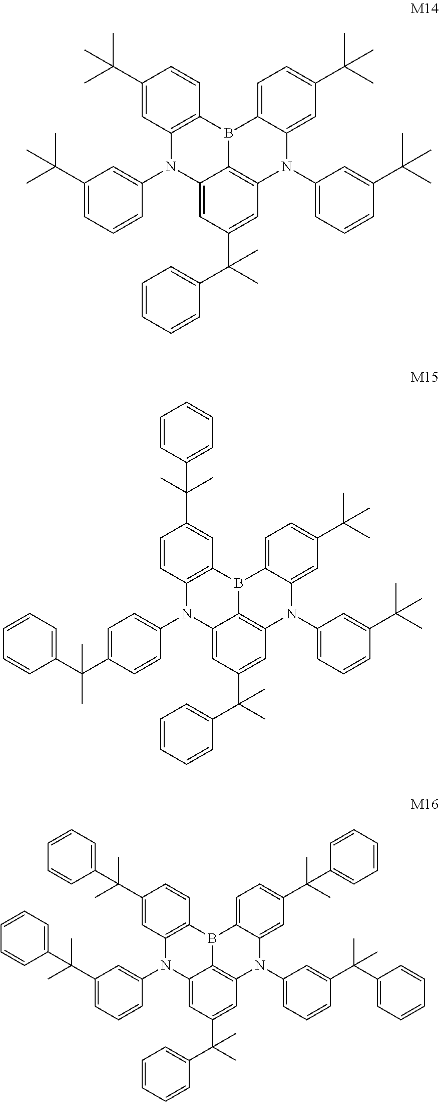 [SMILES: CC(C)(C)c1cccc(N2c3cc(C(C)(C)C)ccc3B3c4ccc(C(C)(C)C)cc4N(c4cccc(C(C)(C)C)c4)c4cc(C(C)(C)c5ccccc5)cc2c43)c1 ; CC(C)(C)c1cccc(N2c3cc(C(C)(C)C)ccc3B3c4cc(C(C)(C)c5ccccc5)ccc4N(c4ccc(C(C)(C)c5ccccc5)cc4)c4cc(C(C)(C)c5ccccc5)cc2c43)c1 ; CC(C)(c1ccccc1)c1cccc(N2c3cc(C(C)(C)c4ccccc4)ccc3B3c4ccc(C(C)(C)c5ccccc5)cc4N(c4cccc(C(C)(C)c5ccccc5)c4)c4cc(C(C)(C)c5ccccc5)cc2c43)c1]

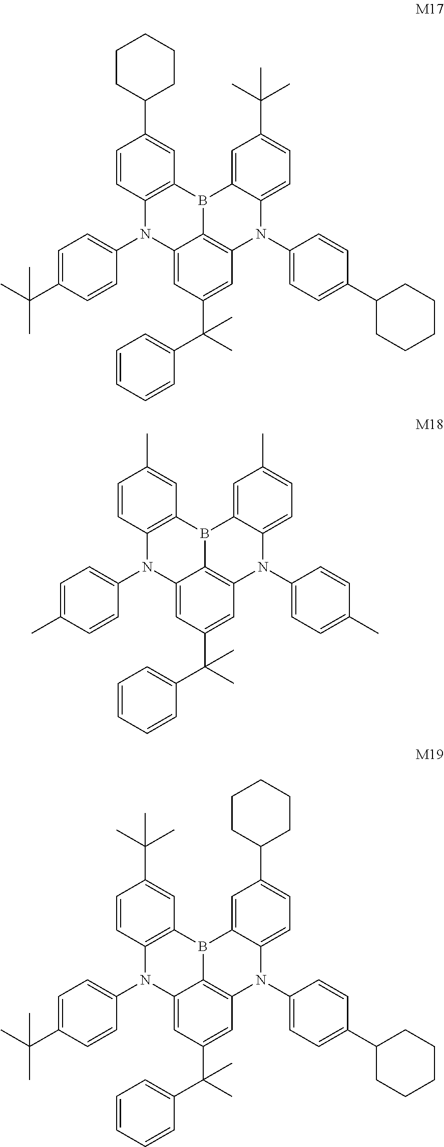

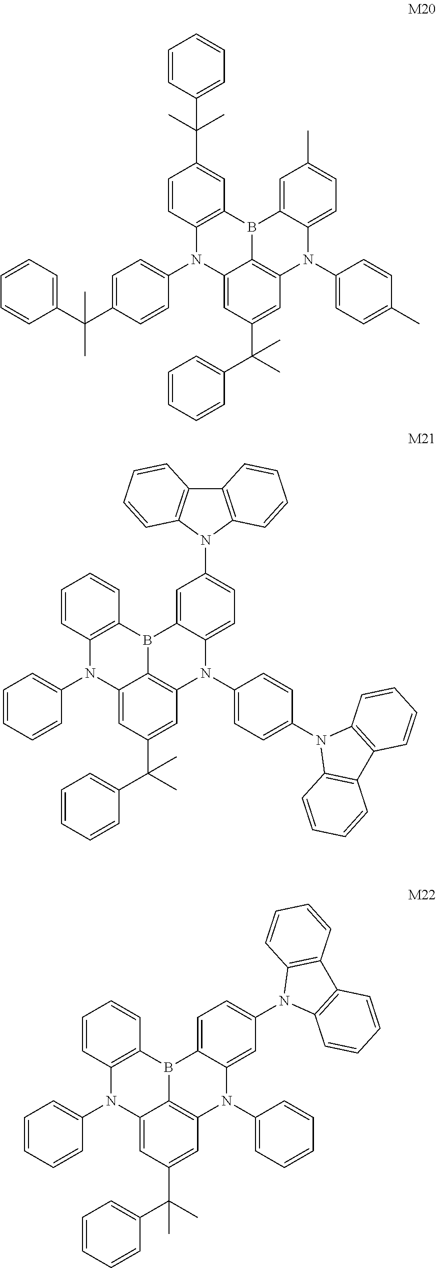 [SMILES: Cc1ccc(N2c3ccc(C)cc3B3c4cc(C(C)(C)c5ccccc5)ccc4N(c4ccc(C(C)(C)c5ccccc5)cc4)c4cc(C(C)(C)c5ccccc5)cc2c43)cc1 ; CC(C)(c1ccccc1)c1cc2c3c(c1)N(c1ccc(-n4c5ccccc5c5ccccc54)cc1)c1ccc(-n4c5ccccc5c5ccccc54)cc1B3c1ccccc1N2c1ccccc1 ; CC(C)(c1ccccc1)c1cc2c3c(c1)N(c1ccccc1)c1cc(-n4c5ccccc5c5ccccc54)ccc1B3c1ccccc1N2c1ccccc1]

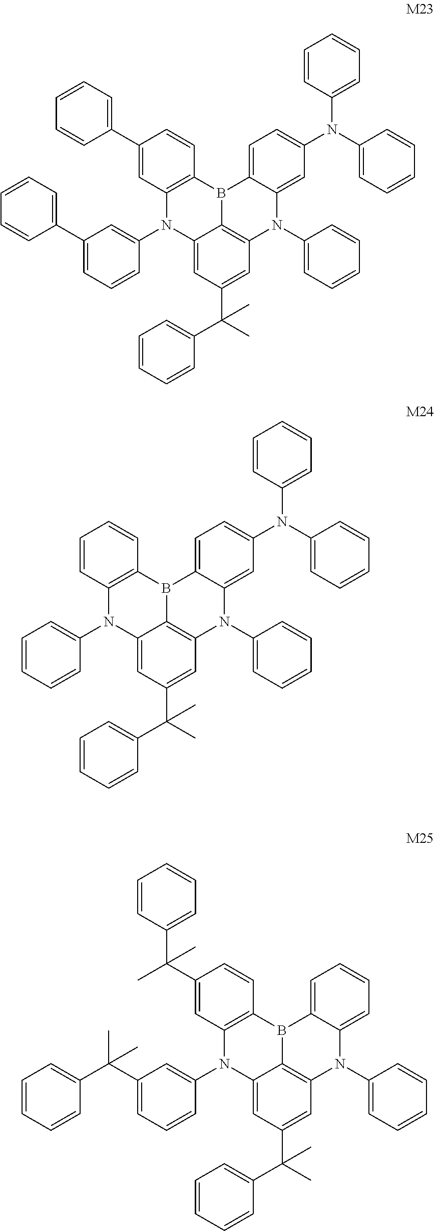 [SMILES: CC(C)(c1ccccc1)c1cc2c3c(c1)N(c1ccccc1)c1cc(N(c4ccccc4)c4ccccc4)ccc1B3c1ccc(-c3ccccc3)cc1N2c1cccc(-c2ccccc2)c1 ; CC(C)(c1ccccc1)c1cc2c3c(c1)N(c1ccccc1)c1cc(N(c4ccccc4)c4ccccc4)ccc1B3c1ccccc1N2c1ccccc1 ; CC(C)(c1ccccc1)c1cccc(N2c3cc(C(C)(C)c4ccccc4)ccc3B3c4ccccc4N(c4ccccc4)c4cc(C(C)(C)c5ccccc5)cc2c43)c1]

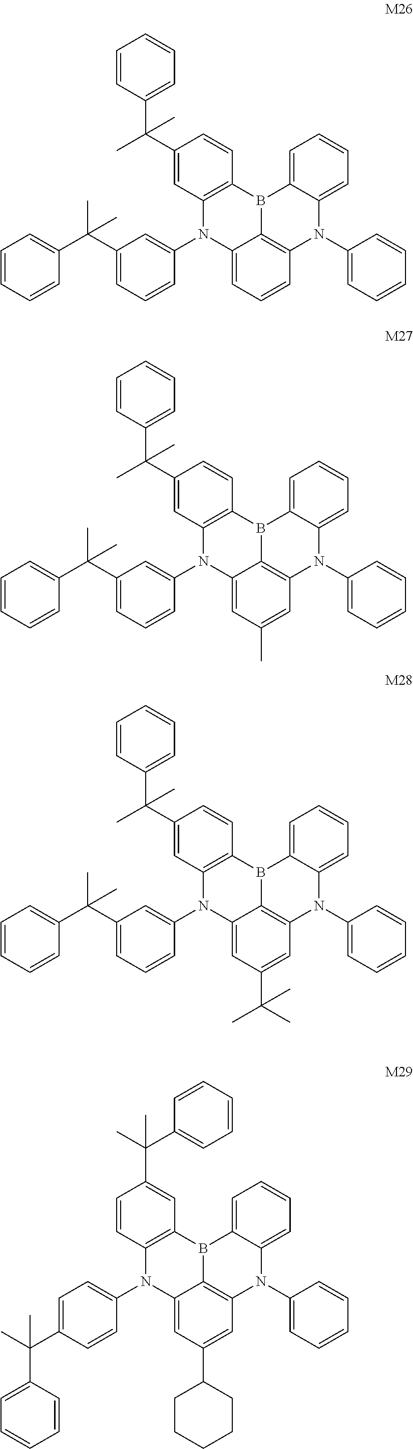 [SMILES: CC(C)(c1ccccc1)c1cccc(N2c3cc(C(C)(C)c4ccccc4)ccc3B3c4ccccc4N(c4ccccc4)c4cccc2c43)c1 ; Cc1cc2c3c(c1)N(c1cccc(C(C)(C)c4ccccc4)c1)c1cc(C(C)(C)c4ccccc4)ccc1B3c1ccccc1N2c1ccccc1 ; CC(C)(C)c1cc2c3c(c1)N(c1cccc(C(C)(C)c4ccccc4)c1)c1cc(C(C)(C)c4ccccc4)ccc1B3c1ccccc1N2c1ccccc1 ; CC(C)(c1ccccc1)c1ccc(N2c3ccc(C(C)(C)c4ccccc4)cc3B3c4ccccc4N(c4ccccc4)c4cc(C5CCCCC5)cc2c43)cc1]

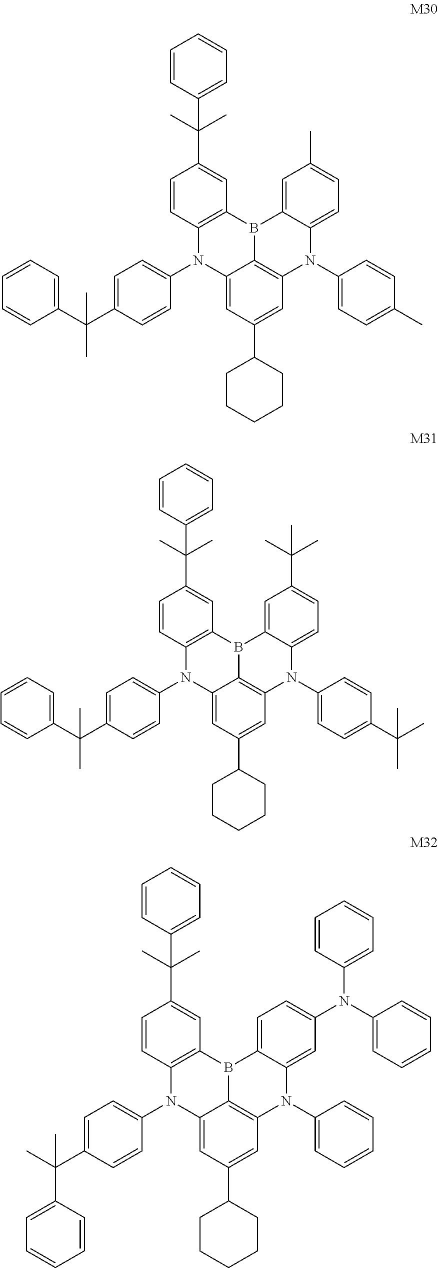 [SMILES: Cc1ccc(N2c3ccc(C)cc3B3c4cc(C(C)(C)c5ccccc5)ccc4N(c4ccc(C(C)(C)c5ccccc5)cc4)c4cc(C5CCCCC5)cc2c43)cc1 ; CC(C)(C)c1ccc(N2c3ccc(C(C)(C)C)cc3B3c4cc(C(C)(C)c5ccccc5)ccc4N(c4ccc(C(C)(C)c5ccccc5)cc4)c4cc(C5CCCCC5)cc2c43)cc1 ; CC(C)(c1ccccc1)c1ccc(N2c3ccc(C(C)(C)c4ccccc4)cc3B3c4ccc(N(c5ccccc5)c5ccccc5)cc4N(c4ccccc4)c4cc(C5CCCCC5)cc2c43)cc1]

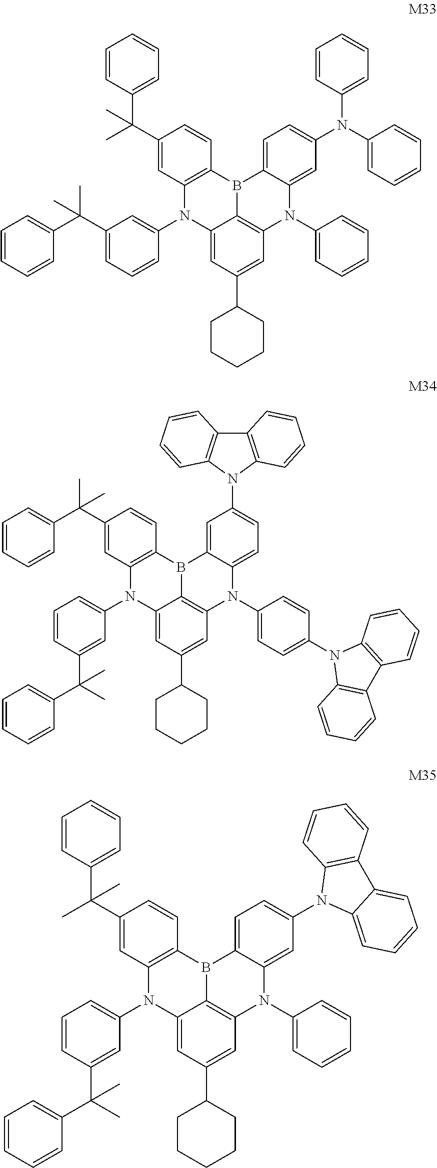 [SMILES: CC(C)(c1ccccc1)c1cccc(N2c3cc(C(C)(C)c4ccccc4)ccc3B3c4ccc(N(c5ccccc5)c5ccccc5)cc4N(c4ccccc4)c4cc(C5CCCCC5)cc2c43)c1 ; CC(C)(c1ccccc1)c1cccc(N2c3cc(C(C)(C)c4ccccc4)ccc3B3c4cc(-n5c6ccccc6c6ccccc65)ccc4N(c4ccc(-n5c6ccccc6c6ccccc65)cc4)c4cc(C5CCCCC5)cc2c43)c1 ; CC(C)(c1ccccc1)c1cccc(N2c3cc(C(C)(C)c4ccccc4)ccc3B3c4ccc(-n5c6ccccc6c6ccccc65)cc4N(c4ccccc4)c4cc(C5CCCCC5)cc2c43)c1]

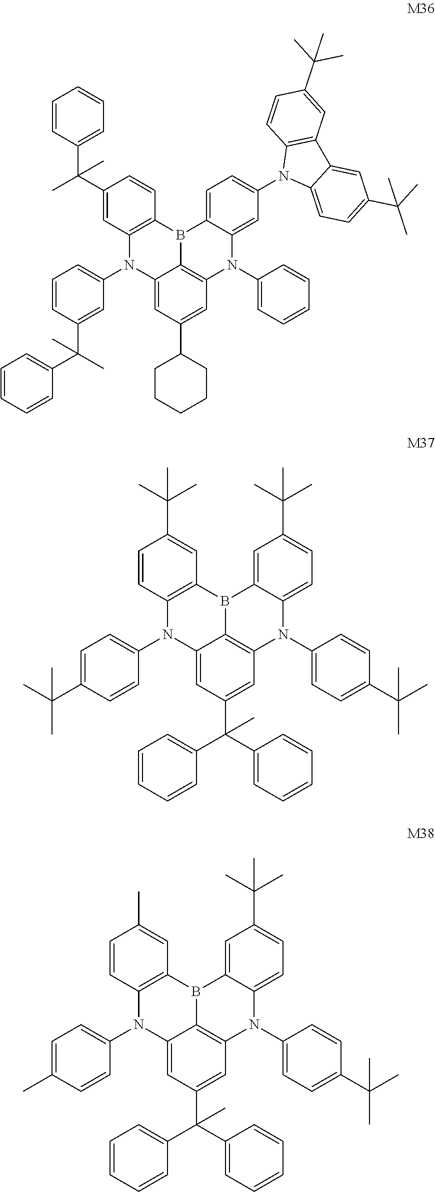

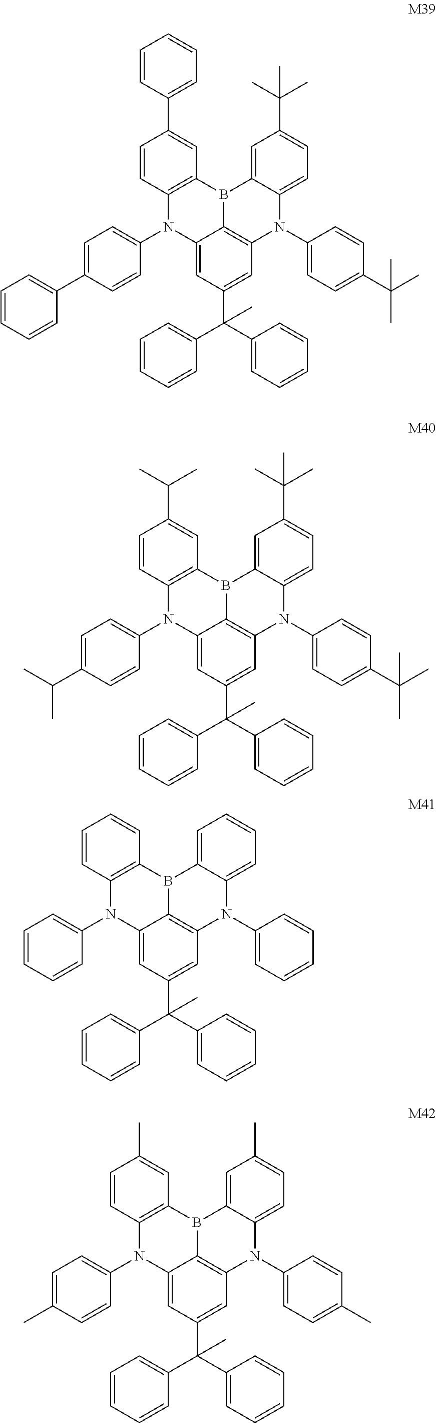

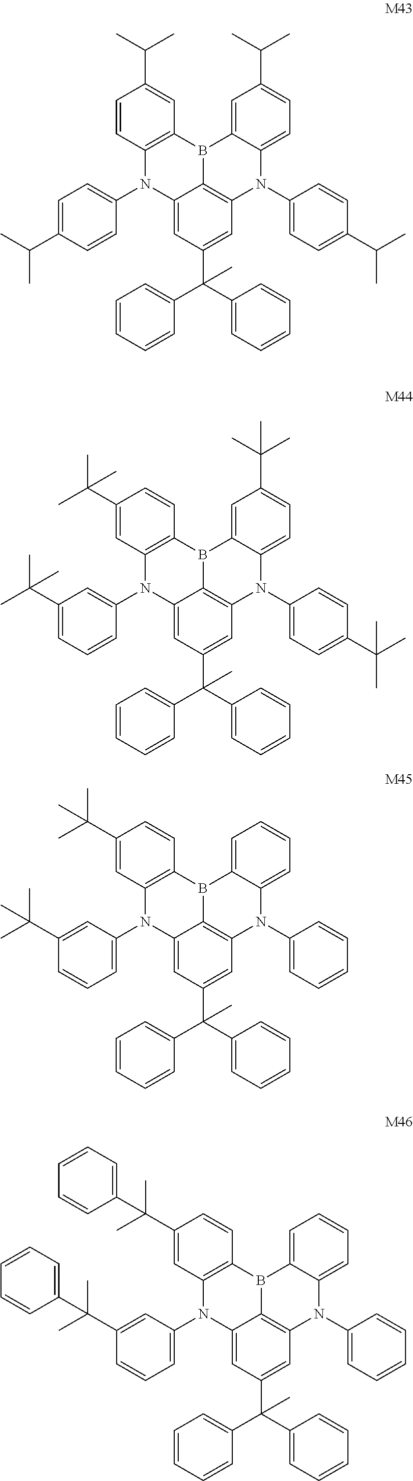

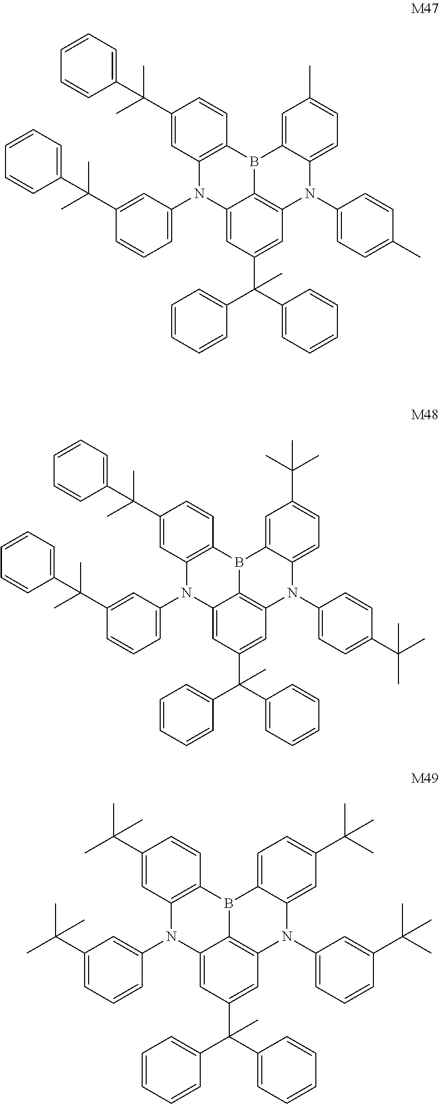

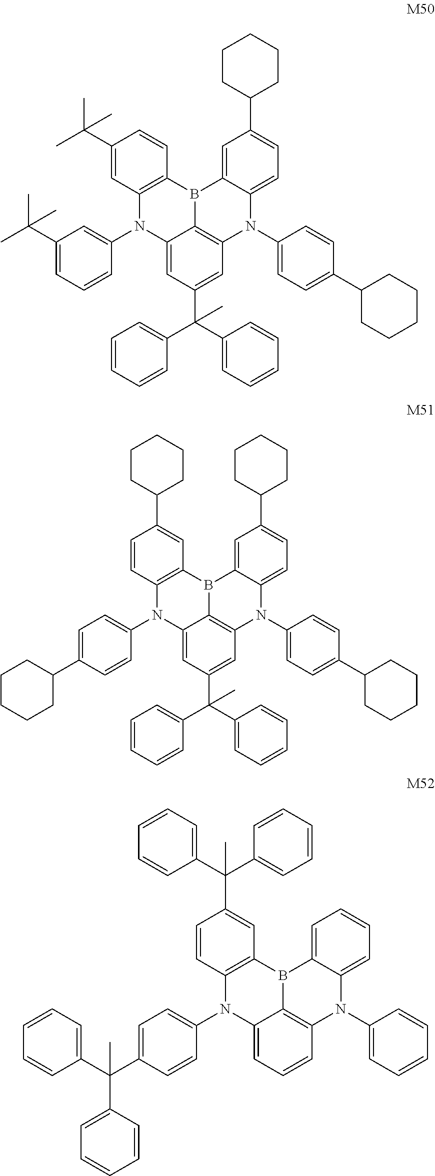 [SMILES: CC(C)(C)c1cccc(N2c3cc(C(C)(C)C)ccc3B3c4cc(C5CCCCC5)ccc4N(c4ccc(C5CCCCC5)cc4)c4cc(C(C)(c5ccccc5)c5ccccc5)cc2c43)c1 ; CC(c1ccccc1)(c1ccccc1)c1cc2c3c(c1)N(c1ccc(C4CCCCC4)cc1)c1ccc(C4CCCCC4)cc1B3c1cc(C3CCCCC3)ccc1N2c1ccc(C2CCCCC2)cc1 ; CC(c1ccccc1)(c1ccccc1)c1ccc(N2c3ccc(C(C)(c4ccccc4)c4ccccc4)cc3B3c4ccccc4N(c4ccccc4)c4cccc2c43)cc1]

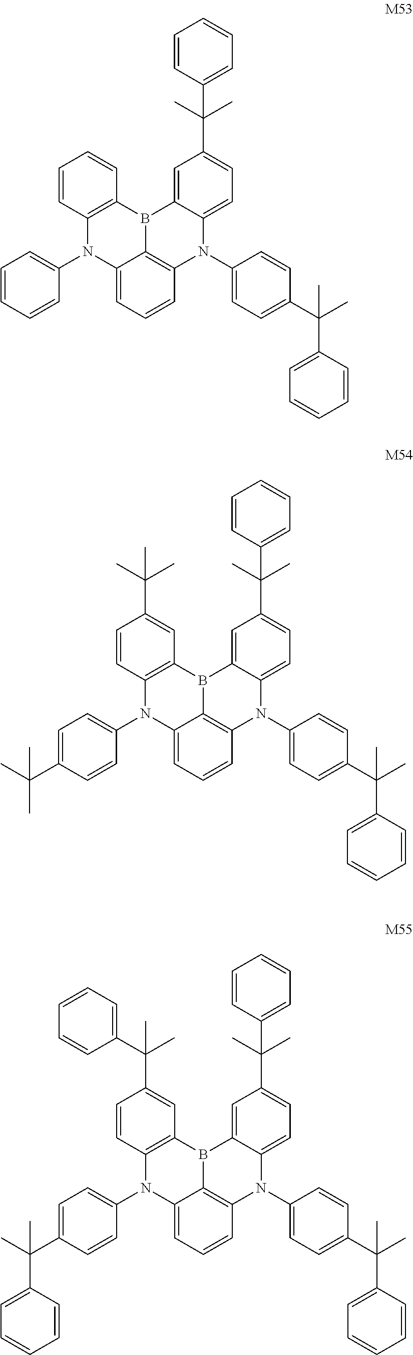

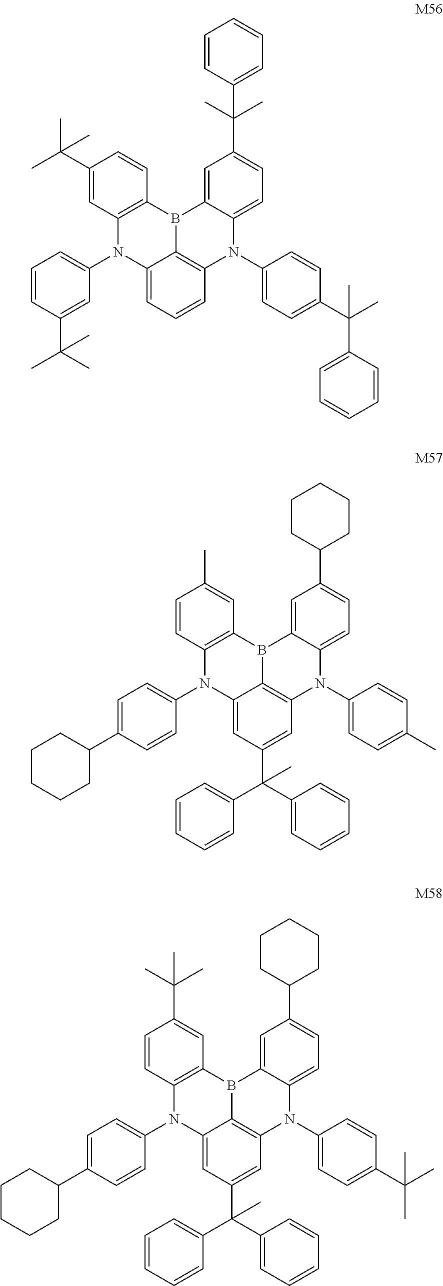 [SMILES: CC(C)(C)c1cccc(N2c3cc(C(C)(C)C)ccc3B3c4cc(C(C)(C)c5ccccc5)ccc4N(c4ccc(C(C)(C)c5ccccc5)cc4)c4cccc2c43)c1 ; Cc1ccc(N2c3ccc(C4CCCCC4)cc3B3c4cc(C)ccc4N(c4ccc(C5CCCCC5)cc4)c4cc(C(C)(c5ccccc5)c5ccccc5)cc2c43)cc1 ; CC(C)(C)c1ccc(N2c3ccc(C4CCCCC4)cc3B3c4cc(C(C)(C)C)ccc4N(c4ccc(C5CCCCC5)cc4)c4cc(C(C)(c5ccccc5)c5ccccc5)cc2c43)cc1]

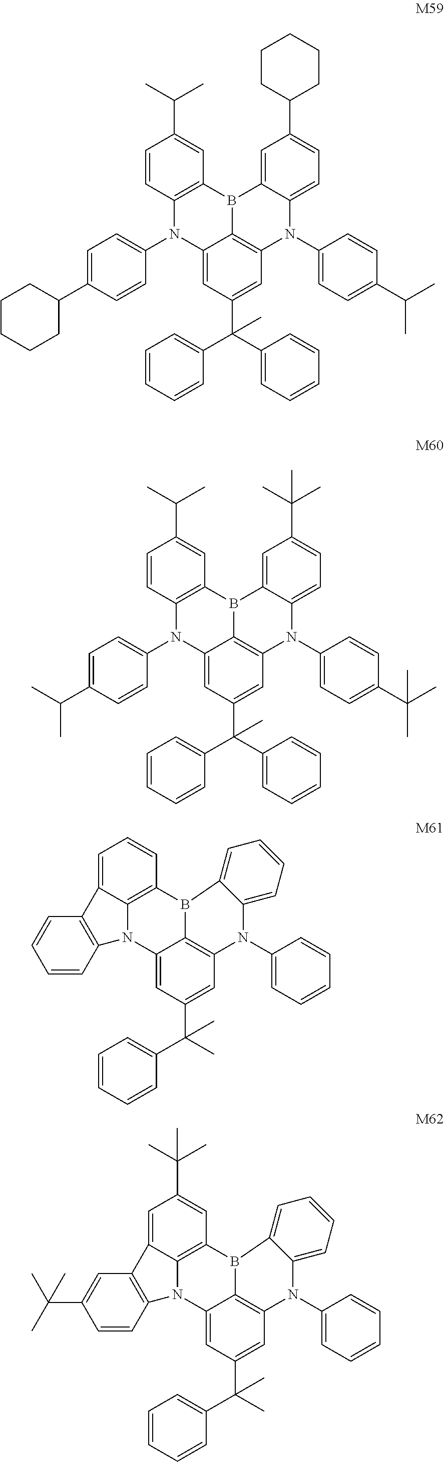

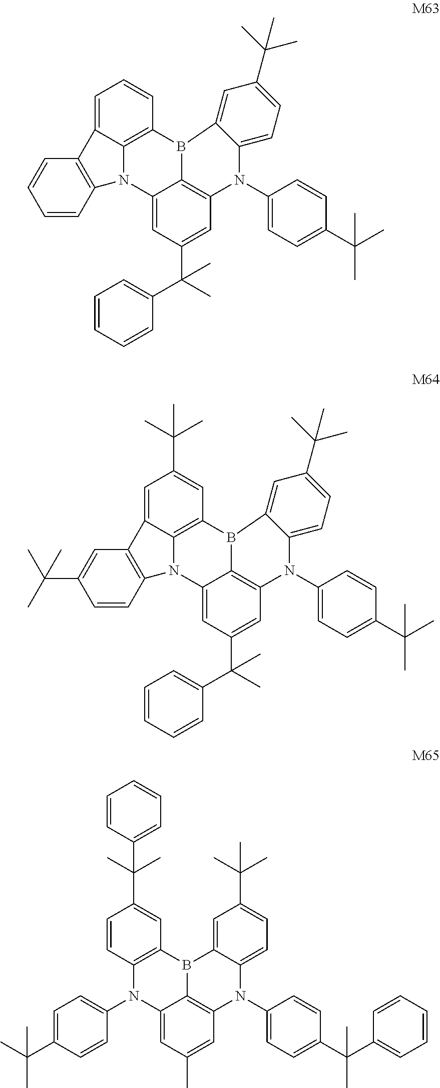

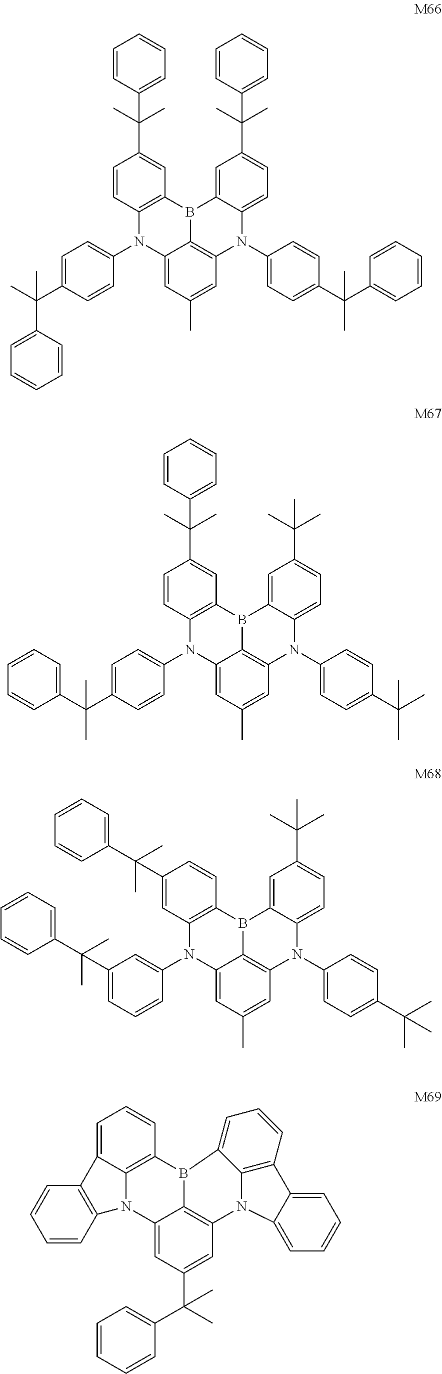 [SMILES: Cc1cc2c3c(c1)N(c1ccc(C(C)(C)c4ccccc4)cc1)c1ccc(C(C)(C)c4ccccc4)cc1B3c1cc(C(C)(C)c3ccccc3)ccc1N2c1ccc(C(C)(C)c2ccccc2)cc1 ; Cc1cc2c3c(c1)N(c1ccc(C(C)(C)c4ccccc4)cc1)c1ccc(C(C)(C)c4ccccc4)cc1B3c1cc(C(C)(C)C)ccc1N2c1ccc(C(C)(C)C)cc1 ; Cc1cc2c3c(c1)N(c1cccc(C(C)(C)c4ccccc4)c1)c1cc(C(C)(C)c4ccccc4)ccc1B3c1cc(C(C)(C)C)ccc1N2c1ccc(C(C)(C)C)cc1 ; CC(C)(c1ccccc1)c1cc2c3c(c1)-n1c4ccccc4c4cccc(c41)B3c1cccc3c4ccccc4n-2c13]

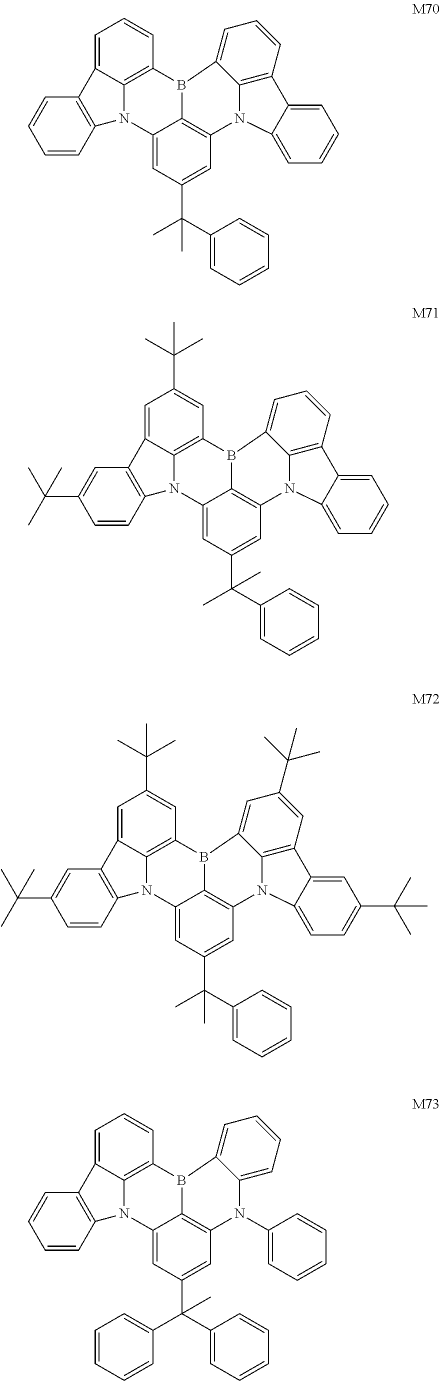 [SMILES: CC(C)(c1ccccc1)c1cc2c3c(c1)-n1c4ccccc4c4cccc(c41)B3c1cccc3c4ccccc4n-2c13 ; CC(C)(C)c1ccc2c(c1)c1cc(C(C)(C)C)cc3c1n2-c1cc(C(C)(C)c2ccccc2)cc2c1B3c1cccc3c4ccccc4n-2c13 ; CC(C)(C)c1ccc2c(c1)c1cc(C(C)(C)C)cc3c1n2-c1cc(C(C)(C)c2ccccc2)cc2c1B3c1cc(C(C)(C)C)cc3c4cc(C(C)(C)C)ccc4n-2c13 ; CC(c1ccccc1)(c1ccccc1)c1cc2c3c(c1)-n1c4ccccc4c4cccc(c41)B3c1ccccc1N2c1ccccc1]

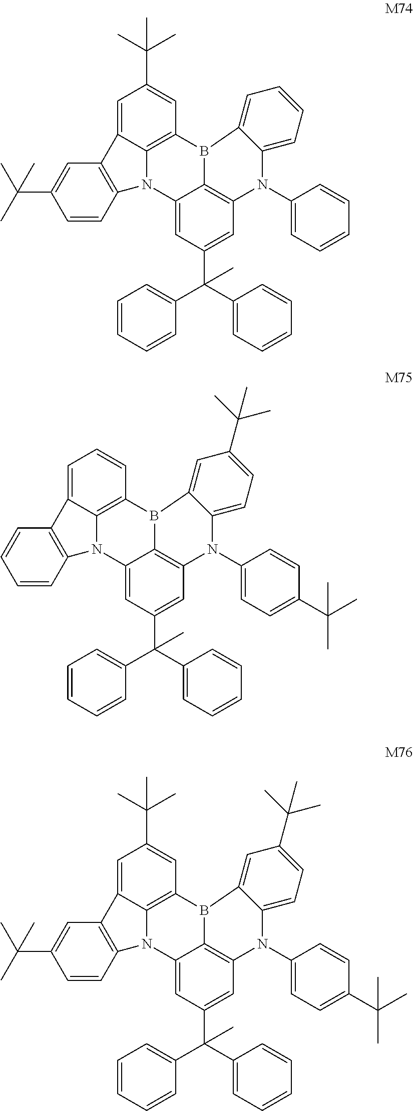

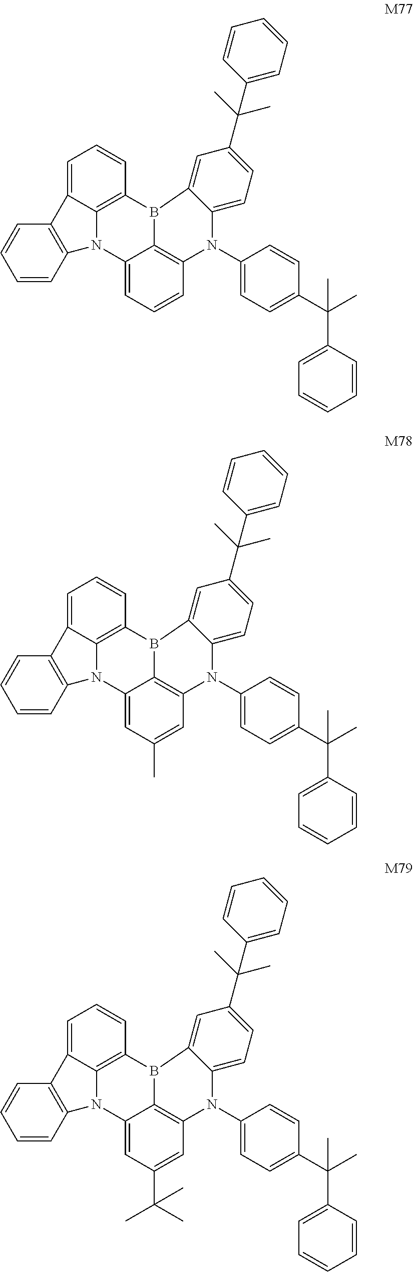 [SMILES: CC(C)(c1ccccc1)c1ccc(N2c3ccc(C(C)(C)c4ccccc4)cc3B3c4c2cccc4-n2c4ccccc4c4cccc3c42)cc1 ; Cc1cc2c3c(c1)-n1c4ccccc4c4cccc(c41)B3c1cc(C(C)(C)c3ccccc3)ccc1N2c1ccc(C(C)(C)c2ccccc2)cc1 ; CC(C)(C)c1cc2c3c(c1)-n1c4ccccc4c4cccc(c41)B3c1cc(C(C)(C)c3ccccc3)ccc1N2c1ccc(C(C)(C)c2ccccc2)cc1]

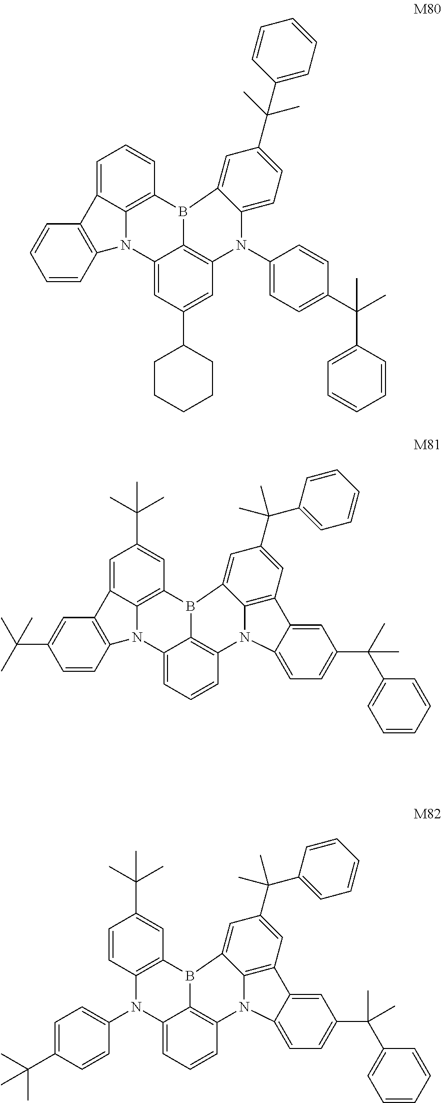

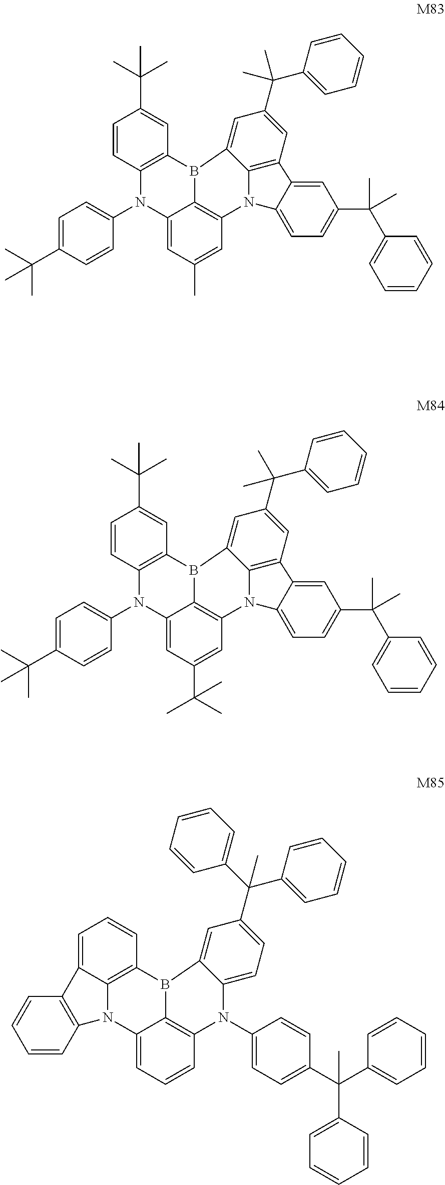 [SMILES: Cc1cc2c3c(c1)-n1c4ccc(C(C)(C)c5ccccc5)cc4c4cc(C(C)(C)c5ccccc5)cc(c41)B3c1cc(C(C)(C)C)ccc1N2c1ccc(C(C)(C)C)cc1 ; CC(C)(C)c1ccc(N2c3ccc(C(C)(C)C)cc3B3c4c2cc(C(C)(C)C)cc4-n2c4ccc(C(C)(C)c5ccccc5)cc4c4cc(C(C)(C)c5ccccc5)cc3c42)cc1 ; CC(c1ccccc1)(c1ccccc1)c1ccc(N2c3ccc(C(C)(c4ccccc4)c4ccccc4)cc3B3c4c2cccc4-n2c4ccccc4c4cccc3c42)cc1]

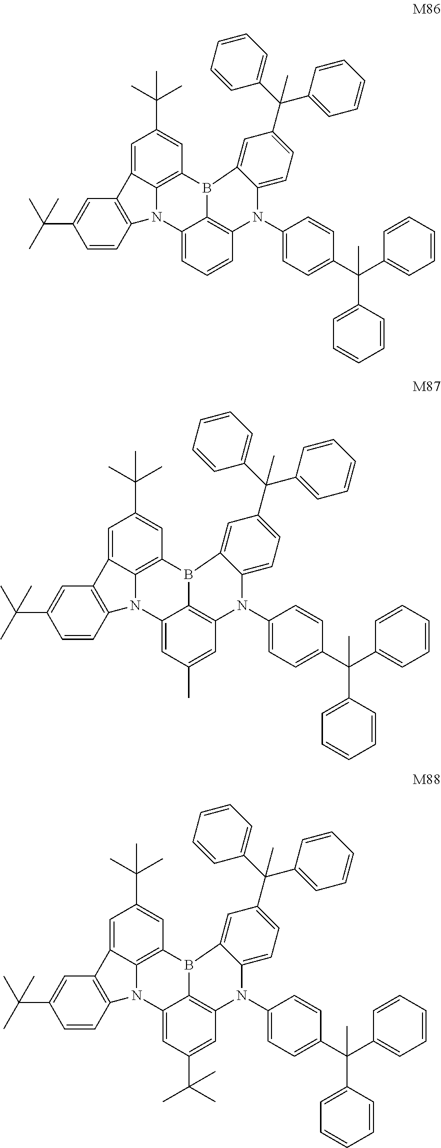 [SMILES: CC(C)(C)c1ccc2c(c1)c1cc(C(C)(C)C)cc3c1n2-c1cccc2c1B3c1cc(C(C)(c3ccccc3)c3ccccc3)ccc1N2c1ccc(C(C)(c2ccccc2)c2ccccc2)cc1 ; Cc1cc2c3c(c1)-n1c4ccc(C(C)(C)C)cc4c4cc(C(C)(C)C)cc(c41)B3c1cc(C(C)(c3ccccc3)c3ccccc3)ccc1N2c1ccc(C(C)(c2ccccc2)c2ccccc2)cc1 ; CC(C)(C)c1cc2c3c(c1)-n1c4ccc(C(C)(C)C)cc4c4cc(C(C)(C)C)cc(c41)B3c1cc(C(C)(c3ccccc3)c3ccccc3)ccc1N2c1ccc(C(C)(c2ccccc2)c2ccccc2)cc1]

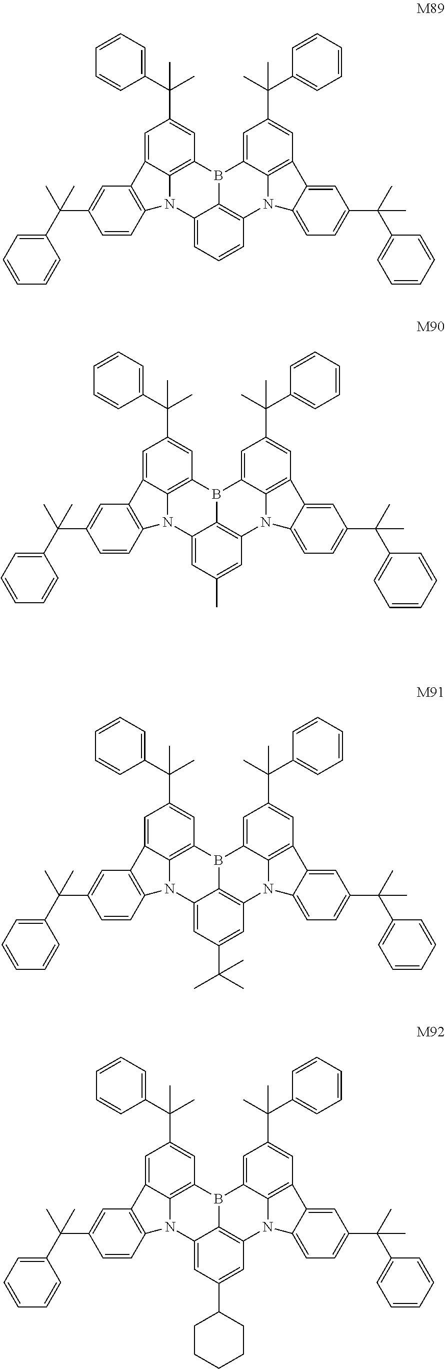

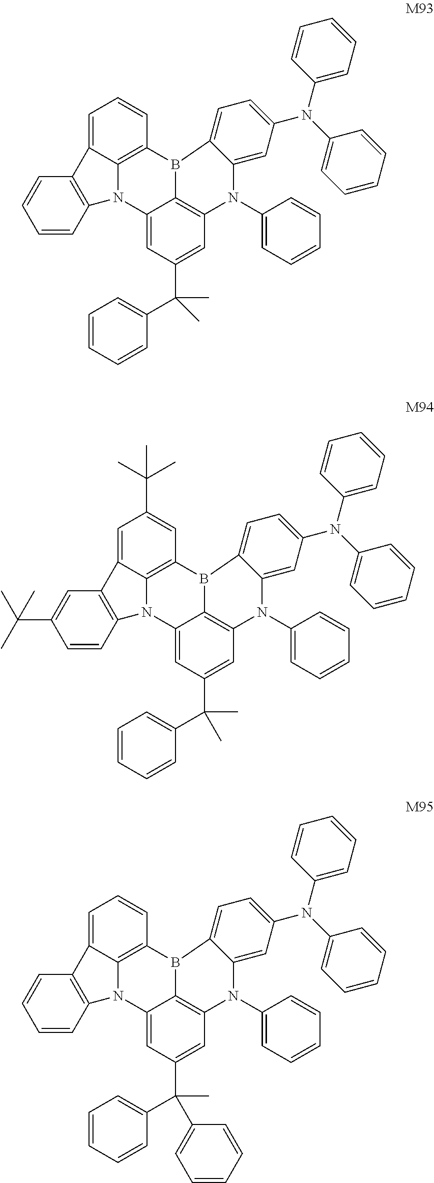 [SMILES: CC(C)(c1ccccc1)c1cc2c3c(c1)-n1c4ccccc4c4cccc(c41)B3c1ccc(N(c3ccccc3)c3ccccc3)cc1N2c1ccccc1 ; CC(C)(C)c1ccc2c(c1)c1cc(C(C)(C)C)cc3c1n2-c1cc(C(C)(C)c2ccccc2)cc2c1B3c1ccc(N(c3ccccc3)c3ccccc3)cc1N2c1ccccc1 ; CC(c1ccccc1)(c1ccccc1)c1cc2c3c(c1)-n1c4ccccc4c4cccc(c41)B3c1ccc(N(c3ccccc3)c3ccccc3)cc1N2c1ccccc1]

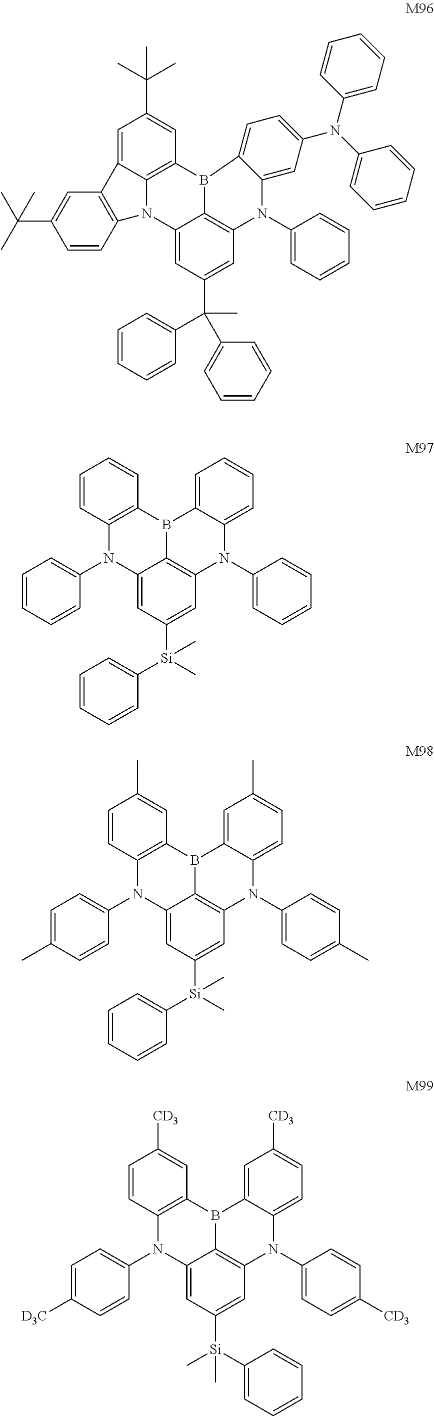

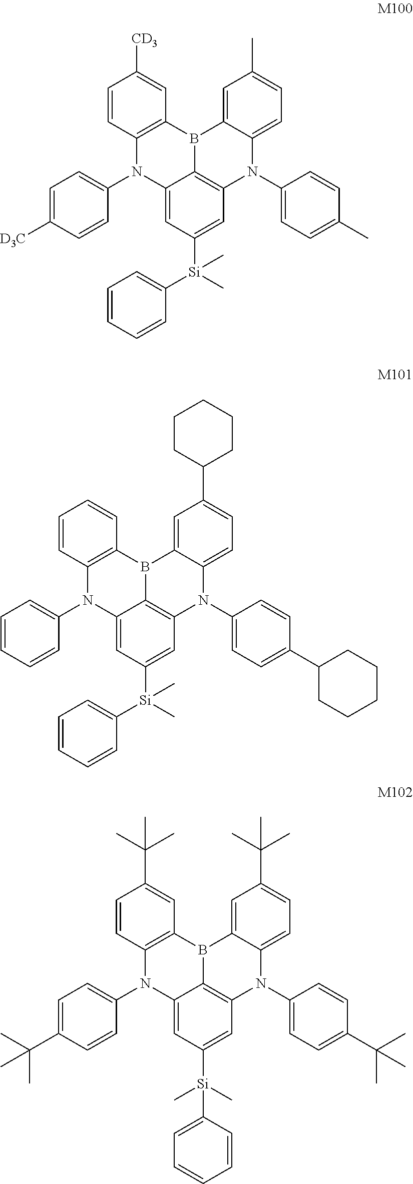

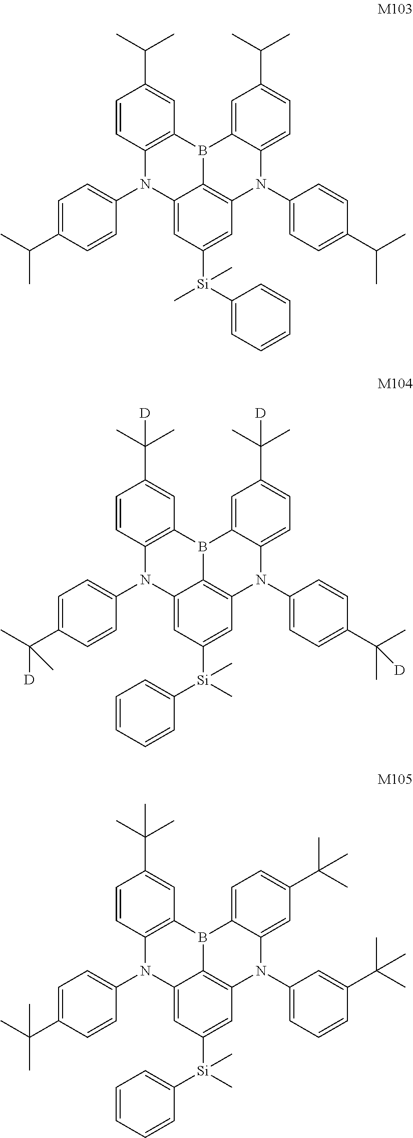

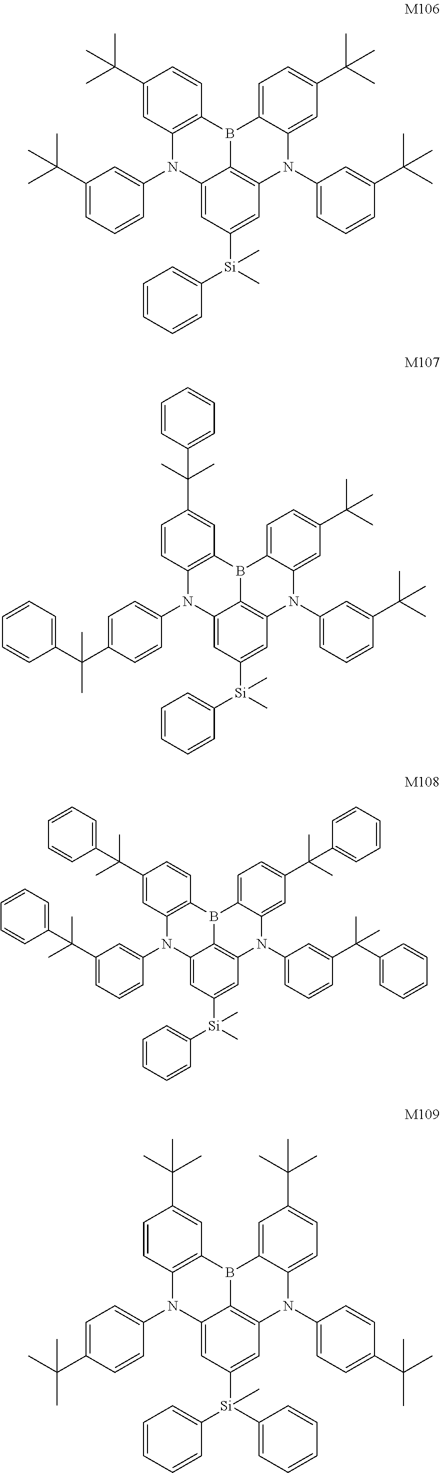

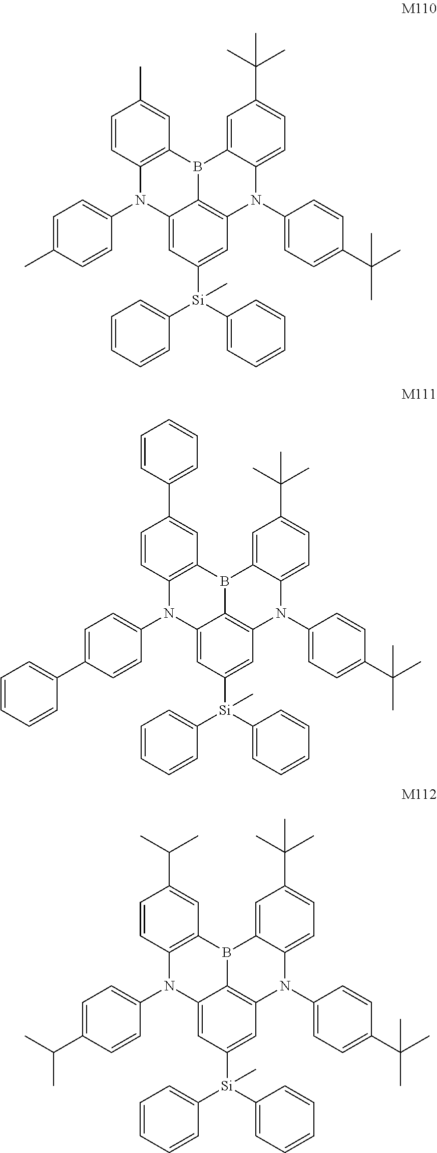

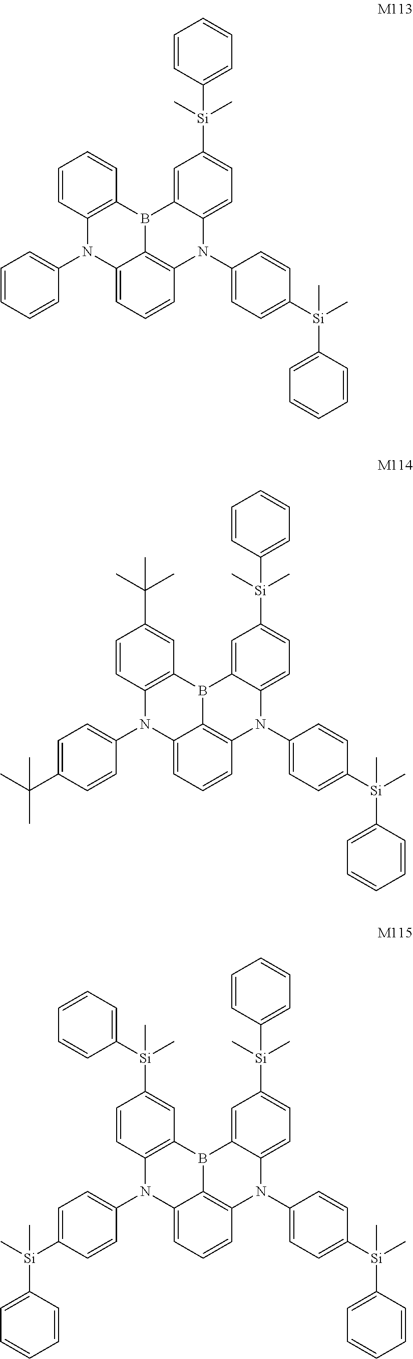

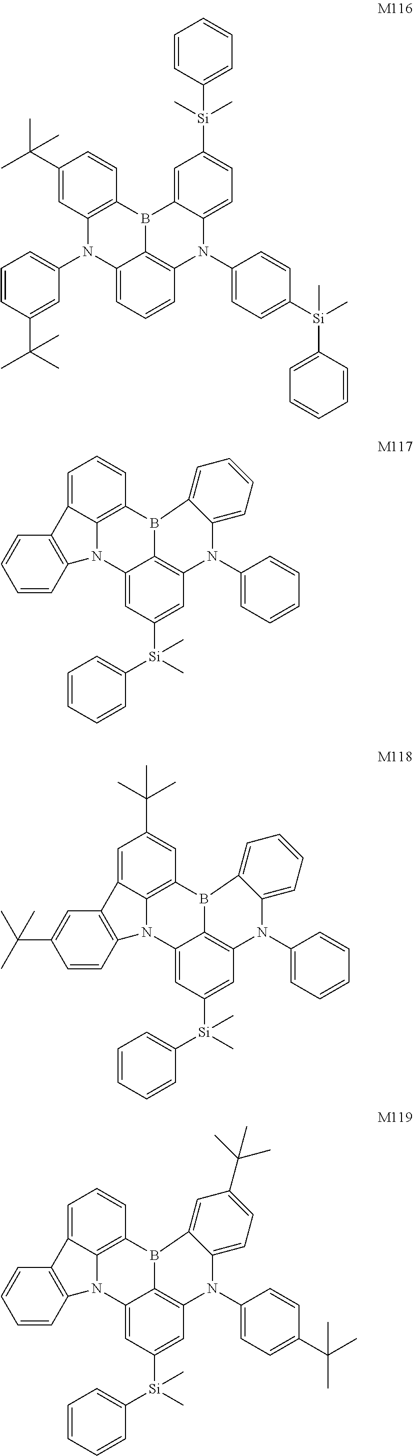

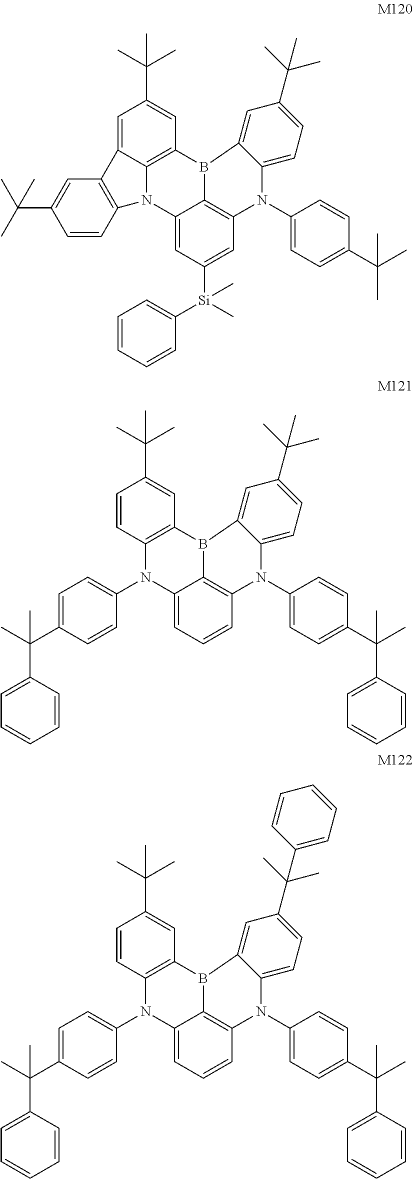

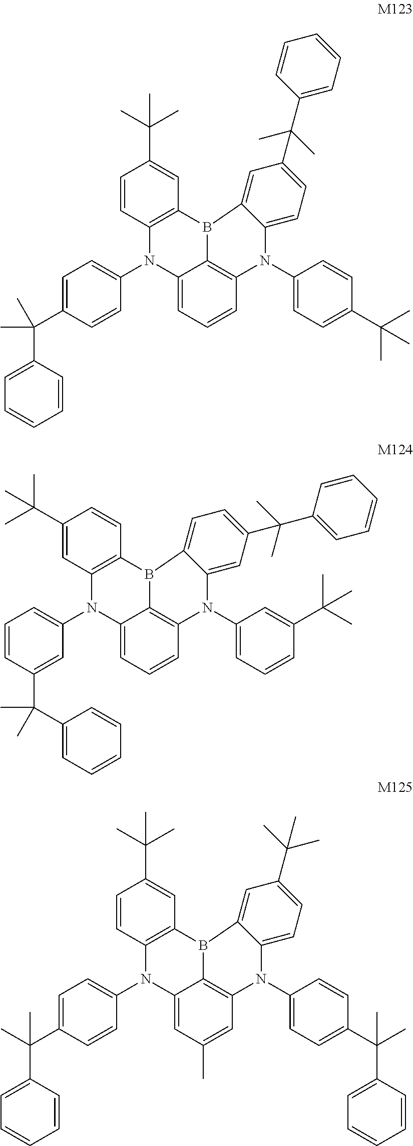

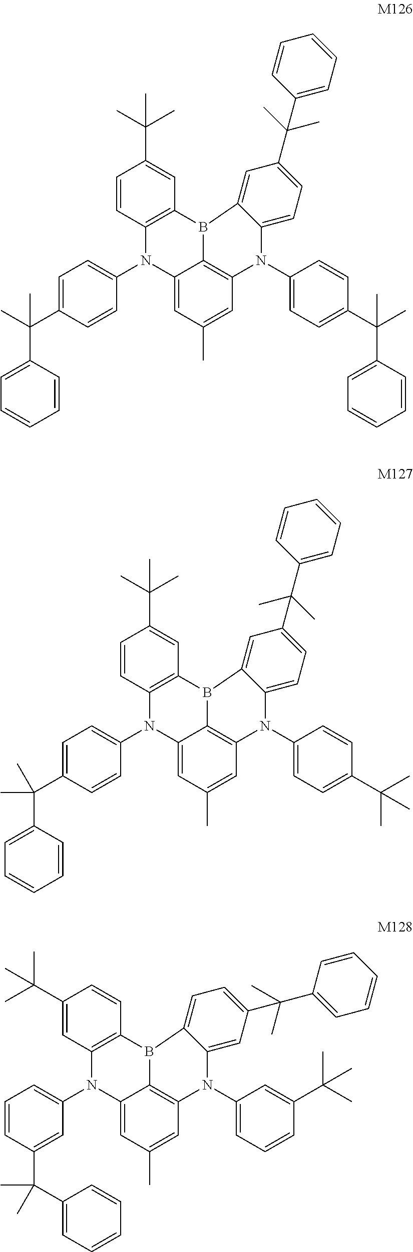

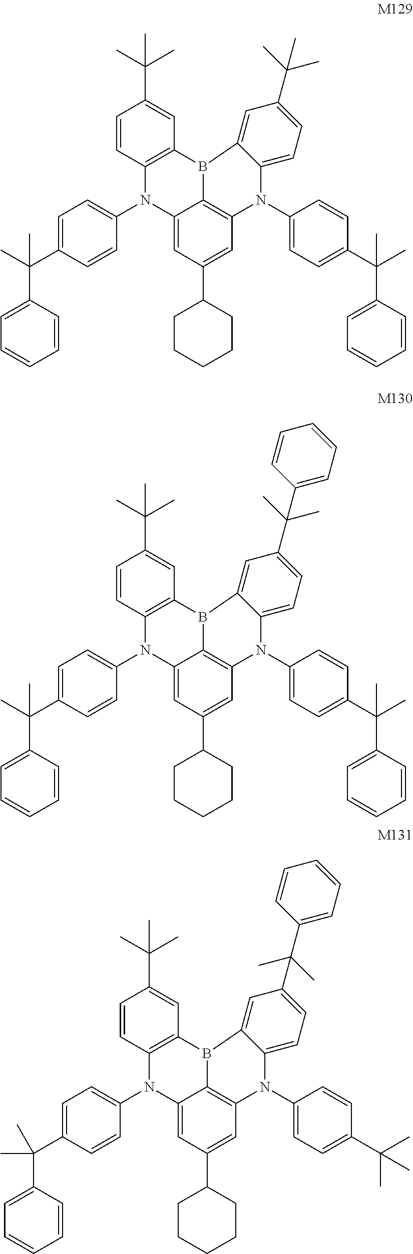

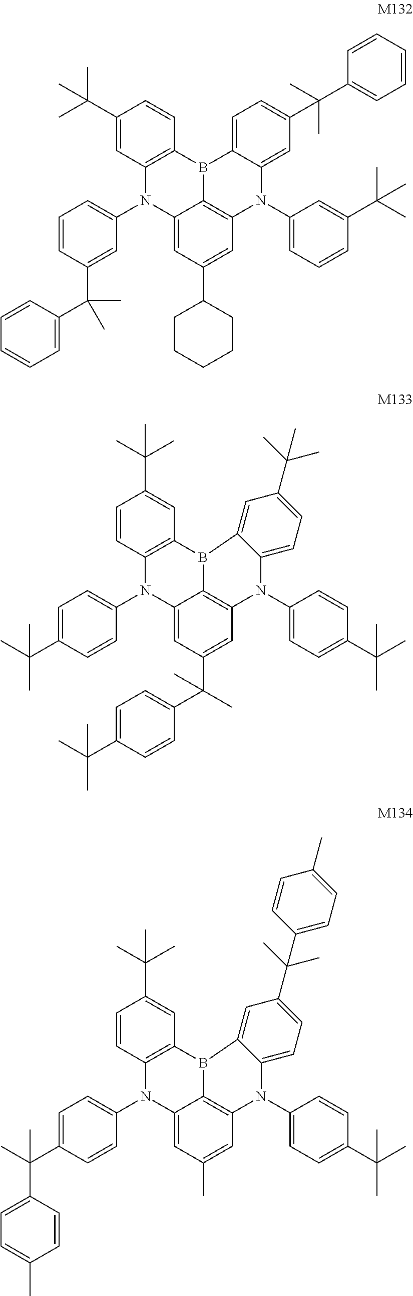

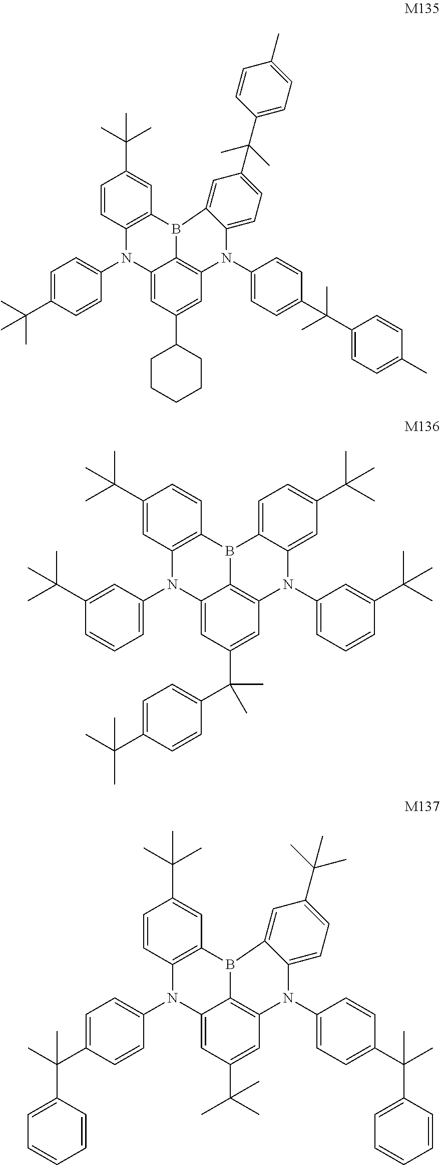

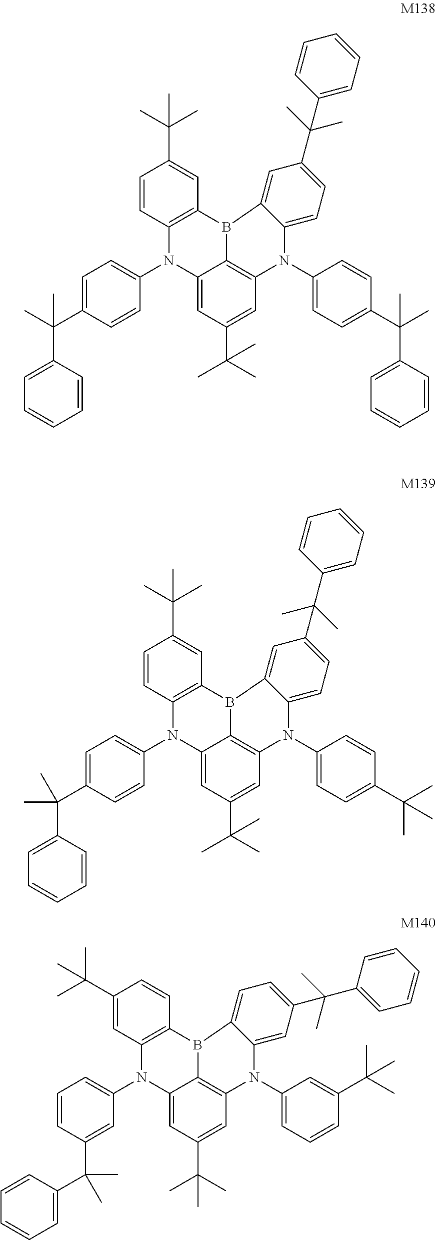

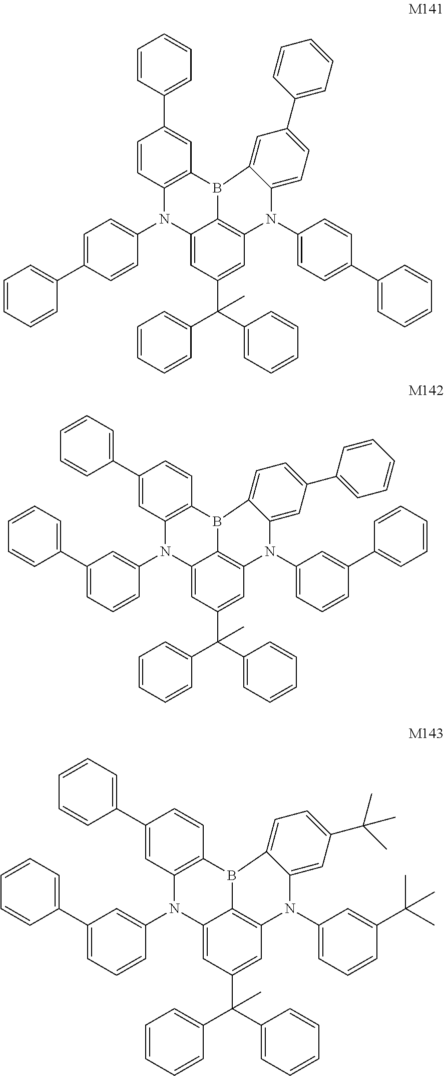 [SMILES: CC(c1ccccc1)(c1ccccc1)c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1 ; CC(c1ccccc1)(c1ccccc1)c1cc2c3c(c1)N(c1cccc(-c4ccccc4)c1)c1cc(-c4ccccc4)ccc1B3c1ccc(-c3ccccc3)cc1N2c1cccc(-c2ccccc2)c1 ; CC(C)(C)c1cccc(N2c3cc(C(C)(C)C)ccc3B3c4ccc(-c5ccccc5)cc4N(c4cccc(-c5ccccc5)c4)c4cc(C(C)(c5ccccc5)c5ccccc5)cc2c43)c1]

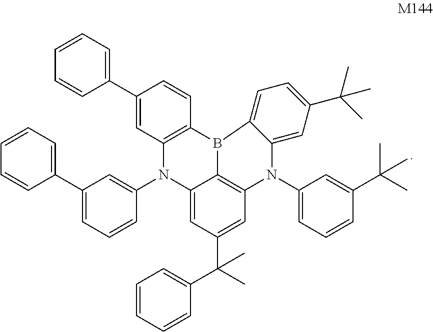 [SMILES: CC(C)(C)c1cccc(N2c3cc(C(C)(C)C)ccc3B3c4ccc(-c5ccccc5)cc4N(c4cccc(-c5ccccc5)c4)c4cc(C(C)(C)c5ccccc5)cc2c43)c1]

The fluorescent dye described in the present disclosure can be prepared through a conventional method in the art, and the present disclosure merely exemplarily provides the following representative synthesis routes:

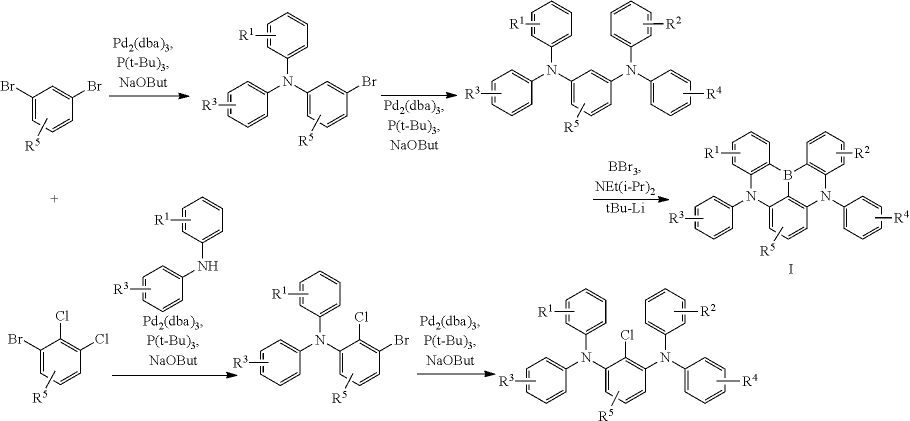

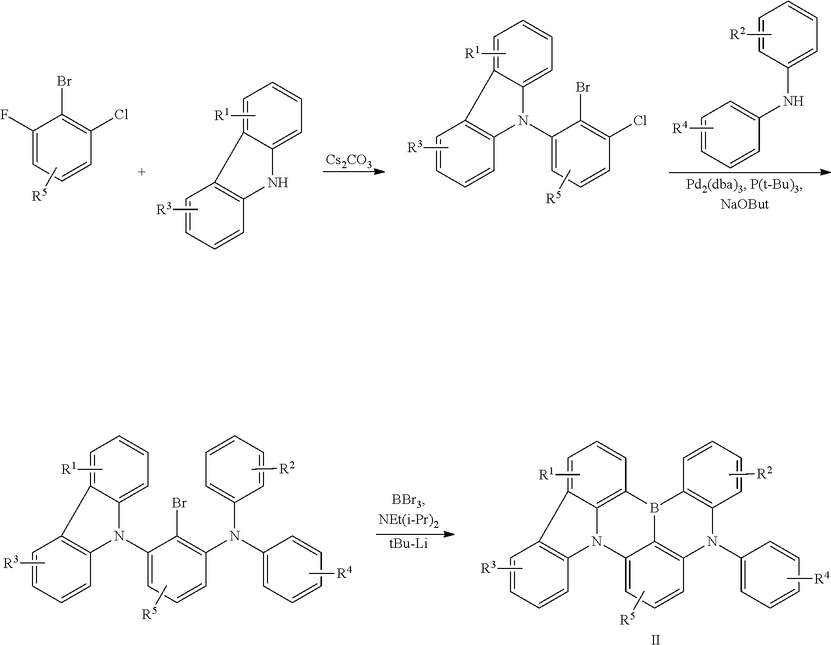

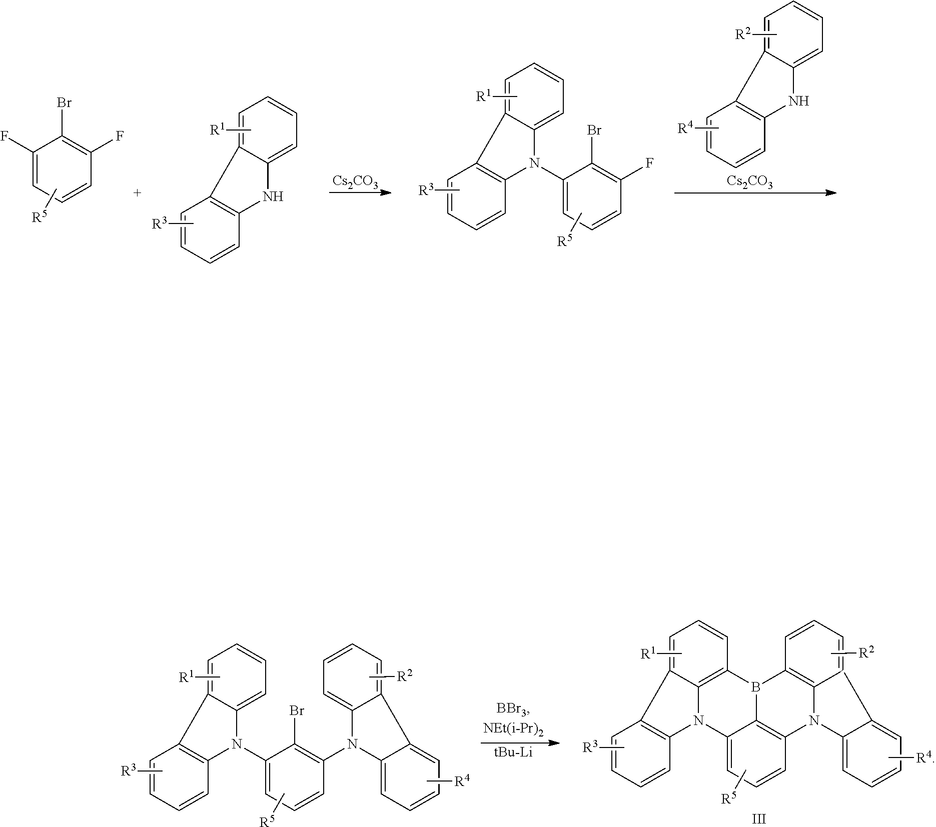

It is to be noted that acquiring the fluorescent dye of the present disclosure is not limited to the synthesis methods and the raw materials used in the present disclosure, and those skilled in the art can also select another method or route to obtain the fluorescent dye provided in the present disclosure.

In an optional embodiment, the host material is selected from any one or a combination of at least two of the following compounds TDH-1 to TDH-30 (such as a combination of TDH-2 and TDH-10, a combination of TDH-23 and TDH-8 or a combination of TDH-16, TDH-22 and TDH-30):

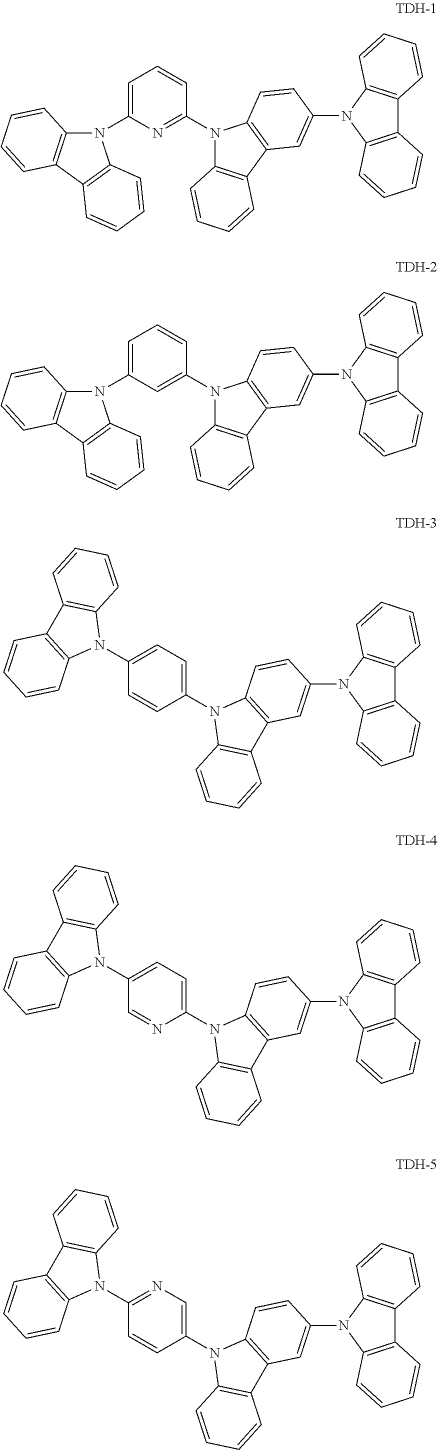 [SMILES: c1cc(-n2c3ccccc3c3ccccc32)nc(-n2c3ccccc3c3cc(-n4c5ccccc5c5ccccc54)ccc32)c1 ; c1cc(-n2c3ccccc3c3ccccc32)cc(-n2c3ccccc3c3cc(-n4c5ccccc5c5ccccc54)ccc32)c1 ; c1ccc2c(c1)c1ccccc1n2-c1ccc(-n2c3ccccc3c3cc(-n4c5ccccc5c5ccccc54)ccc32)cc1 ; c1ccc2c(c1)c1ccccc1n2-c1ccc(-n2c3ccccc3c3cc(-n4c5ccccc5c5ccccc54)ccc32)nc1 ; c1ccc2c(c1)c1ccccc1n2-c1ccc2c(c1)c1ccccc1n2-c1ccc(-n2c3ccccc3c3ccccc32)nc1]

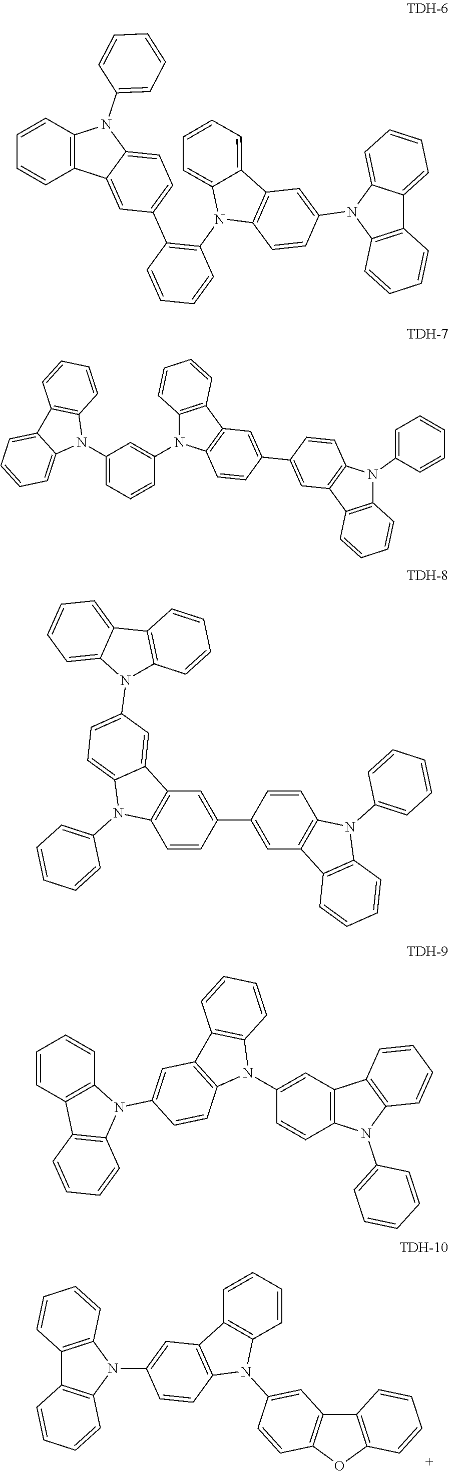 [SMILES: c1ccc(-n2c3ccccc3c3cc(-c4ccccc4-n4c5ccccc5c5cc(-n6c7ccccc7c7ccccc76)ccc54)ccc32)cc1 ; c1ccc(-n2c3ccccc3c3cc(-c4ccc5c(c4)c4ccccc4n5-c4cccc(-n5c6ccccc6c6ccccc65)c4)ccc32)cc1 ; c1ccc(-n2c3ccccc3c3cc(-c4ccc5c(c4)c4cc(-n6c7ccccc7c7ccccc76)ccc4n5-c4ccccc4)ccc32)cc1 ; c1ccc(-n2c3ccccc3c3cc(-n4c5ccccc5c5cc(-n6c7ccccc7c7ccccc76)ccc54)ccc32)cc1 ; c1ccc2c(c1)oc1ccc(-n3c4ccccc4c4cc(-n5c6ccccc6c6ccccc65)ccc43)cc12]

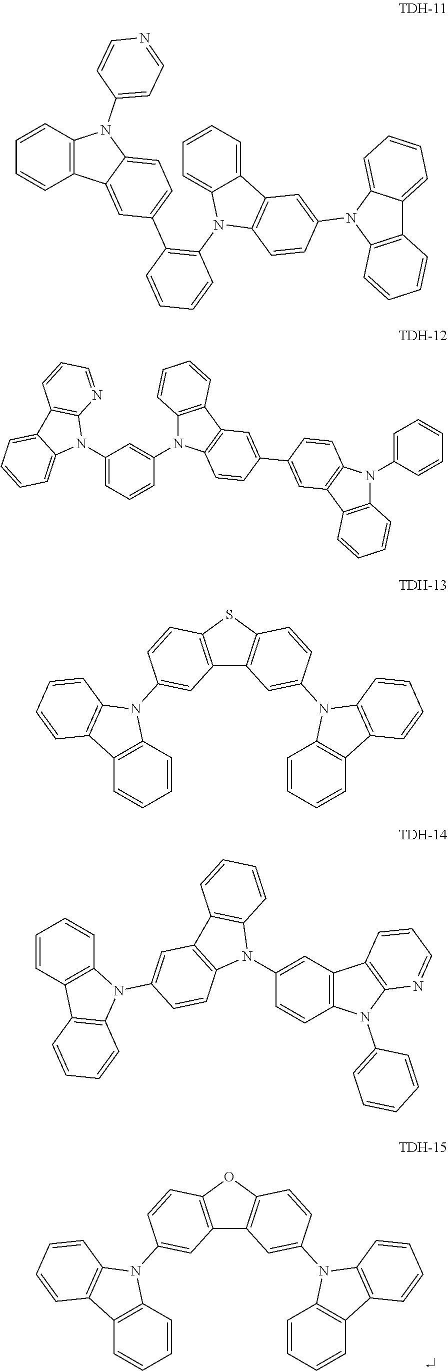 [SMILES: c1ccc(-n2c3ccccc3c3cc(-n4c5ccccc5c5ccccc54)ccc32)c(-c2ccc3c(c2)c2ccccc2n3-c2ccncc2)c1 ; c1ccc(-n2c3ccccc3c3cc(-c4ccc5c(c4)c4ccccc4n5-c4cccc(-n5c6ccccc6c6cccnc65)c4)ccc32)cc1 ; c1ccc2c(c1)c1ccccc1n2-c1ccc2sc3ccc(-n4c5ccccc5c5ccccc54)cc3c2c1 ; c1ccc(-n2c3ccc(-n4c5ccccc5c5cc(-n6c7ccccc7c7ccccc76)ccc54)cc3c3cccnc32)cc1 ; c1ccc2c(c1)c1ccccc1n2-c1ccc2oc3ccc(-n4c5ccccc5c5ccccc54)cc3c2c1]

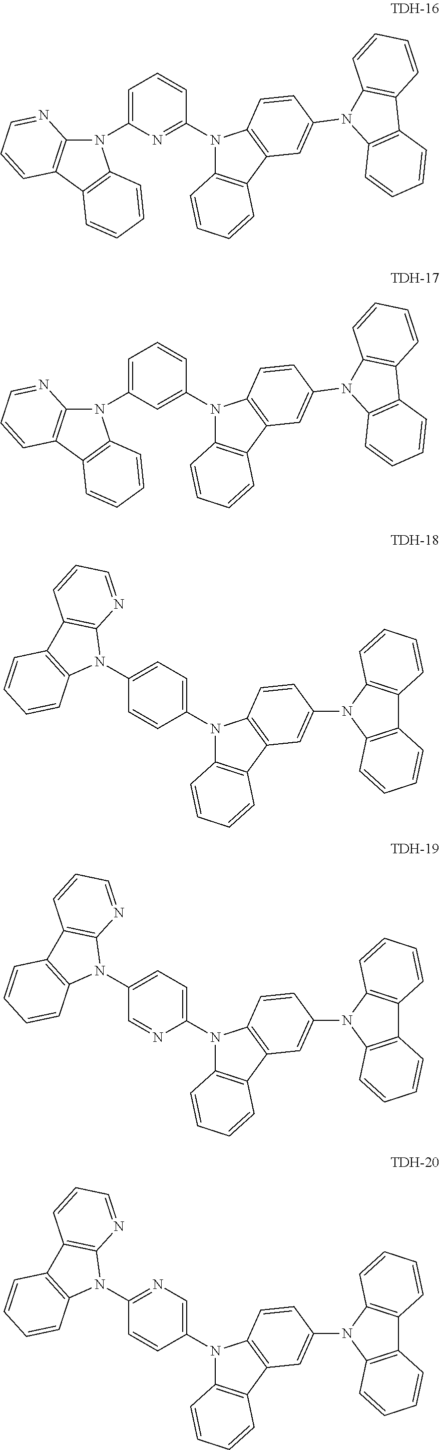 [SMILES: c1cc(-n2c3ccccc3c3cc(-n4c5ccccc5c5ccccc54)ccc32)nc(-n2c3ccccc3c3cccnc32)c1 ; c1cc(-n2c3ccccc3c3cc(-n4c5ccccc5c5ccccc54)ccc32)cc(-n2c3ccccc3c3cccnc32)c1 ; c1ccc2c(c1)c1ccccc1n2-c1ccc2c(c1)c1ccccc1n2-c1ccc(-n2c3ccccc3c3cccnc32)cc1 ; c1ccc2c(c1)c1ccccc1n2-c1ccc2c(c1)c1ccccc1n2-c1ccc(-n2c3ccccc3c3cccnc32)cn1 ; c1ccc2c(c1)c1ccccc1n2-c1ccc2c(c1)c1ccccc1n2-c1ccc(-n2c3ccccc3c3cccnc32)nc1]

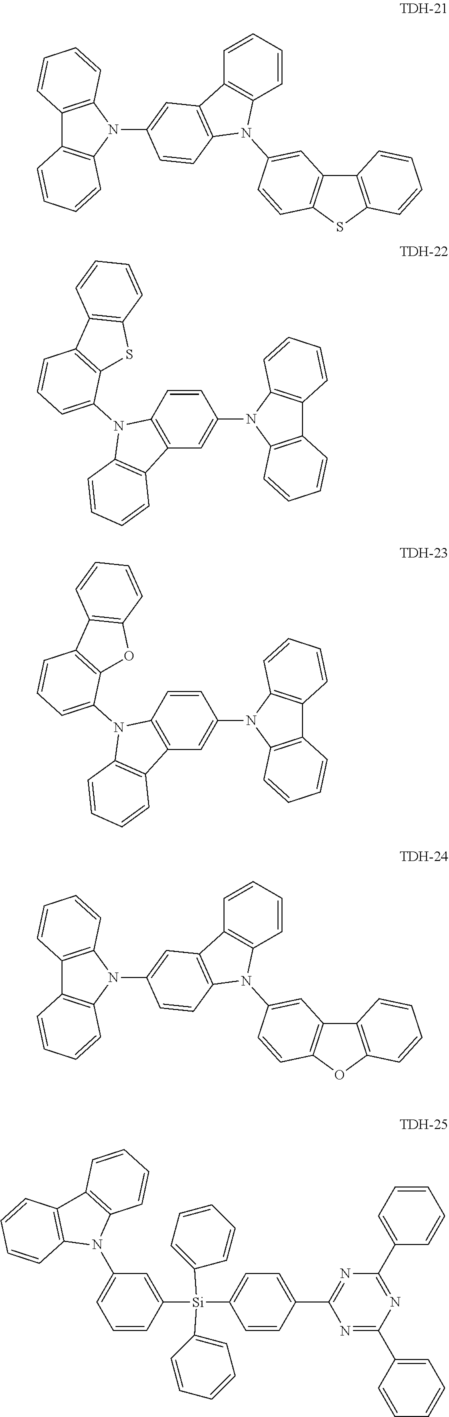

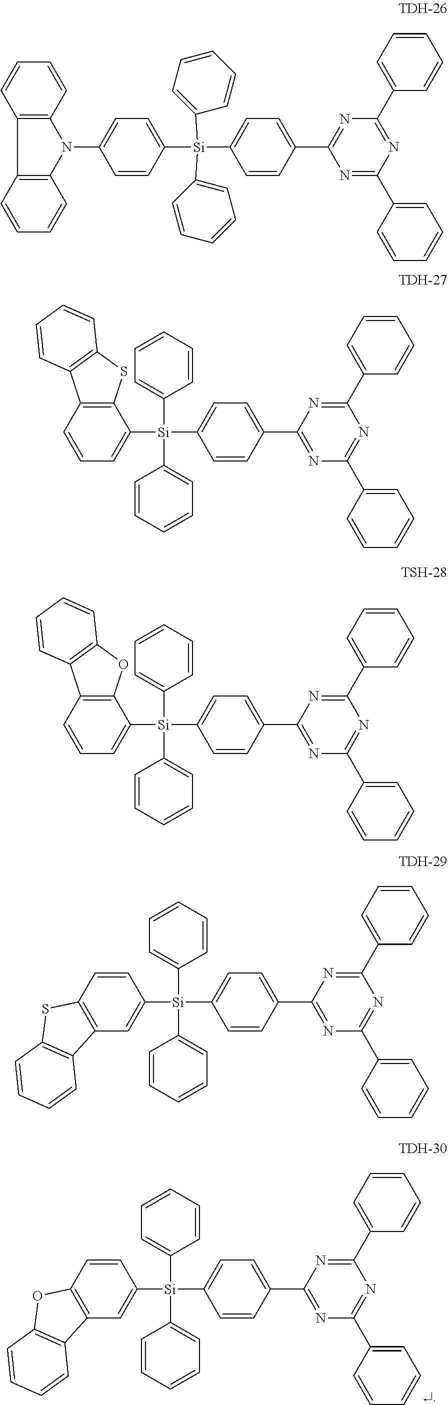 [SMILES: c1ccc(-c2nc(-c3ccccc3)nc(-c3ccc([Si](c4ccccc4)(c4ccccc4)c4ccc(-n5c6ccccc6c6ccccc65)cc4)cc3)n2)cc1 ; c1ccc(-c2nc(-c3ccccc3)nc(-c3ccc([Si](c4ccccc4)(c4ccccc4)c4cccc5c4sc4ccccc45)cc3)n2)cc1 ; c1ccc(-c2nc(-c3ccccc3)nc(-c3ccc([Si](c4ccccc4)(c4ccccc4)c4cccc5c4oc4ccccc45)cc3)n2)cc1 ; c1ccc(-c2nc(-c3ccccc3)nc(-c3ccc([Si](c4ccccc4)(c4ccccc4)c4ccc5sc6ccccc6c5c4)cc3)n2)cc1 ; c1ccc(-c2nc(-c3ccccc3)nc(-c3ccc([Si](c4ccccc4)(c4ccccc4)c4ccc5oc6ccccc6c5c4)cc3)n2)cc1]

In an optional embodiment, the TADF sensitizer is selected from any one or a combination of at least two of the following compounds TDE1 to TDE37 (such as a combination of TDE3 and TDE8, a combination of TDE25 and TDE9 or a combination of TDE18, TDE21 and TDE35):

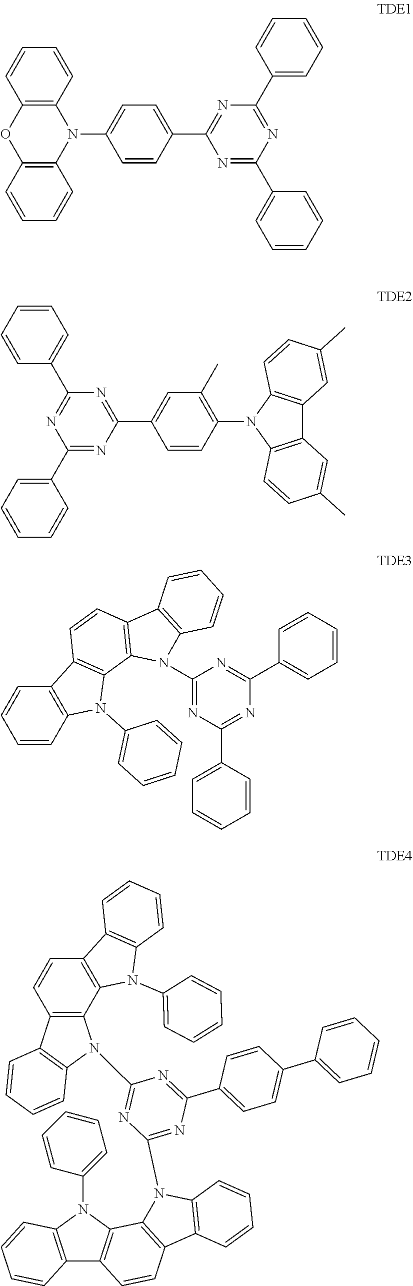 [SMILES: c1ccc(-c2nc(-c3ccccc3)nc(-c3ccc(N4c5ccccc5Oc5ccccc54)cc3)n2)cc1 ; Cc1ccc2c(c1)c1cc(C)ccc1n2-c1ccc(-c2nc(-c3ccccc3)nc(-c3ccccc3)n2)cc1C ; c1ccc(-c2nc(-c3ccccc3)nc(-n3c4ccccc4c4ccc5c6ccccc6n(-c6ccccc6)c5c43)n2)cc1 ; c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1]

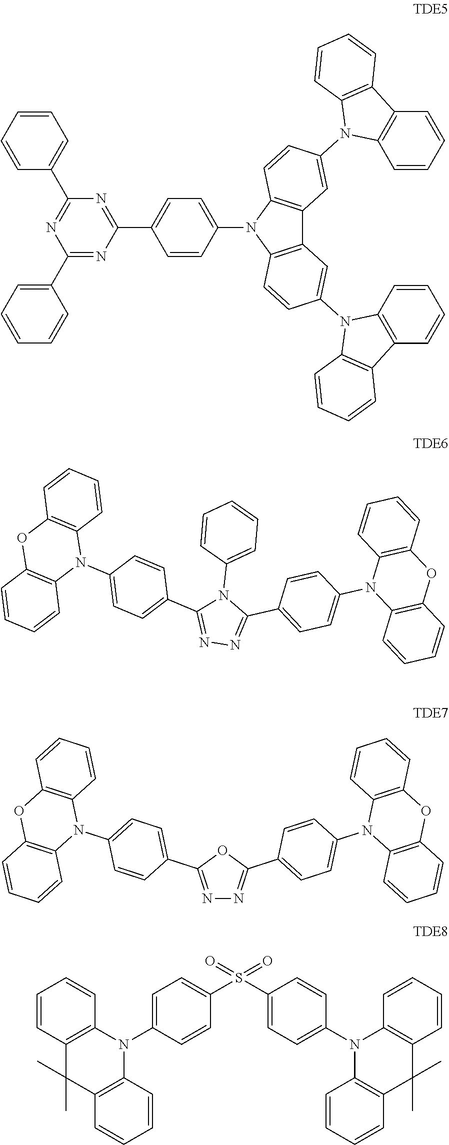 [SMILES: c1ccc(-c2nc(-c3ccccc3)nc(-c3ccc(-n4c5ccc(-n6c7ccccc7c7ccccc76)cc5c5cc(-n6c7ccccc7c7ccccc76)ccc54)cc3)n2)cc1 ; c1ccc(-n2c(-c3ccc(N4c5ccccc5Oc5ccccc54)cc3)nnc2-c2ccc(N3c4ccccc4Oc4ccccc43)cc2)cc1 ; c1ccc2c(c1)Oc1ccccc1N2c1ccc(-c2nnc(-c3ccc(N4c5ccccc5Oc5ccccc54)cc3)o2)cc1 ; CC1(C)c2ccccc2N(c2ccc(S(=O)(=O)c3ccc(N4c5ccccc5C(C)(C)c5ccccc54)cc3)cc2)c2ccccc21]

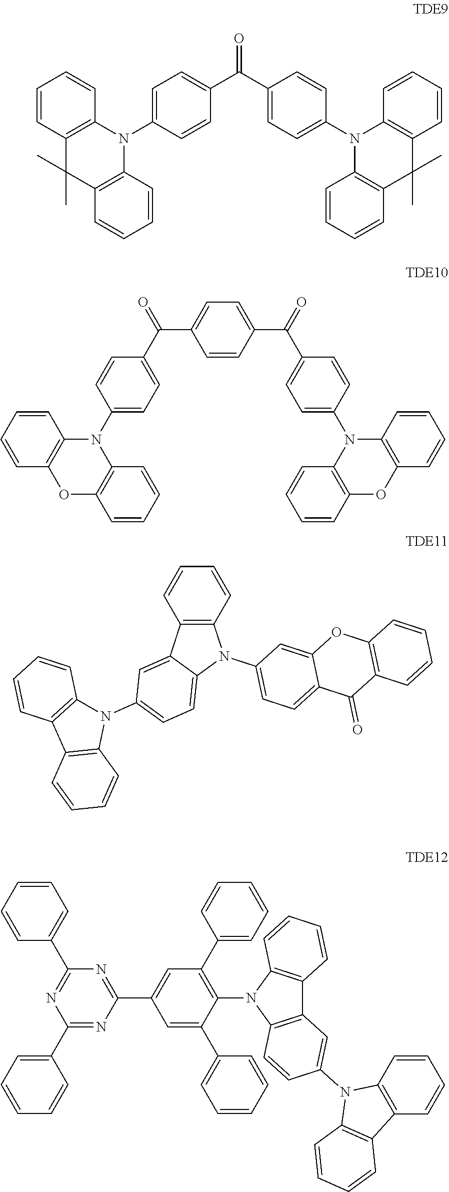 [SMILES: CC1(C)c2ccccc2N(c2ccc(C(=O)c3ccc(N4c5ccccc5C(C)(C)c5ccccc54)cc3)cc2)c2ccccc21 ; O=C(c1ccc(C(=O)c2ccc(N3c4ccccc4Oc4ccccc43)cc2)cc1)c1ccc(N2c3ccccc3Oc3ccccc32)cc1 ; O=c1c2ccccc2oc2cc(-n3c4ccccc4c4cc(-n5c6ccccc6c6ccccc65)ccc43)ccc12 ; c1ccc(-c2nc(-c3ccccc3)nc(-c3cc(-c4ccccc4)c(-n4c5ccccc5c5cc(-n6c7ccccc7c7ccccc76)ccc54)c(-c4ccccc4)c3)n2)cc1]

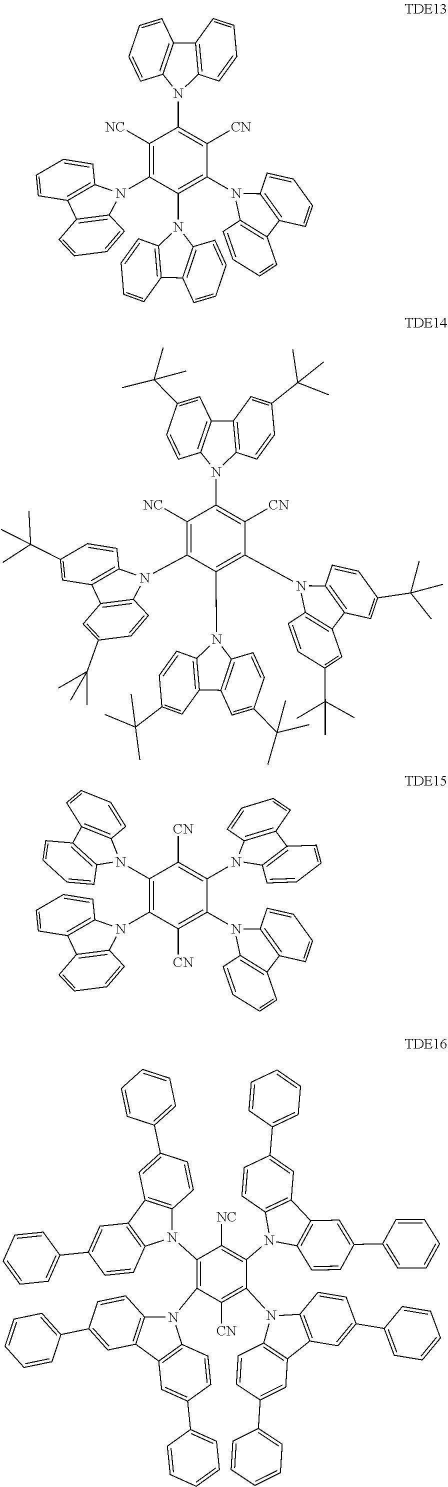

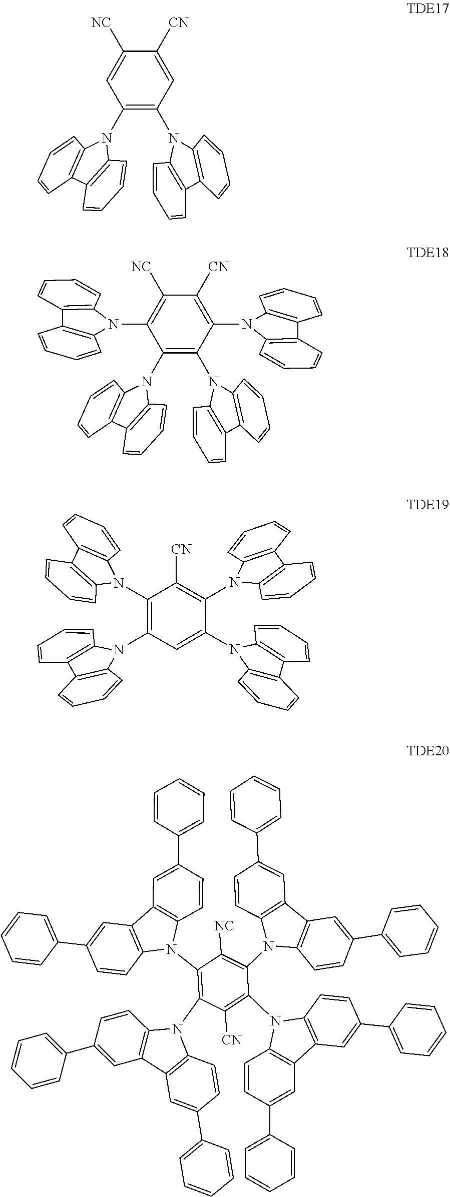

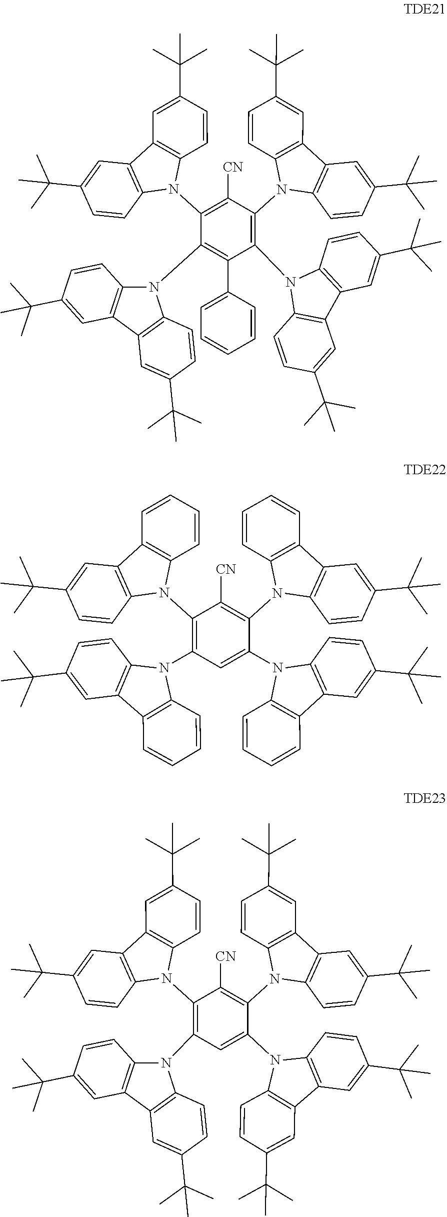

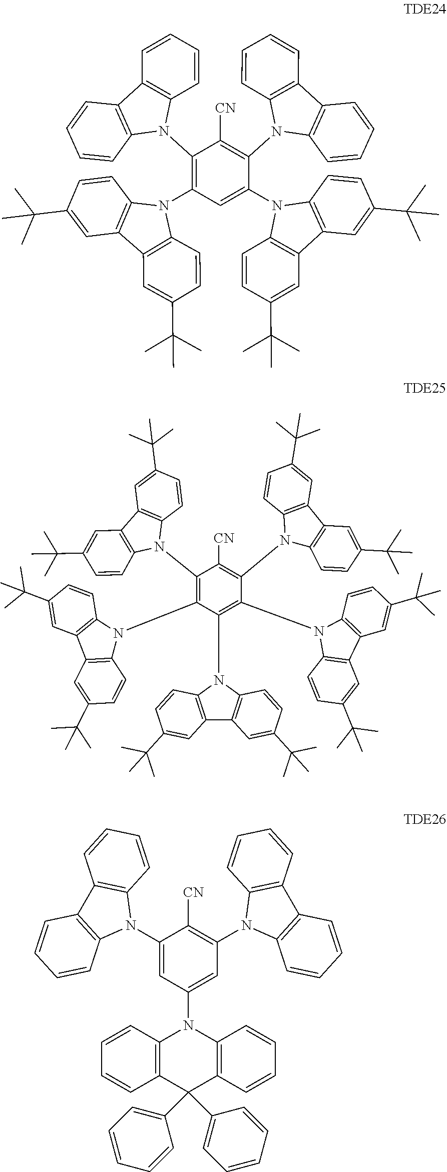

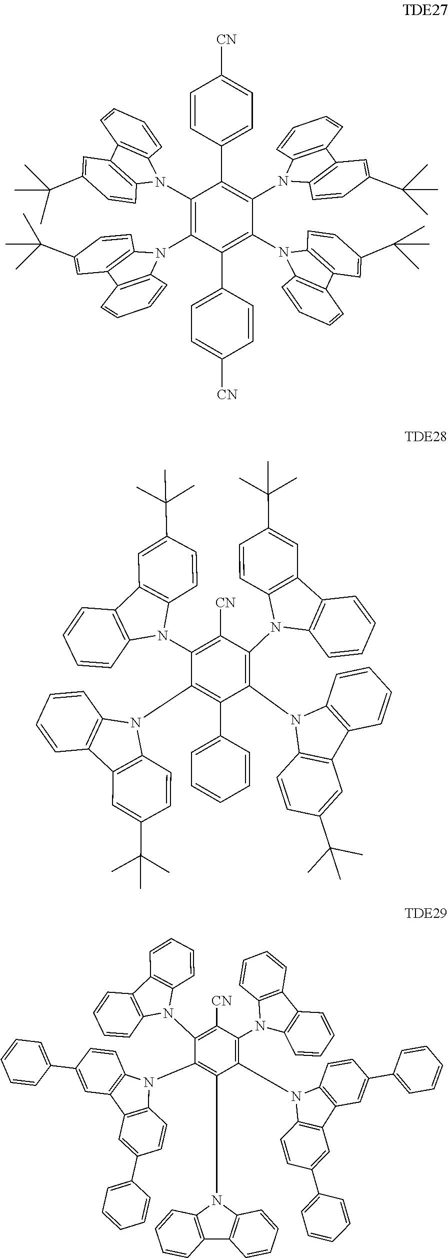

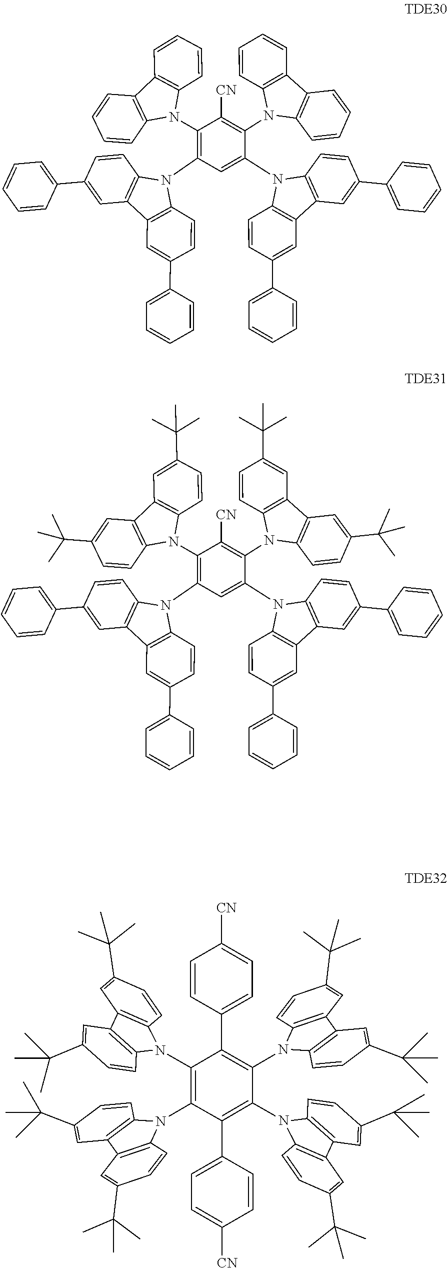

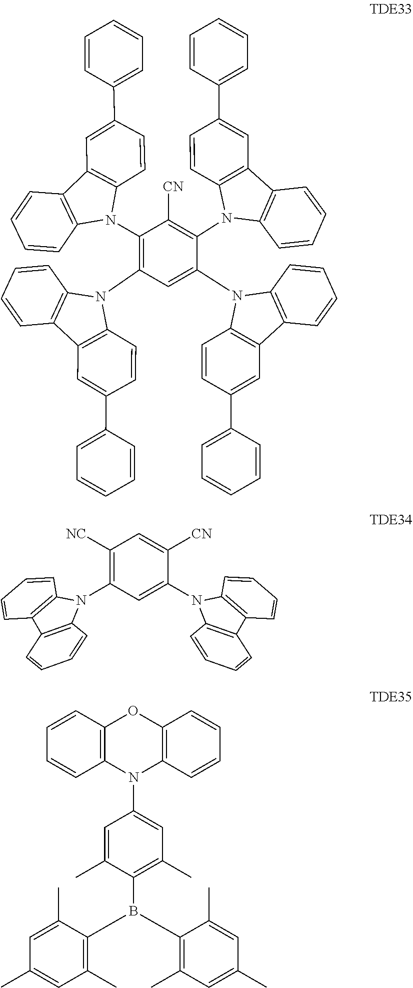

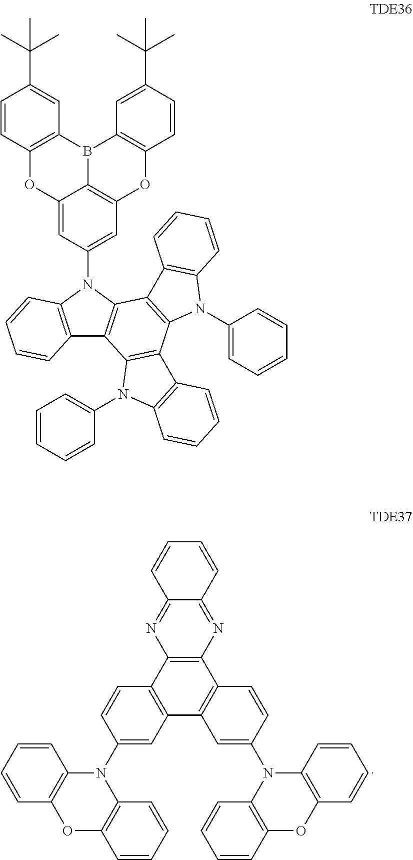 [SMILES: CC(C)(C)c1ccc2c(c1)B1c3cc(C(C)(C)C)ccc3Oc3cc(-n4c5ccccc5c5c6c(c7ccccc7n6-c6ccccc6)c6c(c7ccccc7n6-c6ccccc6)c54)cc(c31)O2 ; c1ccc2c(c1)Oc1ccccc1N2c1ccc2c(c1)c1cc(N3c4ccccc4Oc4ccccc43)ccc1c1nc3ccccc3nc21]

In an optional embodiment, a mass of the fluorescent dye accounts for 0.1% to 10% of a total mass of the EML (which can be referred to as a doping concentration for short), preferably 0.2%, 0.3%, 0.4%, 0.5%, 0.6%, 0.8%, 1%, 1.5%, 2%, 2.5%, 3%, 3.5%, 4%, 4.5%, 5%, 5.5%, 6%, 6.5%, 7%, 7.5%, 8%, 8.5%, 9%, 9.5% or the like, and further preferably 1%.

For the fluorescent dye having the specific structure selected in the present disclosure, the doping concentration of the fluorescent dye in the EML is further optimized. Within the above concentration range, the performance of the TASF device is further improved. If the doping amount is too low, less dye molecules participate in light emission, and the device efficiency is relatively low; if the doping amount is too high, the quenching of the dye in the device is exacerbated, resulting in poorer device efficiency, drive voltage and device service life.

In an optional embodiment, a mass of the TADF sensitizer accounts for 1% to 99% of the total mass of the EML, preferably 2%, 5%, 10%, 15%, 20%, 25%, 30%, 35%, 40%, 45%, 50%, 55%, 60%, 65%, 70%, 75%, 80%, 85%, 90%, 95% or the like, and further preferably 10% to 50%.

In an optional embodiment, the organic layer further comprises any one or a combination of at least two of a hole injection layer (HIL), a hole transport layer (HTL), a hole blocking layer (HBL), an electron blocking layer (EBL), an electron transport layer (ETL) or an electron injection layer (EIL).

Embodiments of the present disclosure further provide a display apparatus. The display apparatus comprises the organic electroluminescent device as provided above. Specifically, the display apparatus can be an organic light-emitting diode (OLED) display panel and any product or component having a display function such as a television, a digital camera, a mobile phone and a tablet computer including the display panel. The advantages of the display apparatus are the same as those of the above organic electroluminescent device relative to the existing art, which are not repeated here.

It is to be understood that the first electrode and the second electrode in the present disclosure represent an anode and a cathode, respectively.

The hole transport region, the electron transport region, the anode and the cathode of the present disclosure are described below. The hole transport region is located between the anode and the EML. The hole transport region is an HTL having a monolayer structure, which comprises a monolayer HTL containing only one compound and a monolayer HTL containing a plurality of compounds. The hole transport region can also be a multilayer structure including at least two of the HIL, the HTL or the EBL.

A material of the hole transport region (including the HIL and the HTL) can be selected from, but is not limited to, phthalocyanine derivatives such as CuPc, and conductive polymers or polymers containing a conductive dopant such as poly(p-phenylenevinylene), polyaniline/dodecylbenzenesulfonic acid (Pani/DBSA), poly(3,4-ethylenedioxythiophene)/poly(sodium 4-styrenesulfonate) (PEDOT/PSS), polyaniline/camphorsulfonic acid (Pani/CSA), polyaniline/poly(sodium 4-styrenesulfonate) (Pani/PSS) and aromatic amine derivatives.

The aromatic amine derivatives are compounds represented by the following HT-1 to HT-34. If the material of the hole transport region is an aromatic amine derivative, the aromatic amine derivative can be one or a combination of at least two of the compounds represented by HT-1 to HT-34 (such as a combination of HT-5 and HT-8 or a combination of HT-11, HT-12 and HT-15).

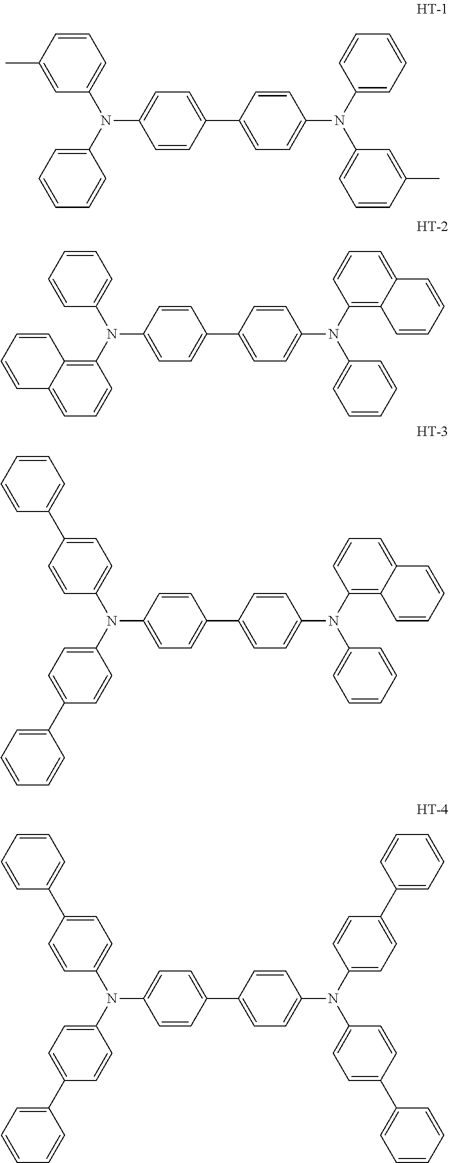

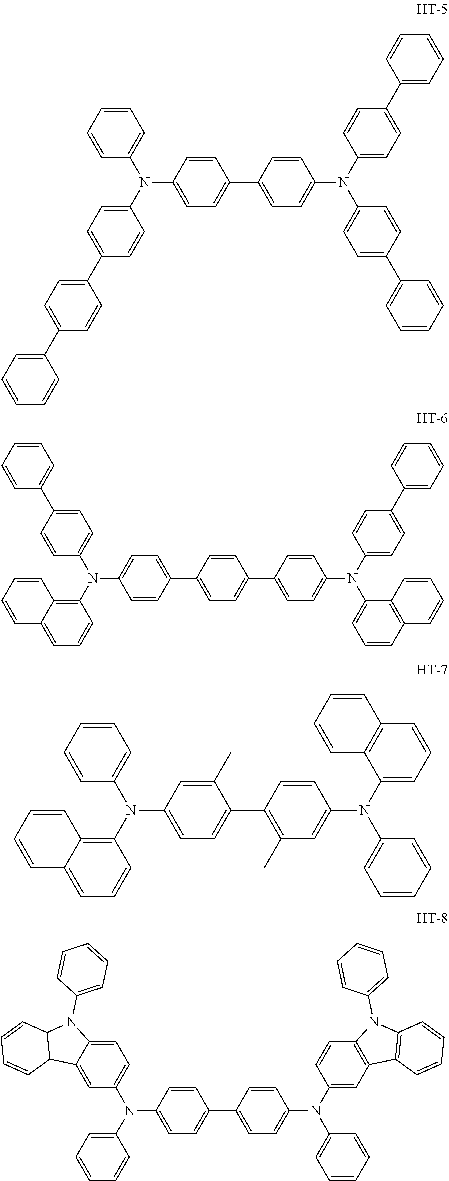 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(N(c3ccc(-c4ccc(-c5ccc(N(c6ccc(-c7ccccc7)cc6)c6cccc7ccccc67)cc5)cc4)cc3)c3cccc4ccccc34)cc2)cc1 ; Cc1cc(N(c2ccccc2)c2cccc3ccccc23)ccc1-c1ccc(N(c2ccccc2)c2cccc3ccccc23)cc1C ; C1=CC2c3cc(N(c4ccccc4)c4ccc(-c5ccc(N(c6ccccc6)c6ccc7c(c6)c6ccccc6n7-c6ccccc6)cc5)cc4)ccc3N(c3ccccc3)C2C=C1]

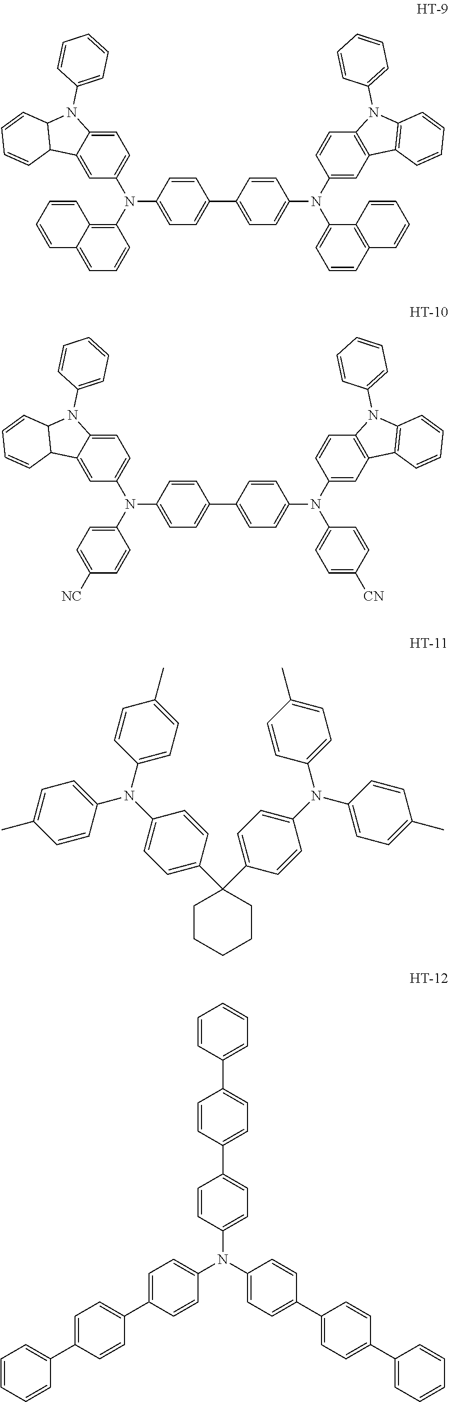

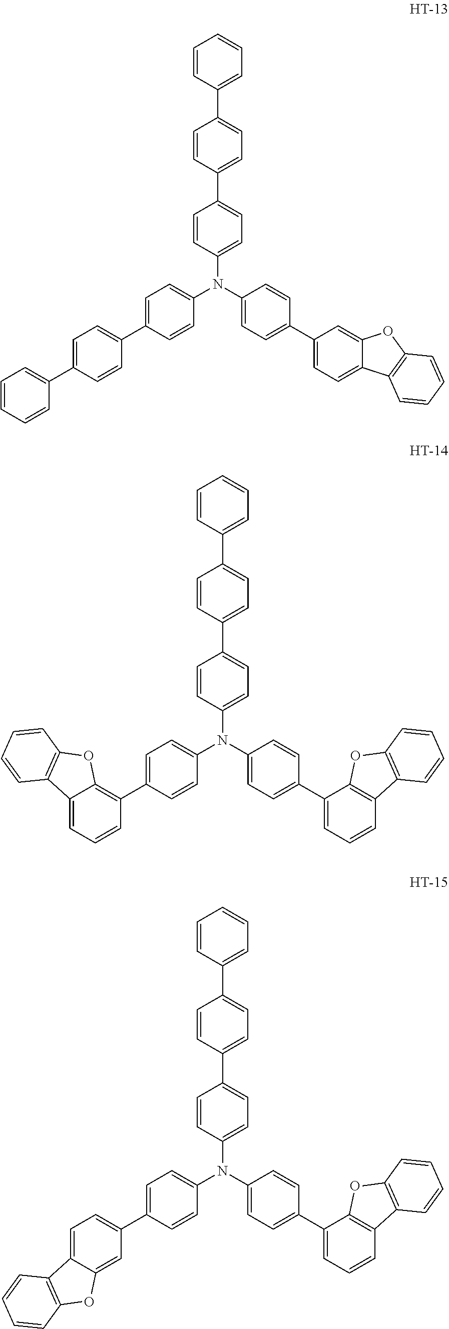 [SMILES: c1ccc(-c2ccc(-c3ccc(N(c4ccc(-c5ccc(-c6ccccc6)cc5)cc4)c4ccc(-c5ccc6c(c5)oc5ccccc56)cc4)cc3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(-c3ccc(N(c4ccc(-c5ccc6c(c5)oc5ccccc56)cc4)c4ccc(-c5cccc6c5oc5ccccc56)cc4)cc3)cc2)cc1]

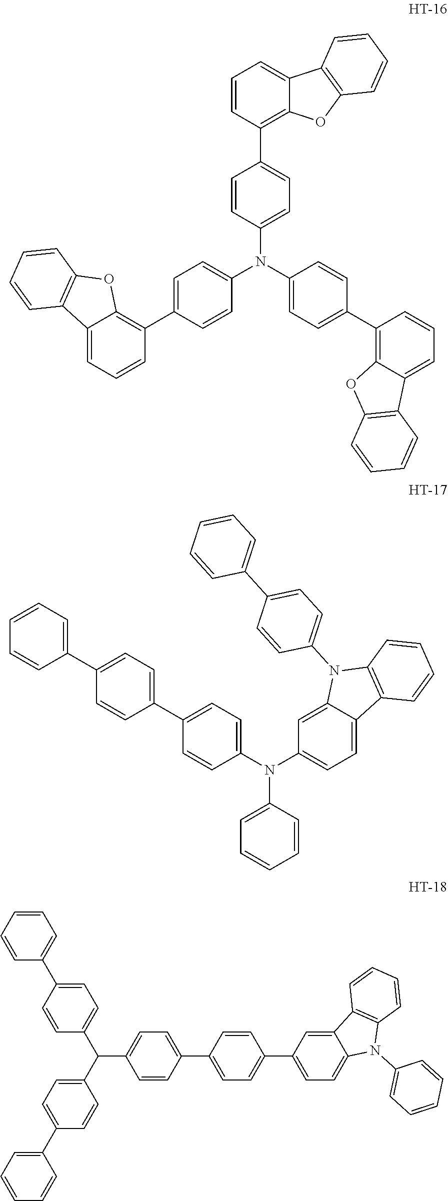 [SMILES: c1ccc2c(c1)oc1c(-c3ccc(N(c4ccc(-c5cccc6c5oc5ccccc56)cc4)c4ccc(-c5cccc6c5oc5ccccc56)cc4)cc3)cccc12 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(C(c3ccc(-c4ccccc4)cc3)c3ccc(-c4ccc(-c5ccc6c(c5)c5ccccc5n6-c5ccccc5)cc4)cc3)cc2)cc1]

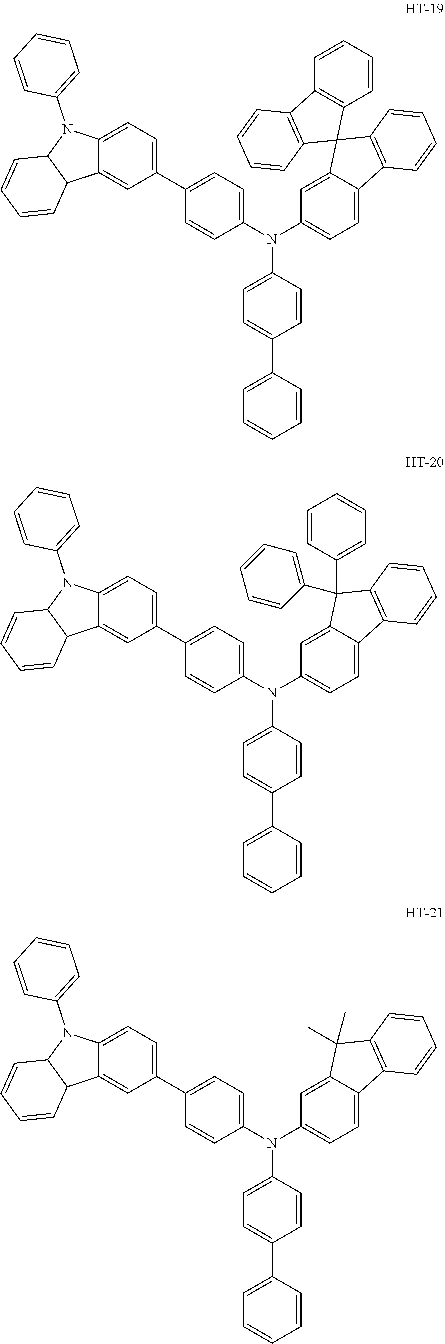 [SMILES: C1=CC2c3cc(-c4ccc(N(c5ccc(-c6ccccc6)cc5)c5ccc6c(c5)C5(c7ccccc7-c7ccccc75)c5ccccc5-6)cc4)ccc3N(c3ccccc3)C2C=C1 ; C1=CC2c3cc(-c4ccc(N(c5ccc(-c6ccccc6)cc5)c5ccc6c(c5)C(c5ccccc5)(c5ccccc5)c5ccccc5-6)cc4)ccc3N(c3ccccc3)C2C=C1 ; CC1(C)c2ccccc2-c2ccc(N(c3ccc(-c4ccccc4)cc3)c3ccc(-c4ccc5c(c4)C4C=CC=CC4N5c4ccccc4)cc3)cc21]

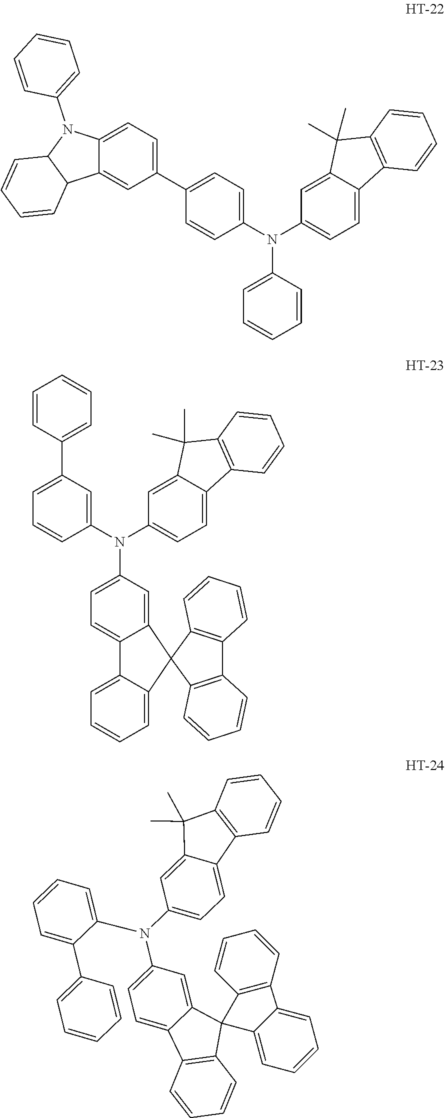

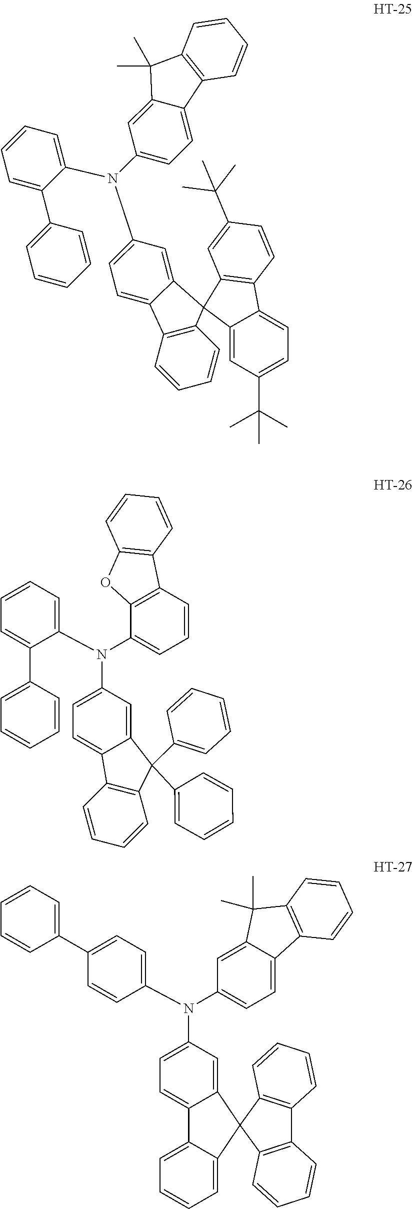 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; c1ccc(-c2ccccc2N(c2ccc3c(c2)C(c2ccccc2)(c2ccccc2)c2ccccc2-3)c2cccc3c2oc2ccccc23)cc1 ; CC1(C)c2ccccc2-c2ccc(N(c3ccc(-c4ccccc4)cc3)c3ccc4c(c3)C3(c5ccccc5-c5ccccc53)c3ccccc3-4)cc21]

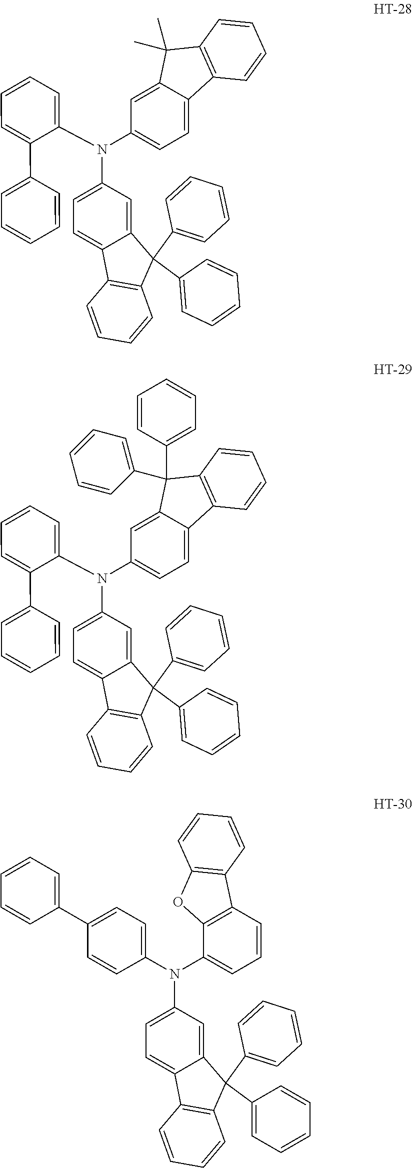 [SMILES: CC1(C)c2ccccc2-c2ccc(N(c3ccc4c(c3)C(c3ccccc3)(c3ccccc3)c3ccccc3-4)c3ccccc3-c3ccccc3)cc21 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; c1ccc(-c2ccc(N(c3ccc4c(c3)C(c3ccccc3)(c3ccccc3)c3ccccc3-4)c3cccc4c3oc3ccccc34)cc2)cc1]

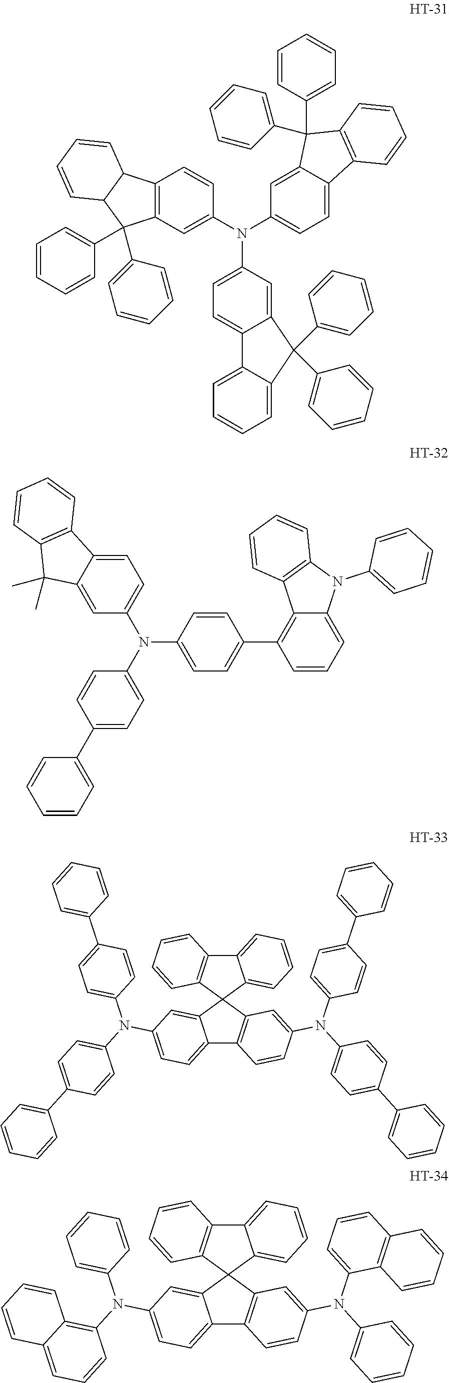 [SMILES: C1=CC2c3ccc(N(c4ccc5c(c4)C(c4ccccc4)(c4ccccc4)c4ccccc4-5)c4ccc5c(c4)C(c4ccccc4)(c4ccccc4)c4ccccc4-5)cc3C(c3ccccc3)(c3ccccc3)C2C=C1 ; CC1(C)c2ccccc2-c2ccc(N(c3ccc(-c4ccccc4)cc3)c3ccc(-c4cccc5c4c4ccccc4n5-c4ccccc4)cc3)cc21 ; c1ccc(-c2ccc(N(c3ccc(-c4ccccc4)cc3)c3ccc4c(c3)C3(c5ccccc5-c5ccccc53)c3cc(N(c5ccc(-c6ccccc6)cc5)c5ccc(-c6ccccc6)cc5)ccc3-4)cc2)cc1 ; c1ccc(N(c2ccc3c(c2)C2(c4ccccc4-c4ccccc42)c2cc(N(c4ccccc4)c4cccc5ccccc45)ccc2-3)c2cccc3ccccc23)cc1]

The HIL is located between the anode and the HTL. The HIL is a single compound material or a combination of a plurality of compounds. For example, the HIL uses one or at least two compounds of HT-1 to HT-34 described above, or one or a combination of at least two of HI-1 to HI-3 described below; and the HIL also uses one or a combination of at least two of HT-1 to HT-34 doped with one or a combination of at least two of HI-1 to HI-3 described below (such as a combination of HI-1 and HI-2).

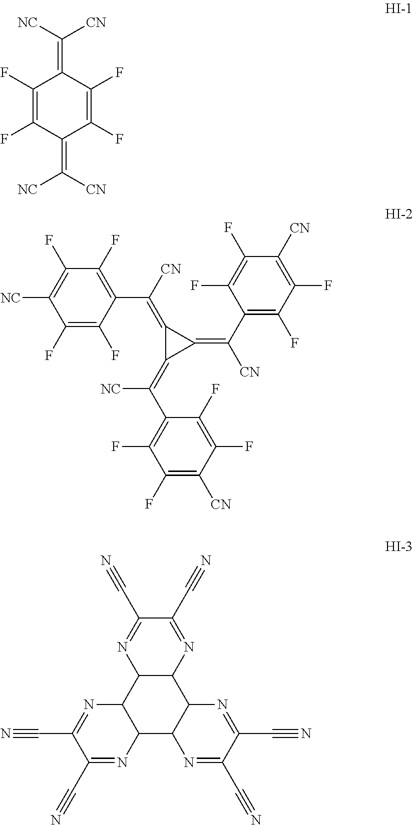 [SMILES: N#CC(C#N)=c1c(F)c(F)c(=C(C#N)C#N)c(F)c1F ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC1=NC2C3N=C(C#N)C(C#N)=NC3C3N=C(C#N)C(C#N)=NC3C2N=C1C#N]

The electron transport region is an ETL having a monolayer structure, which comprises a monolayer ETL containing only one compound and a monolayer ETL containing a plurality of compounds. The electron transport region may also be a multilayer structure including at least two of the EIL, the ETL or the HBL.

Further, in the embodiment of the present disclosure, a material of the ETL may be selected from, but is not limited to, one or a combination of at least two of ET-1 to ET-65 listed below (such as a combination of ET-2 and ET-9 or a combination of ET-12, ET-17 and ET-33).

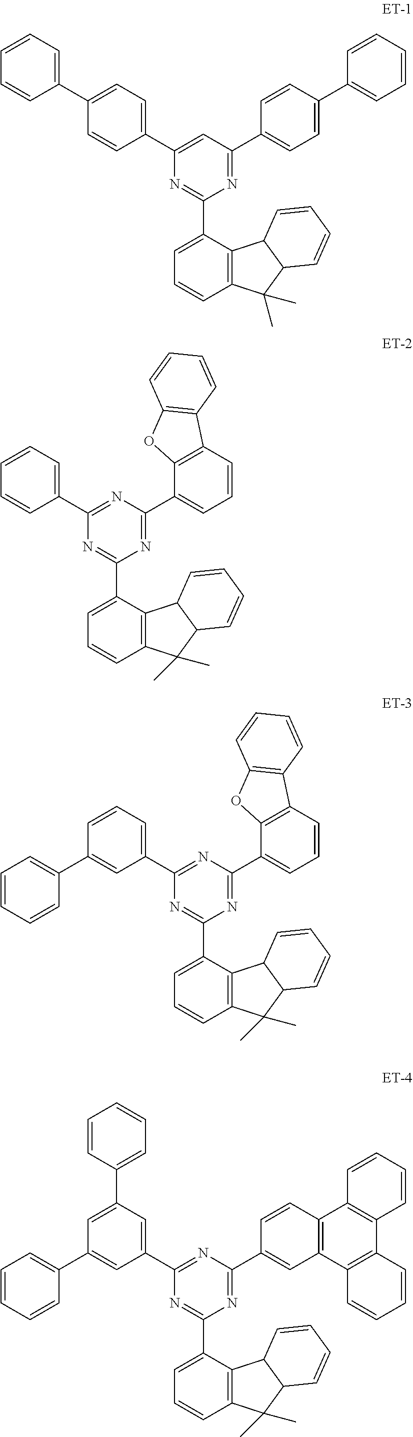 [SMILES: CC1(C)c2cccc(-c3nc(-c4ccc(-c5ccccc5)cc4)cc(-c4ccc(-c5ccccc5)cc4)n3)c2C2C=CC=CC21 ; CC1(C)c2cccc(-c3nc(-c4ccccc4)nc(-c4cccc5c4oc4ccccc45)n3)c2C2C=CC=CC21 ; CC1(C)c2cccc(-c3nc(-c4cccc(-c5ccccc5)c4)nc(-c4cccc5c4oc4ccccc45)n3)c2C2C=CC=CC21 ; CC1(C)c2cccc(-c3nc(-c4cc(-c5ccccc5)cc(-c5ccccc5)c4)nc(-c4ccc5c6ccccc6c6ccccc6c5c4)n3)c2C2C=CC=CC21]

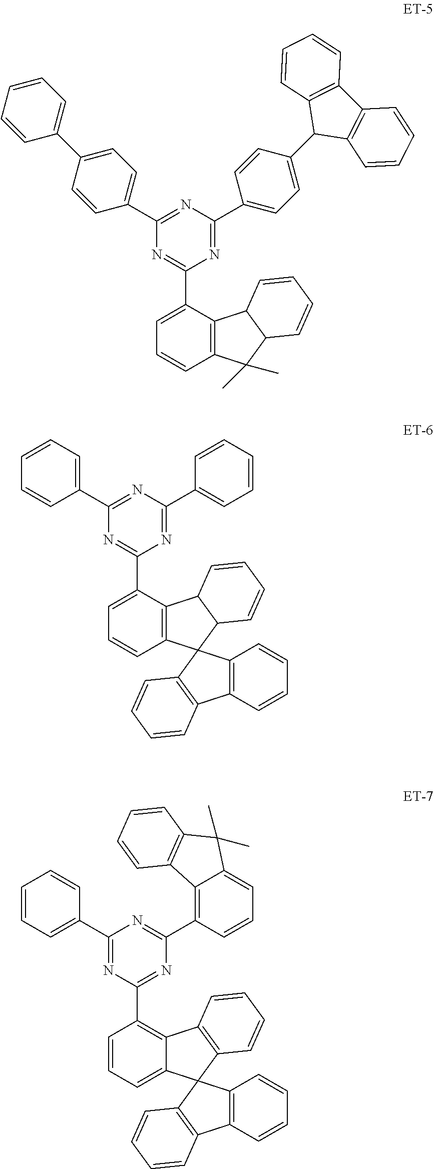 [SMILES: CC1(C)c2cccc(-c3nc(-c4ccc(-c5ccccc5)cc4)nc(-c4ccc(C5c6ccccc6-c6ccccc65)cc4)n3)c2C2C=CC=CC21 ; C1=CC2c3c(-c4nc(-c5ccccc5)nc(-c5ccccc5)n4)cccc3C3(c4ccccc4-c4ccccc43)C2C=C1 ; CC1(C)c2ccccc2-c2c(-c3nc(-c4ccccc4)nc(-c4cccc5c4-c4ccccc4C54c5ccccc5-c5ccccc54)n3)cccc21]

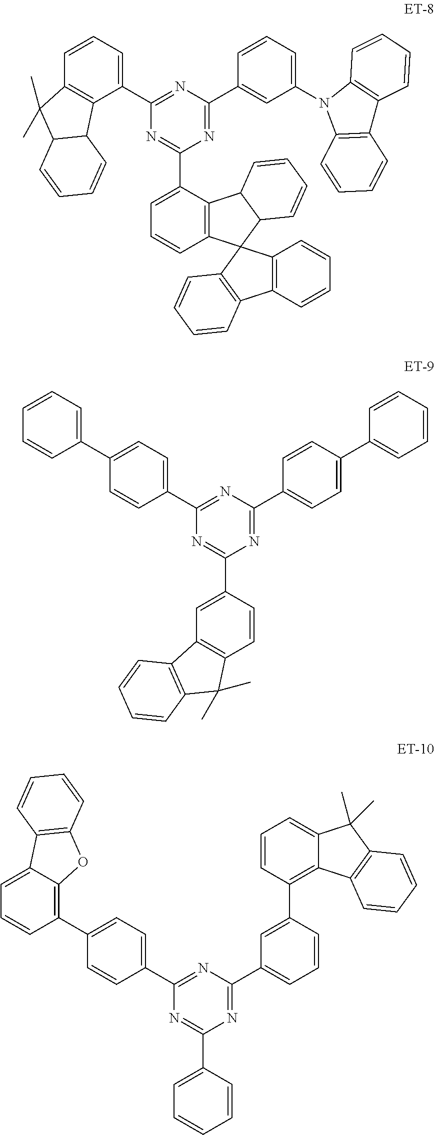 [SMILES: CC1(C)c2cccc(-c3nc(-c4cccc(-n5c6ccccc6c6ccccc65)c4)nc(-c4cccc5c4C4C=CC=CC4C54c5ccccc5-c5ccccc54)n3)c2C2C=CC=CC21 ; CC1(C)c2ccccc2-c2cc(-c3nc(-c4ccc(-c5ccccc5)cc4)nc(-c4ccc(-c5ccccc5)cc4)n3)ccc21 ; CC1(C)c2ccccc2-c2c(-c3cccc(-c4nc(-c5ccccc5)nc(-c5ccc(-c6cccc7c6oc6ccccc67)cc5)n4)c3)cccc21]

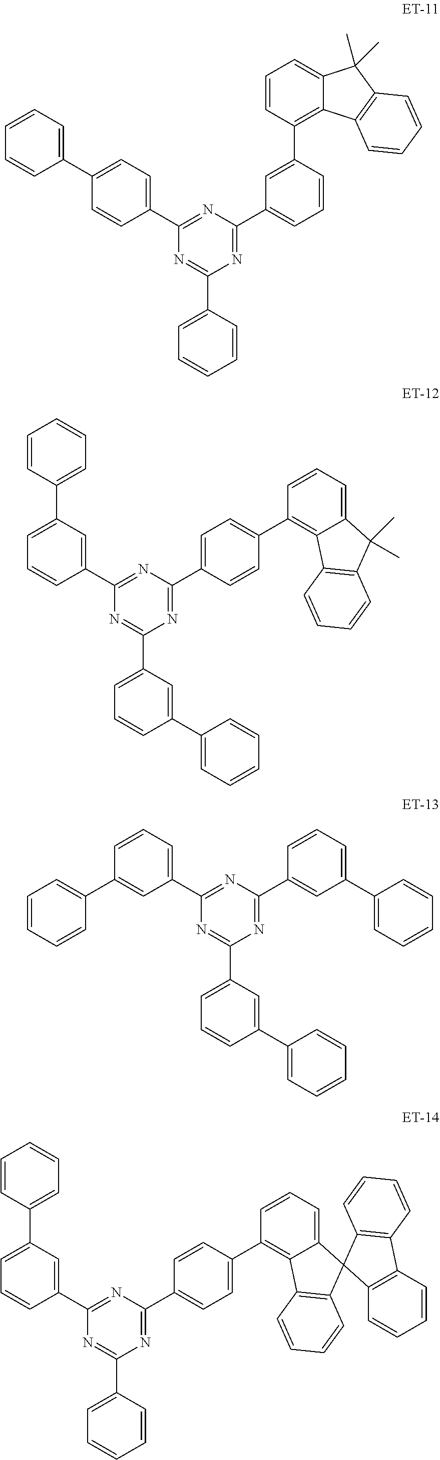 [SMILES: CC1(C)c2ccccc2-c2c(-c3cccc(-c4nc(-c5ccccc5)nc(-c5ccc(-c6ccccc6)cc5)n4)c3)cccc21 ; CC1(C)c2ccccc2-c2c(-c3ccc(-c4nc(-c5cccc(-c6ccccc6)c5)nc(-c5cccc(-c6ccccc6)c5)n4)cc3)cccc21 ; c1ccc(-c2cccc(-c3nc(-c4cccc(-c5ccccc5)c4)nc(-c4cccc(-c5ccccc5)c4)n3)c2)cc1 ; c1ccc(-c2cccc(-c3nc(-c4ccccc4)nc(-c4ccc(-c5cccc6c5-c5ccccc5C65c6ccccc6-c6ccccc65)cc4)n3)c2)cc1]

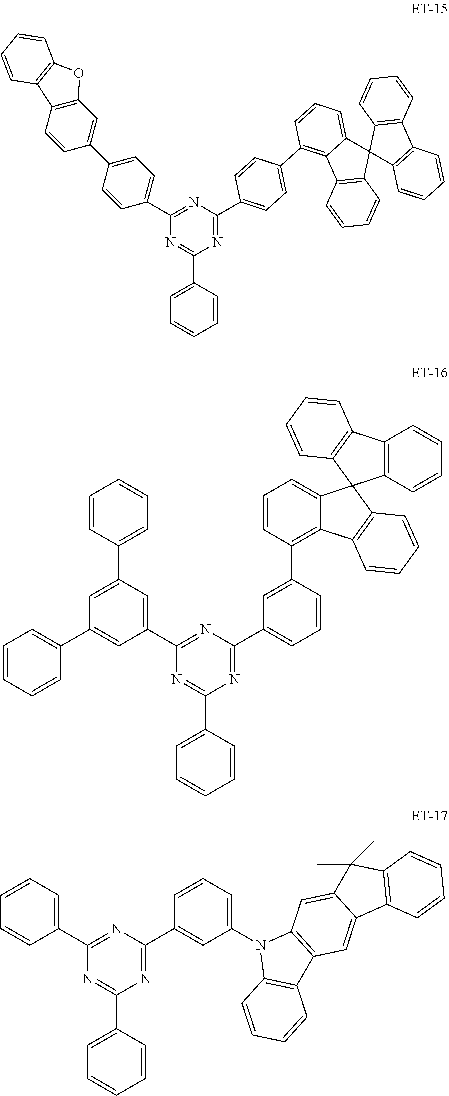 [SMILES: c1ccc(-c2nc(-c3ccc(-c4ccc5c(c4)oc4ccccc45)cc3)nc(-c3ccc(-c4cccc5c4-c4ccccc4C54c5ccccc5-c5ccccc54)cc3)n2)cc1 ; c1ccc(-c2cc(-c3ccccc3)cc(-c3nc(-c4ccccc4)nc(-c4cccc(-c5cccc6c5-c5ccccc5C65c6ccccc6-c6ccccc65)c4)n3)c2)cc1 ; CC1(C)c2ccccc2-c2cc3c4ccccc4n(-c4cccc(-c5nc(-c6ccccc6)nc(-c6ccccc6)n5)c4)c3cc21]

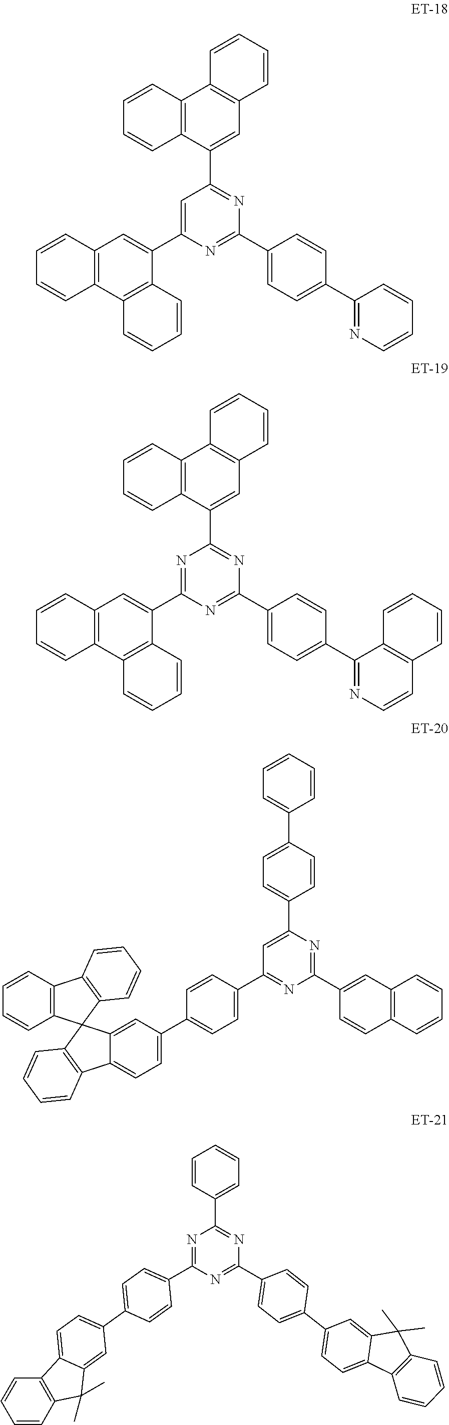 [SMILES: c1ccc(-c2ccc(-c3nc(-c4cc5ccccc5c5ccccc45)cc(-c4cc5ccccc5c5ccccc45)n3)cc2)nc1 ; c1ccc2c(-c3ccc(-c4nc(-c5cc6ccccc6c6ccccc56)nc(-c5cc6ccccc6c6ccccc56)n4)cc3)nccc2c1 ; c1ccc(-c2ccc(-c3cc(-c4ccc(-c5ccc6c(c5)C5(c7ccccc7-c7ccccc75)c5ccccc5-6)cc4)nc(-c4ccc5ccccc5c4)n3)cc2)cc1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

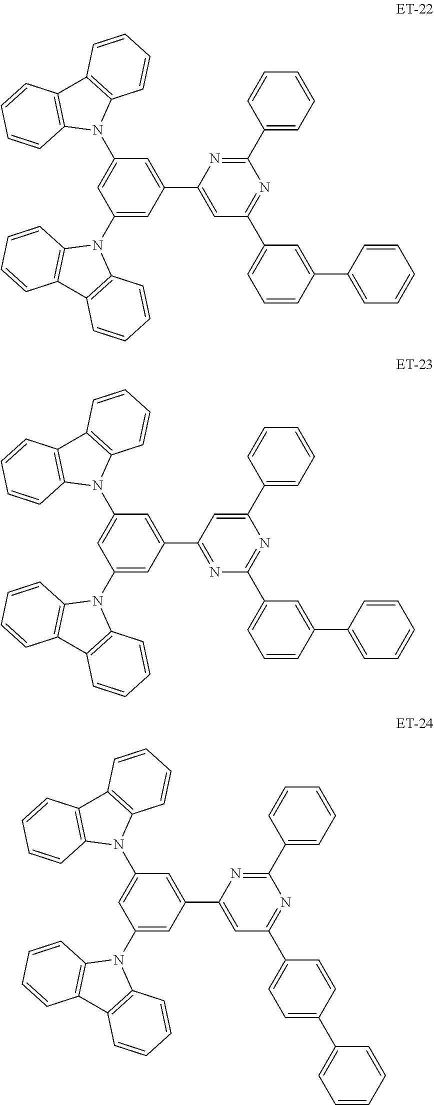 [SMILES: c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2cccc(-c3nc(-c4ccccc4)cc(-c4cc(-n5c6ccccc6c6ccccc65)cc(-n5c6ccccc6c6ccccc65)c4)n3)c2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

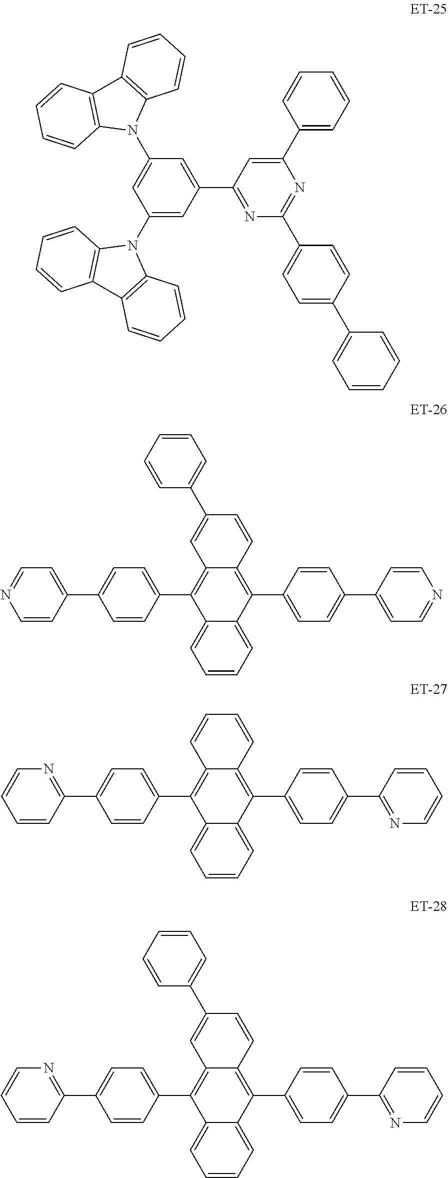

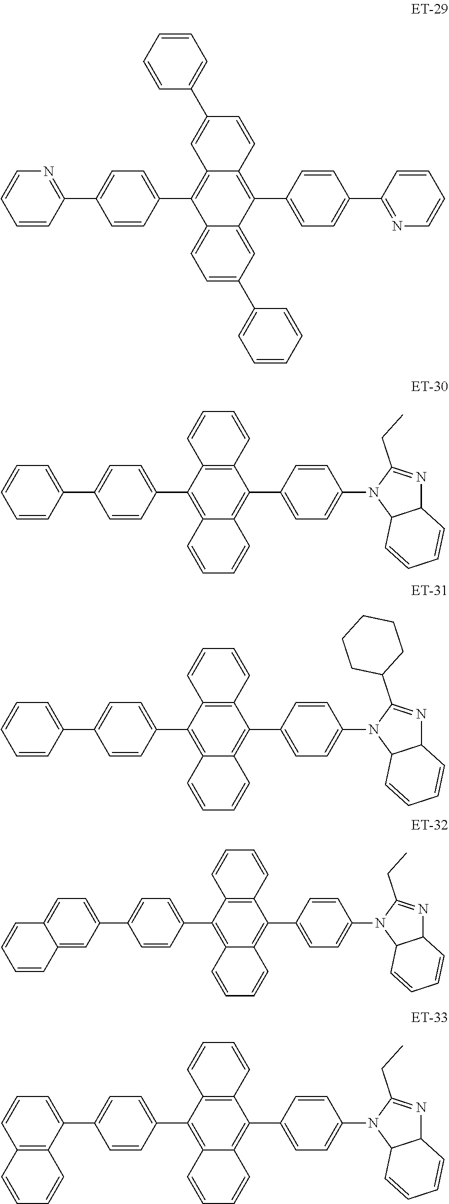

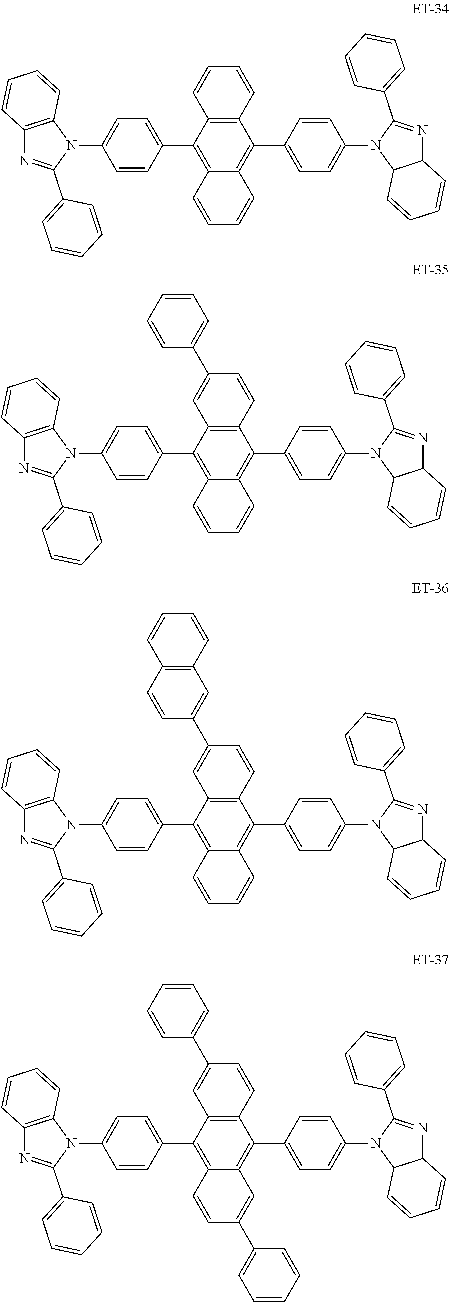 [SMILES: C1=CC2N=C(c3ccccc3)N(c3ccc(-c4c5ccccc5c(-c5ccc(-n6c(-c7ccccc7)nc7ccccc76)cc5)c5ccccc45)cc3)C2C=C1 ; C1=CC2N=C(c3ccccc3)N(c3ccc(-c4c5ccccc5c(-c5ccc(-n6c(-c7ccccc7)nc7ccccc76)cc5)c5cc(-c6ccccc6)ccc45)cc3)C2C=C1 ; C1=CC2N=C(c3ccccc3)N(c3ccc(-c4c5ccccc5c(-c5ccc(-n6c(-c7ccccc7)nc7ccccc76)cc5)c5cc(-c6ccc7ccccc7c6)ccc45)cc3)C2C=C1 ; C1=CC2N=C(c3ccccc3)N(c3ccc(-c4c5ccc(-c6ccccc6)cc5c(-c5ccc(-n6c(-c7ccccc7)nc7ccccc76)cc5)c5ccc(-c6ccccc6)cc45)cc3)C2C=C1]

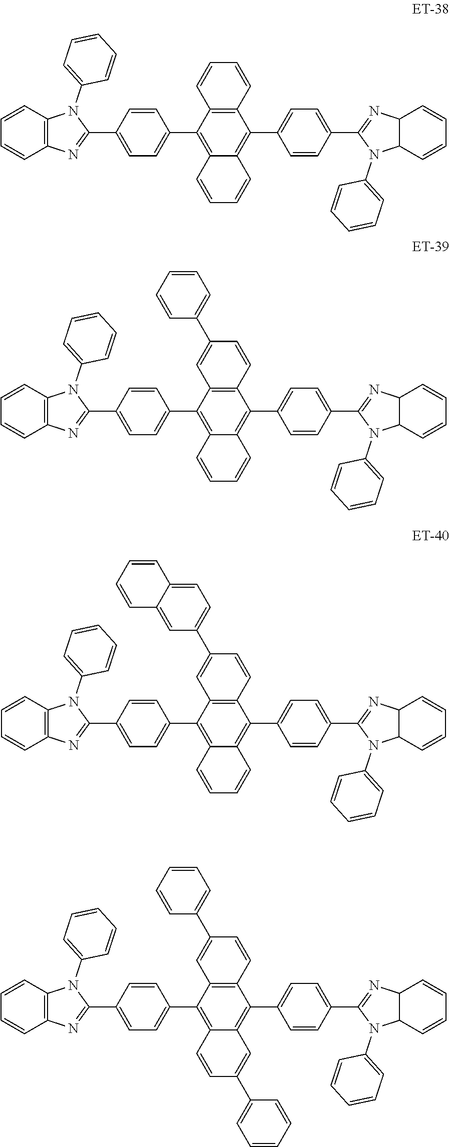 [SMILES: C1=CC2N=C(c3ccc(-c4c5ccccc5c(-c5ccc(-c6nc7ccccc7n6-c6ccccc6)cc5)c5ccccc45)cc3)N(c3ccccc3)C2C=C1 ; C1=CC2N=C(c3ccc(-c4c5ccccc5c(-c5ccc(-c6nc7ccccc7n6-c6ccccc6)cc5)c5cc(-c6ccccc6)ccc45)cc3)N(c3ccccc3)C2C=C1 ; C1=CC2N=C(c3ccc(-c4c5ccccc5c(-c5ccc(-c6nc7ccccc7n6-c6ccccc6)cc5)c5cc(-c6ccc7ccccc7c6)ccc45)cc3)N(c3ccccc3)C2C=C1 ; C1=CC2N=C(c3ccc(-c4c5ccc(-c6ccccc6)cc5c(-c5ccc(-c6nc7ccccc7n6-c6ccccc6)cc5)c5ccc(-c6ccccc6)cc45)cc3)N(c3ccccc3)C2C=C1]

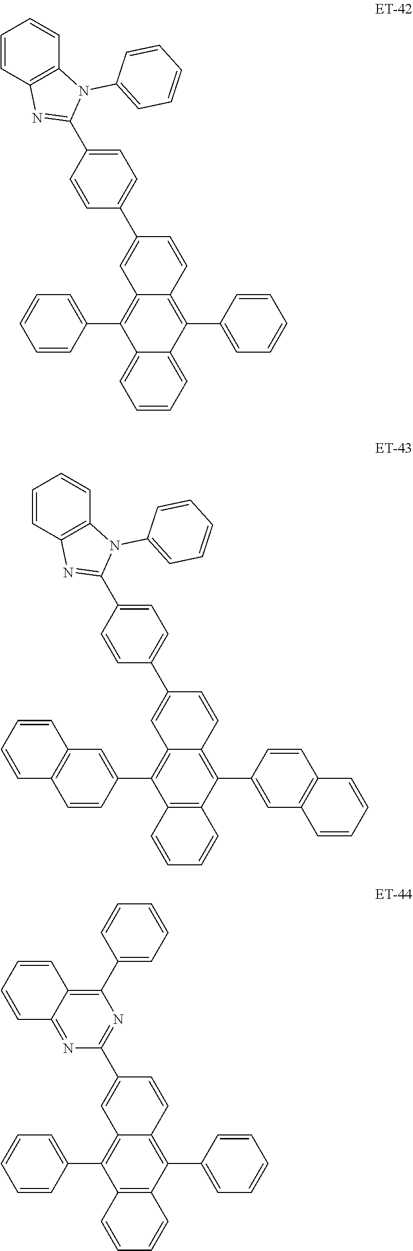

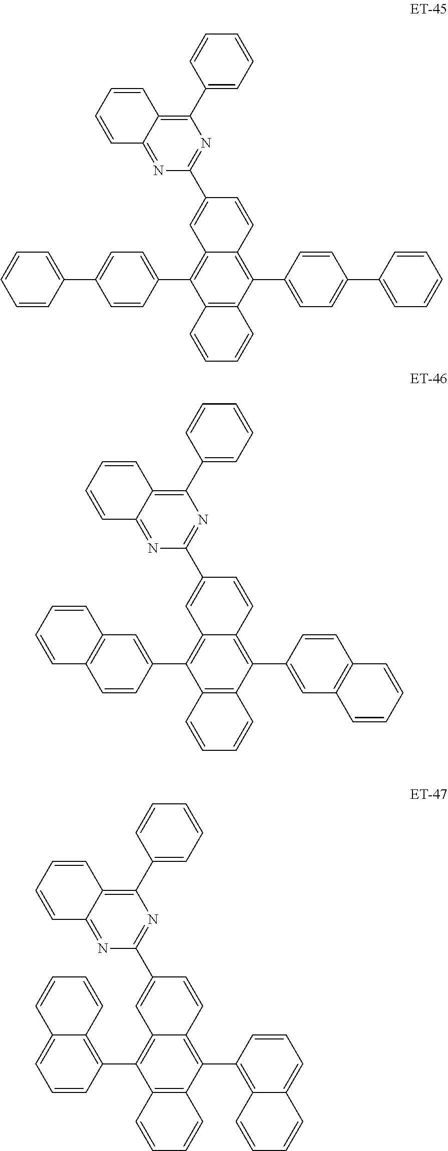

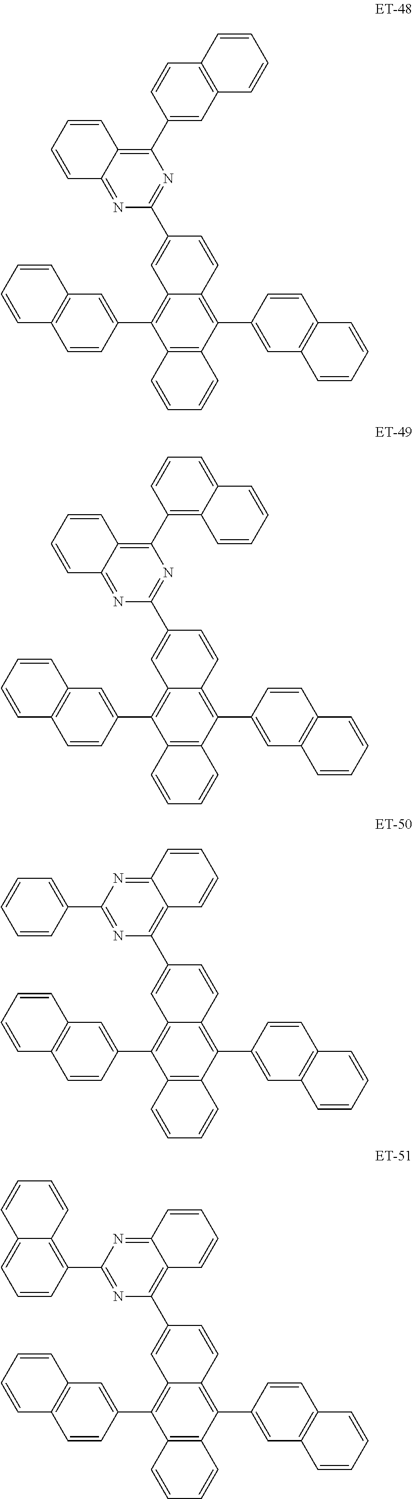

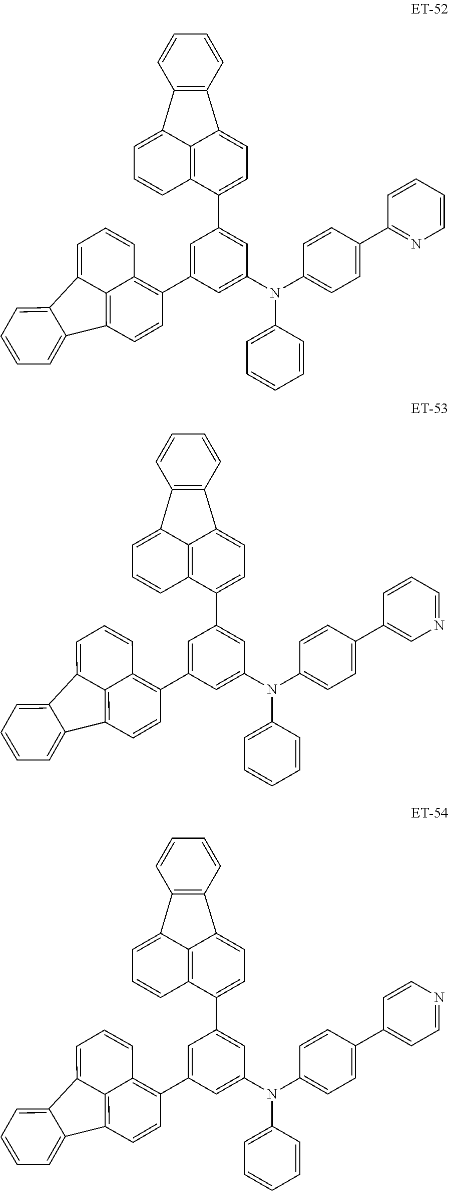 [SMILES: c1ccc(N(c2ccc(-c3ccccn3)cc2)c2cc(-c3ccc4c5c(cccc35)-c3ccccc3-4)cc(-c3ccc4c5c(cccc35)-c3ccccc3-4)c2)cc1 ; c1ccc(N(c2ccc(-c3cccnc3)cc2)c2cc(-c3ccc4c5c(cccc35)-c3ccccc3-4)cc(-c3ccc4c5c(cccc35)-c3ccccc3-4)c2)cc1 ; c1ccc(N(c2ccc(-c3ccncc3)cc2)c2cc(-c3ccc4c5c(cccc35)-c3ccccc3-4)cc(-c3ccc4c5c(cccc35)-c3ccccc3-4)c2)cc1]

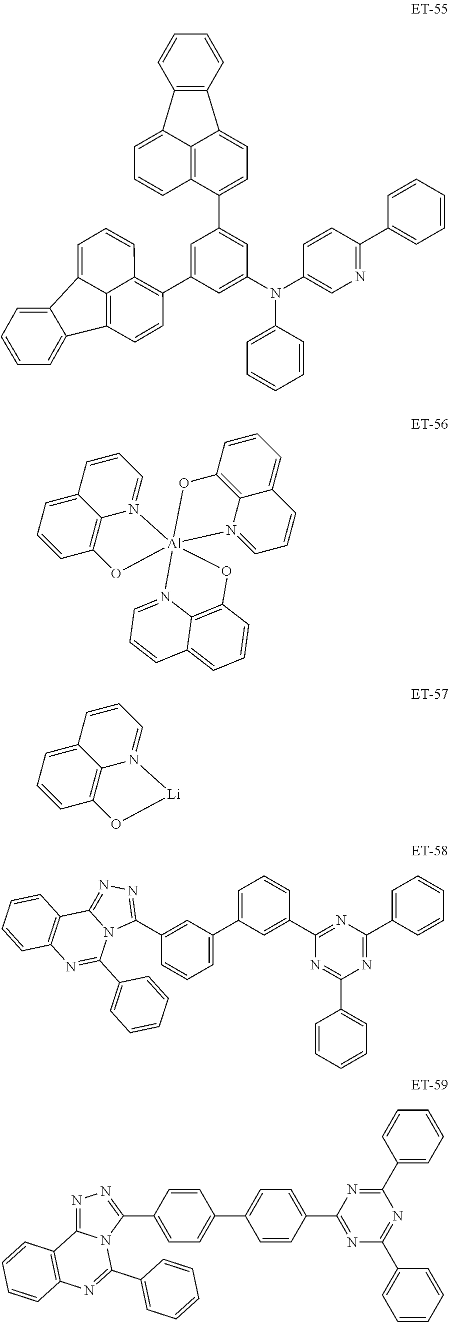

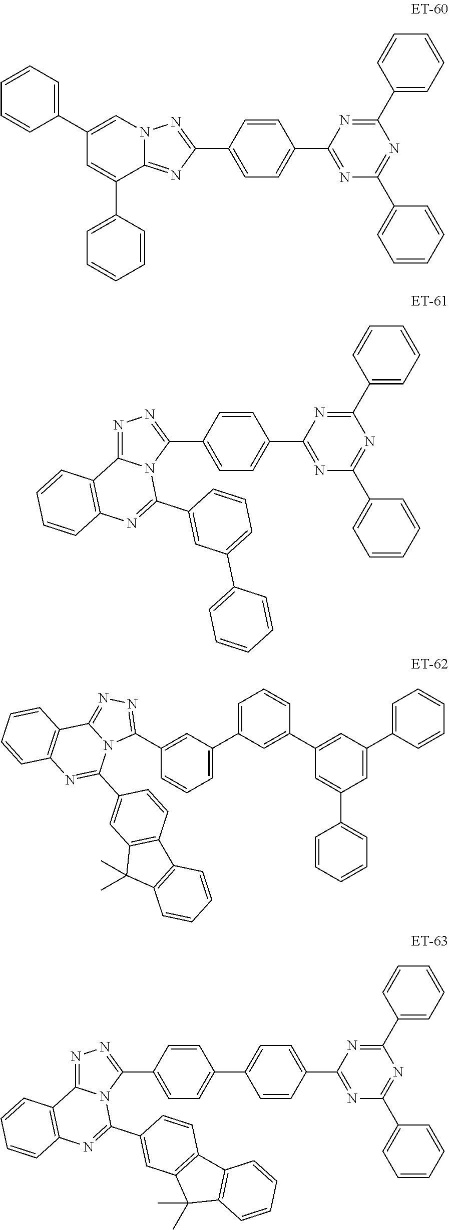

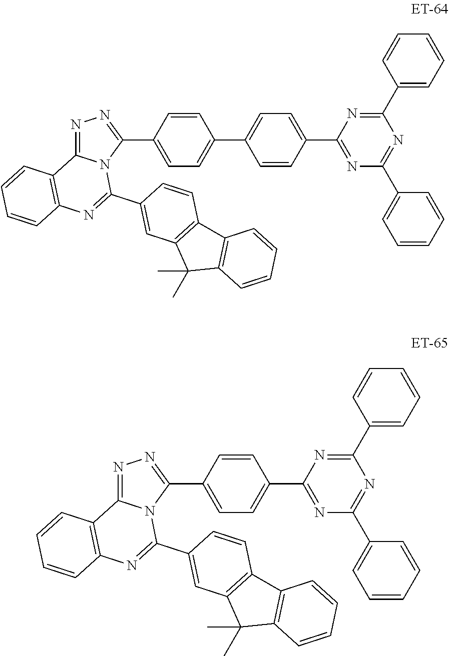 [SMILES: CC1(C)c2ccccc2-c2ccc(-c3nc4ccccc4c4nnc(-c5ccc(-c6ccc(-c7nc(-c8ccccc8)nc(-c8ccccc8)n7)cc6)cc5)n34)cc21 ; CC1(C)c2ccccc2-c2ccc(-c3nc4ccccc4c4nnc(-c5ccc(-c6nc(-c7ccccc7)nc(-c7ccccc7)n6)cc5)n34)cc21]

In an optional embodiment, a hole blocking material of the HBL is selected from any one or a combination of at least two of the compounds represented by the following HB-1 to HB-6 (such as a combination of HB-1 and HB-2, a combination of HB-5, HB-6 and HB-4 or a combination of HB-1, HB-3, HB-4 and HB-6):

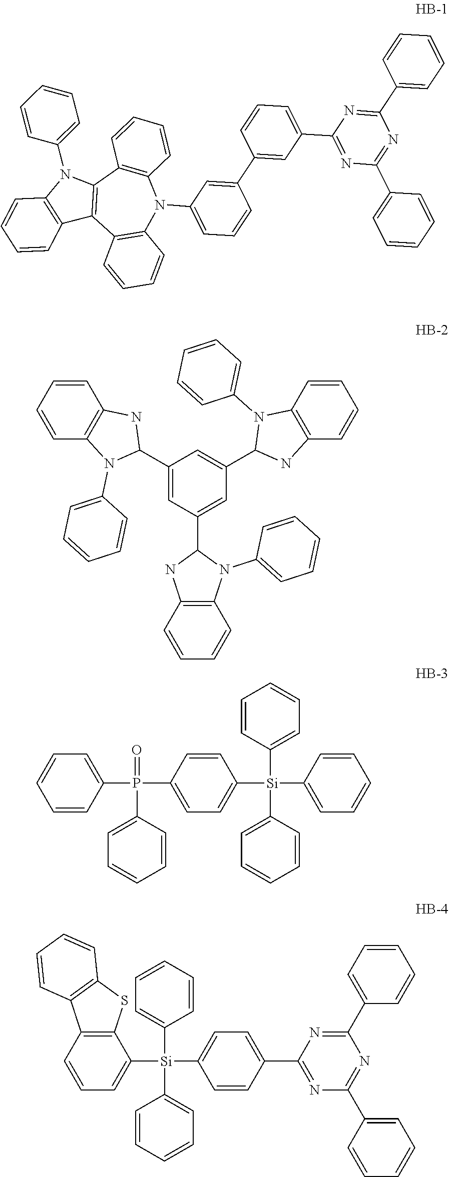 [SMILES: c1ccc(-c2nc(-c3ccccc3)nc(-c3cccc(-c4cccc(N5c6ccccc6-c6c(n(-c7ccccc7)c7ccccc67)-c6ccccc65)c4)c3)n2)cc1 ; c1ccc(N2c3ccccc3NC2c2cc(C3Nc4ccccc4N3c3ccccc3)cc(C3Nc4ccccc4N3c3ccccc3)c2)cc1 ; O=P(c1ccccc1)(c1ccccc1)c1ccc([Si](c2ccccc2)(c2ccccc2)c2ccccc2)cc1 ; c1ccc(-c2nc(-c3ccccc3)nc(-c3ccc([Si](c4ccccc4)(c4ccccc4)c4cccc5c4sc4ccccc45)cc3)n2)cc1]

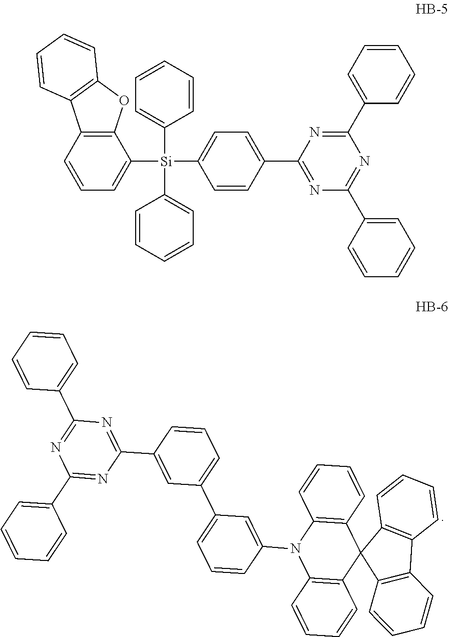 [SMILES: c1ccc(-c2nc(-c3ccccc3)nc(-c3ccc([Si](c4ccccc4)(c4ccccc4)c4cccc5c4oc4ccccc45)cc3)n2)cc1 ; c1ccc(-c2nc(-c3ccccc3)nc(-c3cccc(-c4cccc(N5c6ccccc6C6(c7ccccc7-c7ccccc76)c6ccccc65)c4)c3)n2)cc1]

In an optional embodiment, an electron blocking material of the EBL is selected from any one or a combination of at least two of the compounds represented by the following EB-1 to EB-21 and compounds TDH-1 to TDH-30:

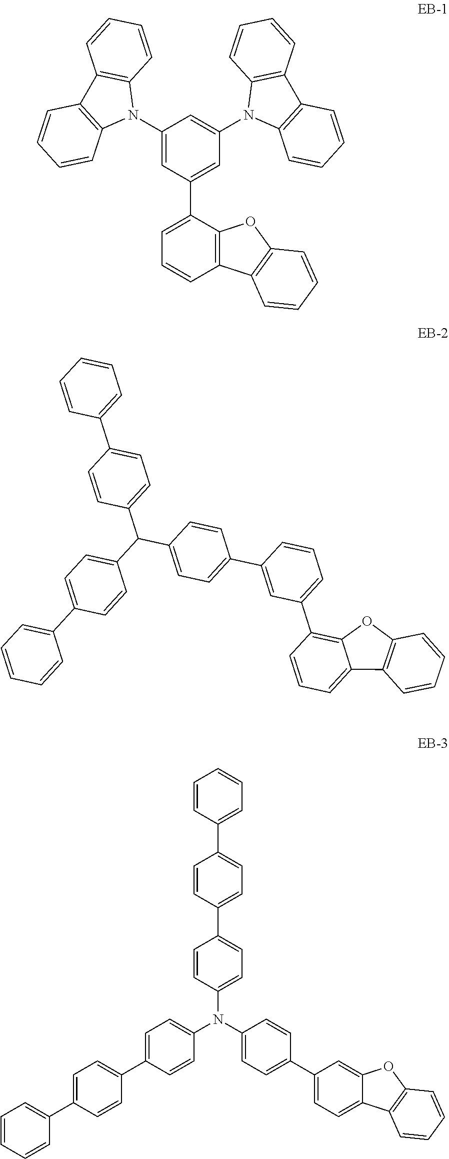 [SMILES: c1ccc2c(c1)oc1c(-c3cc(-n4c5ccccc5c5ccccc54)cc(-n4c5ccccc5c5ccccc54)c3)cccc12 ; c1ccc(-c2ccc(C(c3ccc(-c4ccccc4)cc3)c3ccc(-c4cccc(-c5cccc6c5oc5ccccc56)c4)cc3)cc2)cc1 ; c1ccc(-c2ccc(-c3ccc(N(c4ccc(-c5ccc(-c6ccccc6)cc5)cc4)c4ccc(-c5ccc6c(c5)oc5ccccc56)cc4)cc3)cc2)cc1]

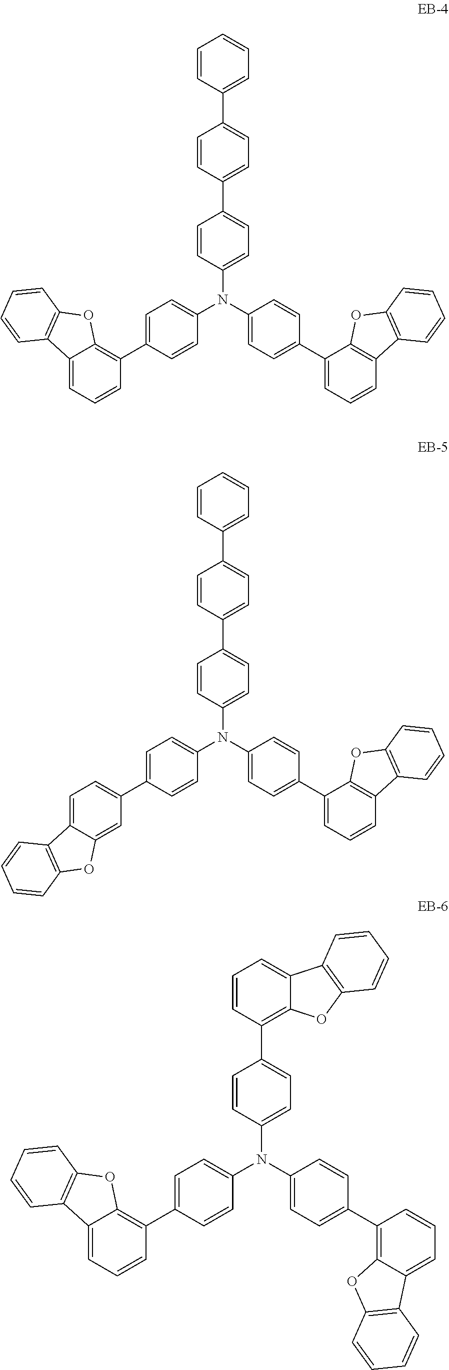 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(-c3ccc(N(c4ccc(-c5ccc6c(c5)oc5ccccc56)cc4)c4ccc(-c5cccc6c5oc5ccccc56)cc4)cc3)cc2)cc1 ; c1ccc2c(c1)oc1c(-c3ccc(N(c4ccc(-c5cccc6c5oc5ccccc56)cc4)c4ccc(-c5cccc6c5oc5ccccc56)cc4)cc3)cccc12]

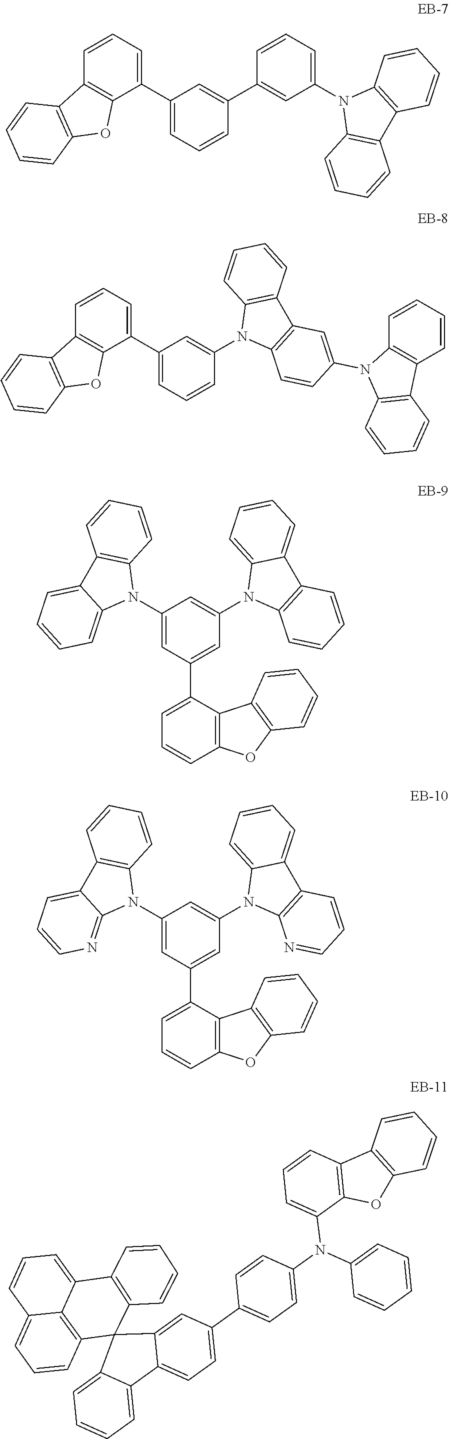 [SMILES: c1cc(-c2cccc(-n3c4ccccc4c4ccccc43)c2)cc(-c2cccc3c2oc2ccccc23)c1 ; c1cc(-c2cccc3c2oc2ccccc23)cc(-n2c3ccccc3c3cc(-n4c5ccccc5c5ccccc54)ccc32)c1 ; c1ccc2c(c1)oc1cccc(-c3cc(-n4c5ccccc5c5ccccc54)cc(-n4c5ccccc5c5ccccc54)c3)c12 ; c1ccc2c(c1)oc1cccc(-c3cc(-n4c5ccccc5c5cccnc54)cc(-n4c5ccccc5c5cccnc54)c3)c12 ; c1ccc(N(c2ccc(-c3ccc4c(c3)C3(c5ccccc5-4)c4ccccc4-c4cccc5cccc3c45)cc2)c2cccc3c2oc2ccccc23)cc1]

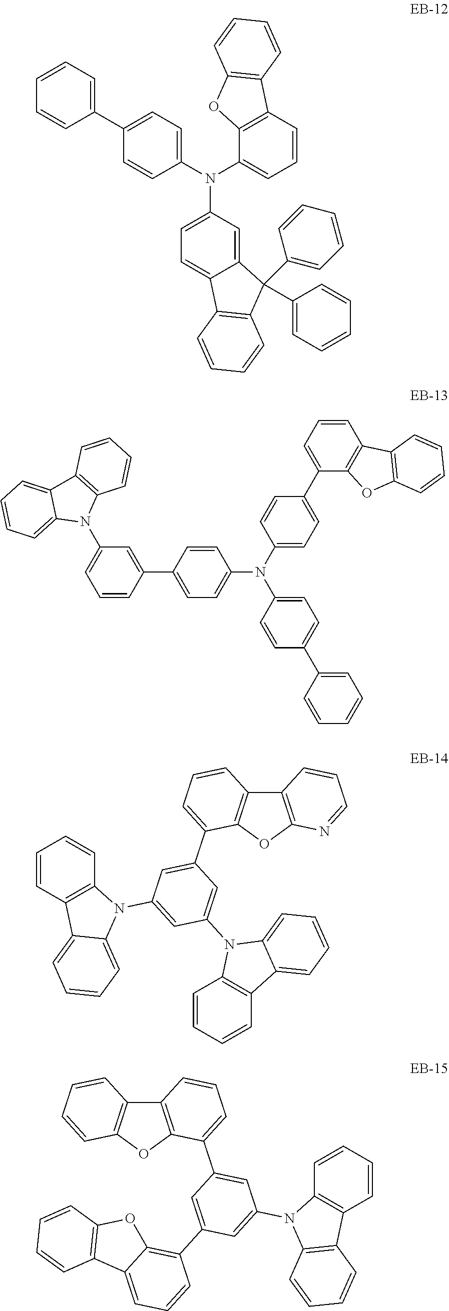

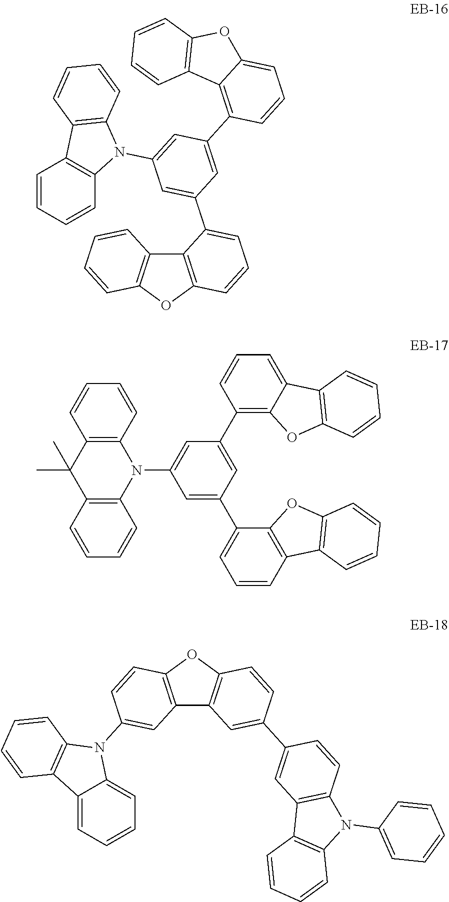 [SMILES: c1ccc2c(c1)oc1cccc(-c3cc(-c4cccc5oc6ccccc6c45)cc(-n4c5ccccc5c5ccccc54)c3)c12 ; CC1(C)c2ccccc2N(c2cc(-c3cccc4c3oc3ccccc34)cc(-c3cccc4c3oc3ccccc34)c2)c2ccccc21 ; c1ccc(-n2c3ccccc3c3cc(-c4ccc5oc6ccc(-n7c8ccccc8c8ccccc87)cc6c5c4)ccc32)cc1]

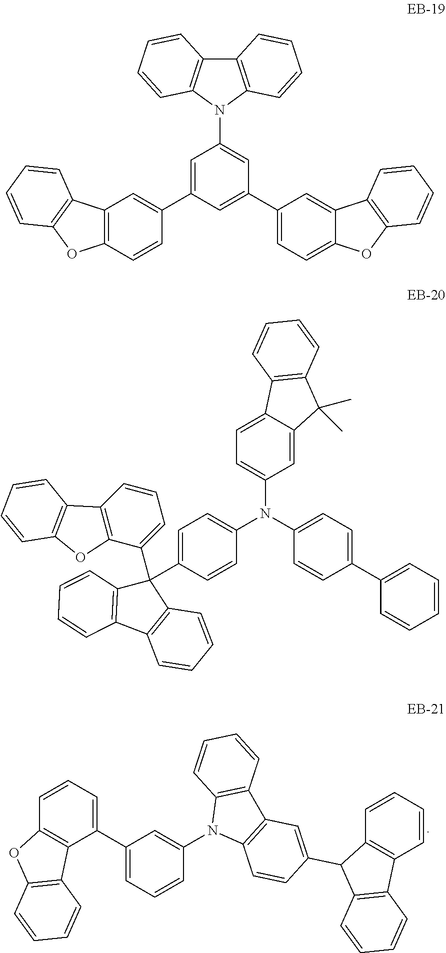 [SMILES: c1ccc2c(c1)oc1ccc(-c3cc(-c4ccc5oc6ccccc6c5c4)cc(-n4c5ccccc5c5ccccc54)c3)cc12 ; CC1(C)c2ccccc2-c2ccc(N(c3ccc(-c4ccccc4)cc3)c3ccc(C4(c5cccc6c5oc5ccccc56)c5ccccc5-c5ccccc54)cc3)cc21 ; c1cc(-c2cccc3oc4ccccc4c23)cc(-n2c3ccccc3c3cc(C4c5ccccc5-c5ccccc54)ccc32)c1]

In an optional embodiment, an electron injection material of the EIL comprises any one or a combination of at least two of the following compounds:

Liq, LiF, NaCl, CsF, Li₂O, Cs₂CO₃, BaO, Na, Li, Ca, Mg, Ag and Yb.

In an optional embodiment, a substrate is used below the first electrode or above the second electrode. The substrate is glass or a polymeric material having mechanical strength, thermal stability, waterproof property and excellent transparency. In addition, a thin-film transistor (TFT) can also be disposed on a substrate used as a display.

In an optional embodiment, the first electrode is formed in a manner of sputtering or depositing a material used as the first electrode on the substrate. When the first electrode is used as the anode, the material of the first electrode is a transparent conductive oxide material such as indium tin oxide (ITO), indium zinc oxide (IZO), tin (IV) oxide (SnO₂) or zinc oxide (ZnO), or any combination thereof. When the first electrode is used as the cathode, the material of the first electrode is a metal or an alloy, such as magnesium (Mg), silver (Ag), aluminum (Al), aluminum-lithium (Al—Li), calcium (Ca), magnesium-indium (Mg—In) or magnesium-silver (Mg—Ag), or any combination thereof

In the device, a capping layer (CPL layer) can be evaporated above the cathode to improve the device efficiency and adjust an optical microcavity.

The thicknesses of the above layers use conventional thicknesses of the layers in the art.

The present disclosure further provides a method for preparing the organic electroluminescent device. The method comprises sequentially depositing an anode, a hole transport region, an EML, an electron transport region and a cathode on a substrate followed by encapsulation. When the EML is prepared, a multi-component co-deposition method is used. The deposition manners of the anode, the hole transport region, the electron transport region and the cathode are the same as the existing manners in the art.

Exemplarily, the following synthesis examples provide specific synthesis methods of the fluorescent dye, where an ABSCIEX mass spectrometer (4000QTRAP) is used for the analysis and detection of compounds.

### Synthesis Example 1: Synthesis of M1

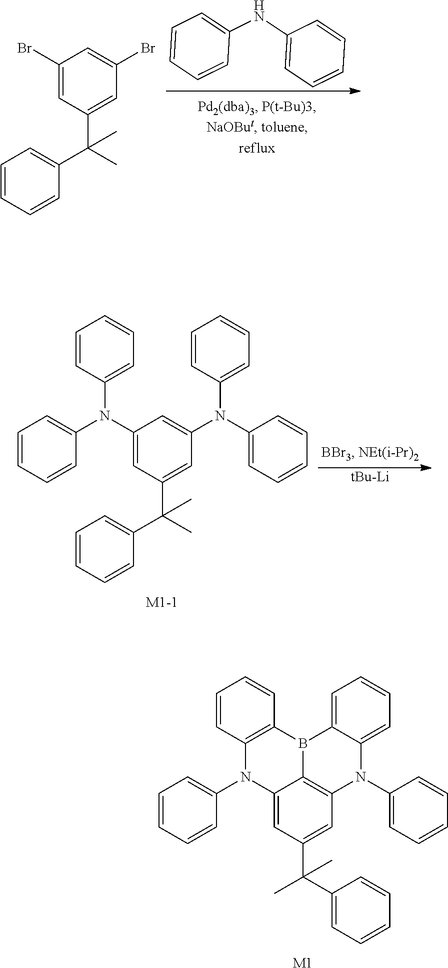

### Synthesis of Intermediate M1-1

At room temperature, 1,3-dibromo-5-(2-phenylpropan-2-yl)benzene (35.2 g, 100 mmol), diphenylamine (41.7 g, 250 mmol), Pd₂(dba)₃ (0.92 g, 1 mmol), s-Phos (0.82 g, 2 mmol), sodium tert-butoxide (24 g, 250 mmol) and xylene (500 mL) were added to a 1 L single-necked flask, purged with nitrogen three times, heated to 130° C. and reacted overnight. The reaction solution was cooled to room temperature. The reaction system was concentrated, extracted with dichloromethane and washed with a large amount of water. The organic phases were dried, concentrated and subjected to column chromatography (PE:DCM=20:1) to obtain a crude product (42.4 g). The crude product was heated, boiled and washed with n-hexane to obtain a white solid (33.1 g) with a yield of 62.4%.

The molecular determined through mass spectrometry is 530.29 (theoretical value: 530.27).

### Synthesis of Compound M1

M1-1 (5.3 g, 10 mmol) was added to a 250 mL three-necked flask. p-tert-Butylbenzene (80 mL) was added and stirred for 20 minutes. The reaction system was cooled to −20° C., and then, tert-butyllithium (15 mmol) was added. The reaction system continued to be stirred for 30 minutes at a low temperature which was maintained. Then, the temperature was gradually increased to 90° C., and the reaction system was continuously heated for 3 h. Finally, the reaction system was reduced to −20° C. again. Under nitrogen protection, boron tribromide (5.1 g, 20 mmol) was added and stirred for 30 minutes, and then diisopropylethylamine (13 g, 80 mmol) was added. Finally, the reaction system was heated to 110° C. and reacted for 12 h. After the reaction system was cooled to room temperature, the organic phases were subjected to rotary evaporation to dryness under reduced pressure. The reaction system was extracted with ethyl acetate (200 mL) three times. The organic phases were combined and dried with anhydrous sodium sulfate. The organic phases were mixed with silica gel, concentrated and subjected to column chromatography (PE:DCM=100:1) to obtain a crude product (2.1 g). The crude product was recrystallized with toluene/n-hexane to obtain a yellow solid (0.95 g) with a yield of 17.6%.

The molecular mass determined through mass spectrometry is 538.22 (theoretical value: 538.26).

### Synthesis Example 2: Synthesis of M6

The synthesis method of M6 was similar to that of M1, except that diphenylamine was replaced with bis(4-tert-butylphenyl)amine in an equivalent amount of substance to obtain a compound M6 with a yield of 15.1%. The molecular ion mass determined through molecular mass spectrometry is 762.49 (theoretical value: 762.51).

### Synthesis Example 3: Synthesis of M37

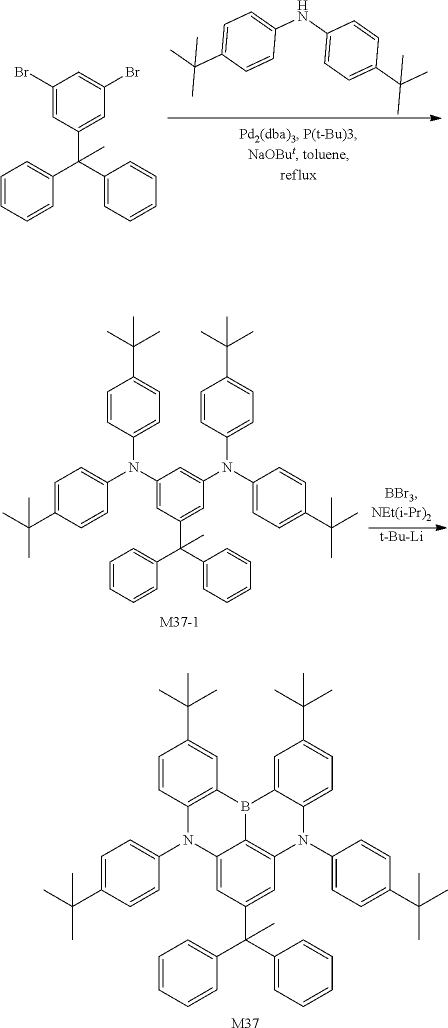

### Synthesis of Intermediate M37-1

At room temperature, (1-(3,5-dibromophenyl)ethane-1,1-diphenyl)diphenyl (41.4 g, 100 mmol), bis(4-tert-butylphenyl)amine (90.0 g, 320 mmol), Pd₂(dba)₃ (2.8 g, 3 mmol), 2-dicyclohexylphosphino-2′,6′-dimethoxybiphenyl (s-Phos) (1.2 g, 3 mmol), sodium tert-butoxide (33.6 g, 350 mmol) and xylene (1200 mL) were added to a 2 L single-necked flask, purged with nitrogen three times, heated to 130° C. and reacted overnight. The reaction solution was cooled to room temperature, extracted with ethyl acetate and washed with a large amount of water. The organic phases were dried, concentrated and subjected to column chromatography (PE:DCM=20:1) to obtain a white solid (66.4 g) with a yield of 81.4%.

The molecular mass determined through mass spectrometry is 816.58 (theoretical value: 816.54).

### Synthesis of Compound M37

M53-1 (8.2 g, 10 mmol) was added to a 500 mL three-necked flask. p-tert-Butylbenzene (150 mL) was added and stirred for 20 minutes. The reaction system was cooled to −20° C., and tert-butyllithium (15 mmol) was added. The reaction system continued to be stirred for 30 minutes at a low temperature which was maintained. Then, the temperature was gradually increased to 90° C., and the reaction system was continuously heated for 3 h. Finally, the reaction system was reduced to −20° C. again. Under nitrogen protection, boron tribromide (5.1 g, 20 mmol) was added and stirred for 30 minutes, and then diisopropylethylamine (13 g, 80 mmol) was added. Finally, the reaction system was heated to 110° C. and reacted for 12 h. After the reaction system was cooled to room temperature, the organic phases were subjected to rotary evaporation to dryness under reduced pressure. The reaction system was extracted with ethyl acetate (200 mL) three times. The organic phases were combined and dried with anhydrous sodium sulfate. The organic phases were mixed with silica gel, concentrated and subjected to column chromatography (PE:DCM=40:1) to obtain a crude product (1.9 g). The crude product was recrystallized with toluene/n-hexane to obtain a yellow solid (1.1 g) with a yield of 13.3%. The molecular mass determined through mass spectrometry is 824.54 (theoretical value: 824.52).

### Synthesis Example 4: Synthesis of M49

The synthesis method of M49 was similar to that of M37, except that bis(4-tert-butylphenyl)amine was replaced with bis(3-tert-butylphenyl)amine in an equivalent amount of substance to obtain Compound M49 with a yield of 15.5%. The molecular mass determined through molecular mass spectrometry is 816.57 (theoretical value: 816.54).

### Synthesis Example 5: Synthesis of M55

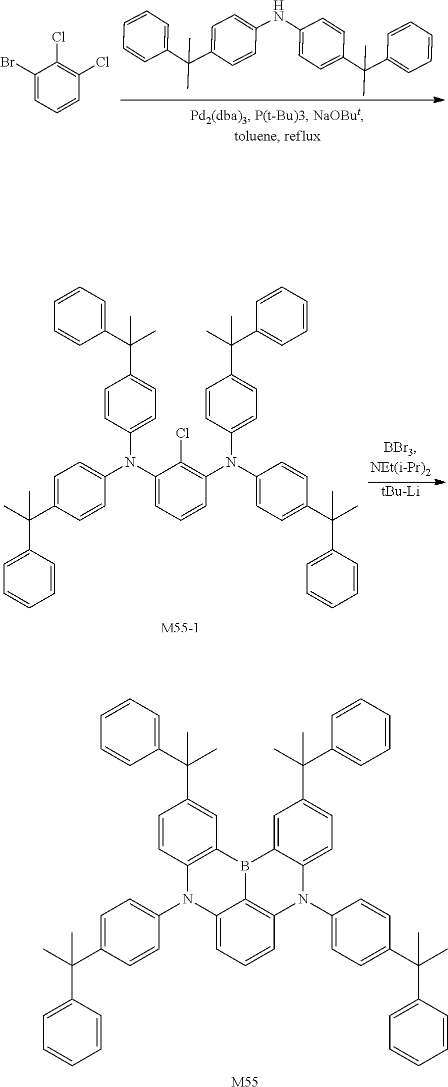

### Synthesis of Intermediate M55-1

At room temperature, 1-bromo-2,3-dichlorobenzene (22.4 g, 100 mmol), bis(4-(2-phenylpropan-2-yl)phenyl)amine (129.7 g, 320 mmol), Pd₂(dba)₃ (2.8 g, 3 mmol), s-Phos (1.2 g, 3 mmol), sodium tert-butoxide (33.6 g, 350 mmol) and xylene (1200 mL) were added to a 2 L single-necked flask, purged with nitrogen three times, heated to 130° C. and reacted overnight. The reaction solution was cooled to room temperature, extracted with ethyl acetate and washed with a large amount of water. The organic phases were dried, concentrated and subjected to column chromatography (PE:DCM=15:1) to obtain a white solid (60.8 g) with a yield of 66.2%.

The molecular mass determined through mass spectrometry is 918.48 (theoretical value: 918.47).

### Synthesis of Compound M55

M55-1 (9.2 g, 10 mmol) was added to a 500 mL three-necked flask. p-tert-Butylbenzene (150 mL) was added and stirred for 20 minutes. The reaction system was cooled to −20° C., and then tert-butyllithium (15 mmol) was added. The reaction system continued to be stirred for 30 minutes at a low temperature which was maintained. Then, the temperature was gradually increased to 90° C., and the reaction system was continuously heated for 3 h. Finally, the reaction system was reduced to −20° C. again. Under nitrogen protection, boron tribromide (5.1 g, 20 mmol) was added and stirred for 30 minutes, and diisopropylethylamine (13 g, 80 mmol) was added. Finally, the reaction system was heated to 110° C. and reacted for 12 h. After the reaction was cooled to room temperature, the organic phases were subjected to rotary evaporation to dryness under reduced pressure. The reaction system was extracted with ethyl acetate (200 mL) three times. The organic phases were combined and dried with anhydrous sodium sulfate. The organic phases were mixed with silica gel, concentrated and subjected to column chromatography (PE:DCM=40:1) to obtain a crude product (3.2 g). The crude product was recrystallized with toluene/n-hexane to obtain a yellow solid (2.3 g) with a yield of 26.3%. The molecular mass determined through mass spectrometry is 892.45 (theoretical value: 892.49).

### Synthesis Example 6: Synthesis of M66

The synthesis method of M66 was similar to that of M55, except that 1-bromo-2,3-dichlorobenzene was replaced with 1-bromo-2,3-dichloro-5-methylbenzene in an equivalent amount of substance to obtain a compound M66 with a yield of 23.5%. The molecular mass determined through molecular mass spectrometry is 906.48 (theoretical value: 906.51).

### Synthesis Example 7: Synthesis of M89

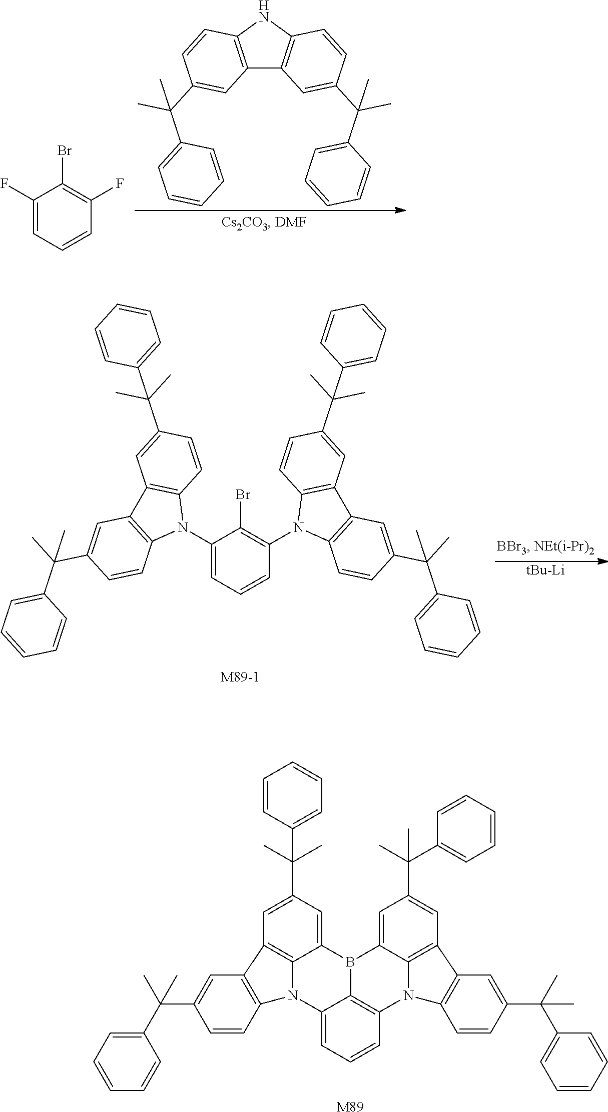

### Synthesis of Intermediate M89-1

At room temperature, 3,6-bis(2-phenylpropan-2yl)carbazole (34.3 g, 85 mmol), 2-bromo-1,3-difluorobenzene (7.7 g, 40 mmol), cesium carbonate (32.6 g, 100 mmol) and N,N-dimethylformamide (350 mL) were added to a 500 mL single-necked flask, purged with nitrogen three times, heated to 130° C. and reacted overnight. After the reaction was stopped and the reaction system was cooled to room temperature, 500 mL water was added and stirred for 10 min. A large amount of white solids were precipitated and subjected to suction filtration. The filter cake was boiled and washed with ethanol for 2 h and subjected to suction filtration at a reduced temperature to obtain a white solid product (37.4 g) with a yield of 97.6%. The molecular mass determined through mass spectrometry is 958.42 (theoretical value: 958.39).

### Synthesis of Compound M89

M89-1 (9.6 g, 10 mmol) was added to a 500 mL three-necked flask. p-tert-Butylbenzene (100 mL) was added and stirred for 20 minutes. The reaction system was cooled to −20° C., and tert-butyllithium (15 mmol) was added. The reaction system continued to be stirred for 30 minutes at a low temperature which was maintained. Then, the temperature was gradually increased to 90° C., and the reaction system was continuously heated for 3 h. Finally, the reaction system was reduced to −20° C. again. Under nitrogen protection, boron tribromide (5.1 g, 20 mmol) was added and stirred for 30 minutes, and then diisopropylethylamine (13 g, 80 mmol) was added. Finally, the reaction system was heated to 110° C. and reacted for 12 h. After the reaction system was cooled to room temperature, the organic phases were subjected to rotary evaporation to dryness under reduced pressure. The reaction system was extracted with ethyl acetate (200 mL) three times. The organic phases were combined and dried with anhydrous sodium sulfate. The organic phases were mixed with silica gel, concentrated and subjected to column chromatography (PE:DCM=40:1) to obtain a crude product (1.9 g). The crude product was recrystallized with toluene/n-hexane to obtain a yellow solid (1.2 g) with a yield of 20.3%. The molecular mass determined through mass spectrometry is 888.47 (theoretical value: 888.46).

### Synthesis Example 8: Synthesis of M90

The synthesis method of M90 was similar to that of M89, except that 2-bromo-1,3-difluobenzene was replaced with 2-bromo-1,3-difluoro-5-methylbenzene in an equivalent amount of substance to obtain Compound M90 with a yield of 19.6%. The molecular mass determined through molecular mass spectrometry is 902.51 (theoretical value: 902.48).

The synthesis methods of other compounds were similar. The other compounds were synthesized according to related synthesis general formulas and confirmed through a mass spectrometry test. The results are as follows:

TABLE 1
Results of mass spectrometry test of compounds

| Compound | Theoretical Value of | Test Data of Mass |
|---|---|---|
| Number | Mass Spectrometry | Spectrometry |
| M3 | 606.40 | 606.62 |
| M14 | 762.51 | 762.66 |
| M31 | 850.54 | 850.81 |
| M44 | 824.52 | 824.96 |
| M76 | 822.51 | 822.63 |
| M81 | 764.43 | 764.64 |
| M102 | 778.49 | 778.72 |
| M106 | 778.49 | 778.83 |
| M108 | 1026.55 | 1026.87 |

The organic electroluminescent device of the present disclosure is further described below through specific embodiments.

### Embodiments One to Twenty-One and Comparative Examples One and Two

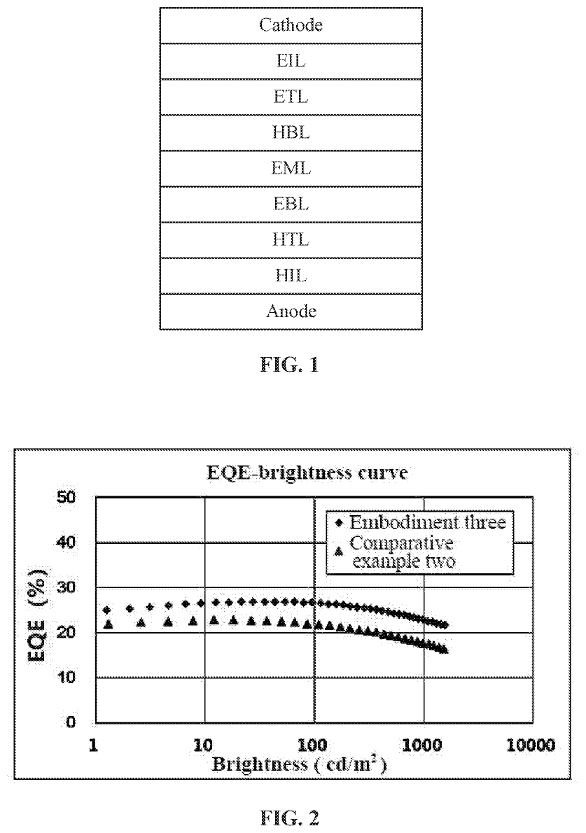

The above embodiments and comparative examples each provide an organic electroluminescent device having a structure shown in FIG. 1, including, from top to bottom, an anode, an HIL, an HTL, an EBL, an EML, an HBL, an ETL, an EIL and a cathode in sequence, where the EML comprises a host material, a TADF sensitizer and a fluorescent dye, and a specific selection of materials is shown in detail in Table 1.

A specific method for preparing the organic electroluminescent device is described below.

(1) A glass plate coated with an ITO transparent conductive layer was sonicated in a commercial cleaning agent, rinsed in deionized water, performed ultrasonic oil removal in an acetone: ethanol mixed solvent, baked in a clean environment to completely remove moisture, washed with ultraviolet light and ozone, and bombarded the surface with a low-energy cation beam.
(2) The above glass substrate with an anode was placed in a vacuum chamber. The vacuum chamber was vacuumized to less than 1×10⁻⁵ Pa. HI-3 was evaporated through vacuum evaporation on a film of the above anode layer as an HIL, where an evaporation rate was 0.1 nm/s, and the evaporated film had a thickness of 2 nm.
(3) An HTL HT-28 was evaporated through vacuum evaporation on the HIL, where an evaporation rate was 0.1 nm/s, and the evaporated film had a total thickness of 30 nm.
(4) An EBL EB-12 was evaporated through vacuum evaporation on the HTL, where an evaporation rate was 0.1 nm/s, and the evaporated film had a total thickness of 5 nm.
(5) An EML, which comprises a host material, a sensitizer and a fluorescent dye, was evaporated through vacuum evaporation on the EBL using a multi-component co-deposition method, where a host evaporation rate was 0.1 nm/s, and the evaporated film had a thickness of 30 nm.
(6) HB-5 was evaporated through vacuum evaporation on the EML as an HBL, where an evaporation rate was 0.1 nm/s, and the evaporated film had a total thickness of 5 nm.
(7) EB-60 and ET-57 were evaporated through vacuum evaporation on the HBL as an ETL at a ratio of 1:1, where an evaporation rate was 0.1 nm/s, and the evaporated film had a total thickness of 25 nm.
(8) Liq with a thickness of 1 nm was evaporated through vacuum evaporation on the ETL as an EIL, and an Al layer with a thickness of 150 nm was evaporated through vacuum evaporation as a cathode of the device.

The fluorescent dyes used in comparative examples one and two each have a structure of D1 or D2:

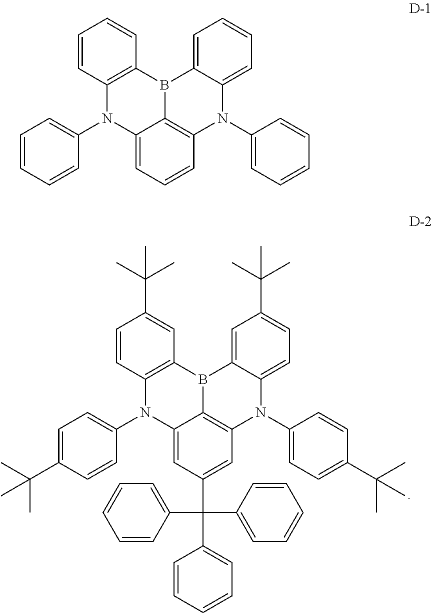 [SMILES: c1ccc(N2c3ccccc3B3c4ccccc4N(c4ccccc4)c4cccc2c43)cc1 ; CC(C)(C)c1ccc(N2c3ccc(C(C)(C)C)cc3B3c4cc(C(C)(C)C)ccc4N(c4ccc(C(C)(C)C)cc4)c4cc(C(c5ccccc5)(c5ccccc5)c5ccccc5)cc2c43)cc1]

Device Performance Test

(1) At the same brightness, the drive voltages and the external quantum efficiency of the organic electroluminescent devices prepared in the device embodiments and the device comparative examples were measured using a digital source meter and PR650. Specifically, the voltage was increased at a rate of 0.1 V per second, and a voltage measured when the brightness of the organic electroluminescent device reached 1000 cd/m² was a drive voltage at the corresponding brightness. Moreover, the external quantum efficiency (EQE, %) of the device can be directly tested on PR650.
(2) Service life test

At the brightness of 1000 cd/m², a constant current was maintained, and a brightness meter was used for measuring the time for the brightness of the organic electroluminescent device to reduce to 800 cd/m², which was referred to an LT80 service life of the device. In this test, the service life of comparative example one was denoted as 100%, and the service life values of other embodiments or comparative examples were all expressed in proportion to that of comparative example one.

The results of the above test are shown in Table 2.

TABLE 2
Results of device performance test

| | Emission Layer | | | | | | | |
|---|---|---|---|---|---|---|---|---|
| | | Sensitizer | | Fluorescent | | Drive | External | LT80 |
| | Host | and Doping | | Dye and Doping | | Voltage | Quantum | Service |
| | Material | Concentration | | Concentration | | (V) | Efficiency (%) | Life |
| Embodiment | TDH-1 | TDE23 | (40%) | M6 | (0.05%) | 5.0 | 19.5% | 190% |
| one | | | | | | | | |
| Embodiment | TDH-1 | TDE23 | (40%) | M6 | (0.1%) | 4.6 | 22.4% | 192% |
| two | | | | | | | | |
| Embodiment | TDH-1 | TDE23 | (40%) | M6 | (1%) | 4.4 | 23.3% | 216% |
| three | | | | | | | | |
| Embodiment | TDH-1 | TDE23 | (40%) | M6 | (10%) | 4.7 | 21.6% | 208% |
| four | | | | | | | | |
| Embodiment | TDH-1 | TDE23 | (40%) | M6 | (12%) | 4.9 | 20.7% | 189% |
| five | | | | | | | | |
| Embodiment | TDH-1 | TDE23 | (40%) | M1 | (1%) | 4.5 | 22.4% | 207% |
| six | | | | | | | | |
| Embodiment | TDH-1 | TDE23 | (40%) | M102 | (1%) | 5.0 | 20.0% | 168% |
| seven | | | | | | | | |
| Embodiment | TDH-2 | TDE23 | (30%) | M3 | (1%) | 4.7 | 21.6% | 189% |
| eight | | | | | | | | |
| Embodiment | TDH-6 | TDE33 | (80%) | M14 | (1%) | 4.7 | 22.1% | 171% |
| nine | | | | | | | | |
| Embodiment | TDH-10 | TDE34 | (10%) | M31 | (1%) | 45.0 | 20.0% | 165% |
| ten | | | | | | | | |
| Embodiment | TDH-15 | TDE12 | (40%) | M44 | (1%) | 4.8 | 19.8% | 173% |
| eleven | | | | | | | | |
| Embodiment | TDH-6 | TDE25 | (40%) | M49 | (1%) | 4.7 | 21.9% | 181% |
| twelve | | | | | | | | |
| Embodiment | TDH-20 | TDE16 | (40%) | M55 | (1%) | 4.6 | 21.4% | 155% |
| thirteen | | | | | | | | |
| Embodiment | TDH-23 | TDE9 | (40%) | M76 | (1%) | 4.8 | 21.2% | 176% |
| fourteen | | | | | | | | |
| Embodiment | TDH-30 | TDE3 | (40%) | M81 | (1%) | 4.9 | 20.8% | 159% |
| fifteen | | | | | | | | |
| Embodiment | TDH-19 | TDE14 | (40%) | M106 | (1%) | 4.8 | 20.9% | 144% |
| sixteen | | | | | | | | |
| Embodiment | TDH-17 | TDE18 | (40%) | M108 | (1%) | 4.7 | 19.6% | 137% |
| seventeen | | | | | | | | |
| Embodiment | TDH-19 | TDE10 | (40%) | M37 | (1%) | 4.4 | 20.6% | 147% |
| eighteen | | | | | | | | |
| Embodiment | TDH-18 | TDE3 | (40%) | M66 | (1%) | 4.6 | 20.5% | 149% |
| nineteen | | | | | | | | |
| Embodiment | TDH-27 | TDE27 | (40%) | M89 | (1%) | 4.8 | 20.6% | 157% |
| twenty | | | | | | | | |
| Embodiment | TDH-20 | TDE22 | (40%) | M90 | (1%) | 4.7 | 19.8% | 174% |
| twenty-one | | | | | | | | |
| Comparative | TDH-1 | TDE23 | (40%) | D-1 | (1%) | 5.3 | 18.9% | 100% |
| example one | | | | | | | | |
| Comparative | TDH-1 | TDE23 | (40%) | D-2 | (1%) | 5.6 | 17.7% | 110% |
| example two | | | | | | | | |

As can be seen from Table 2, in the present disclosure, the fluorescent dye having the specific structure is introduced into the EML of the TASF device so that the device performance can be effectively improved compared with the dye of the existing art, specifically, the drive voltage is reduced, and the external quantum efficiency and the service life are improved.

The fluorescent dye D-1 of comparative example one differs from the fluorescent dye M1 of embodiment six only in the absence of a quaternary carbon substituent, and the fluorescent dye D-2 of comparative example two differs from the fluorescent dye M6 of embodiment three only in that all substitutions on quaternary carbon of D-2 are phenyl while there is a substitution of alkyl on quaternary carbon of M6. The data shows that the device performance of comparative examples one and two is apparently inferior to that of the embodiments, which proves that the quaternary carbon substituent in the fluorescent dye of the present disclosure plays a crucial role.

As can be seen from a comparison among embodiments one to five, the performance of the TASF device can be further improved when the doping proportion of the fluorescent dye of the present disclosure is controlled in a range of 0.1% to 10% (embodiments two to four), and the best effect is achieved when the doping amount is 1% (embodiment three).

As can be seen from a comparison between embodiments three and seven, the fluorescent dye containing an aryl-substituted quaternary carbon group (embodiment three) is more conducive to improving the performance of the TASF device compared with the fluorescent dye containing an aryl-substituted quaternary silicon group (embodiment seven).

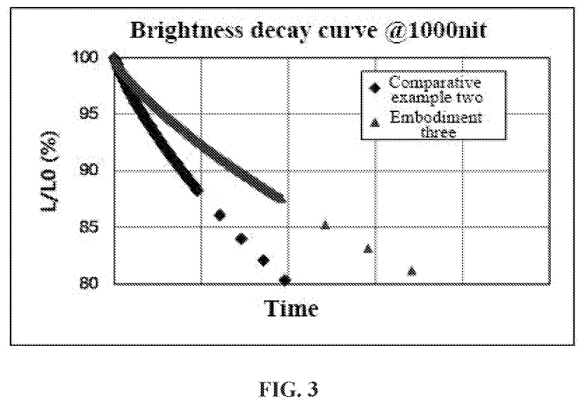

FIG. 2 is a graph illustrating a comparison of external quantum efficiency-brightness between devices of embodiment three and comparative example two, which shows that the device of embodiment three has higher external quantum efficiency at the same brightness.

FIG. 3 is a graph illustrating brightness decay of devices of embodiment three and comparative example two at a brightness of 1000 cd/m², where L₀ represents an initial brightness, and L represents a brightness after corresponding time has passed, which shows that the device of embodiment three has a slower brightness decay rate.

The applicant has stated that although the detailed method of the present disclosure is described through the embodiments described above, the present disclosure is not limited to the detailed method described above, which means that the implementation of the present disclosure does not necessarily depend on the detailed method described above. It is to be apparent to those skilled in the art that any improvements made to the present disclosure, equivalent replacements of raw materials of the product of the present disclosure, additions of adjuvant ingredients, selections of specific manners, etc., all fall within the protection scope and the disclosed scope of the present disclosure.

What is claimed is:

1. An organic electroluminescent device, comprising a first electrode, a second electrode and an organic layer disposed between the first electrode and the second electrode,
wherein the organic layer comprises an emission layer (EML), the EML comprises a host material, a thermally activated delayed fluorescence (TADF) sensitizer and a fluorescent dye, and the fluorescent dye is selected from a compound represented by Formula (1): 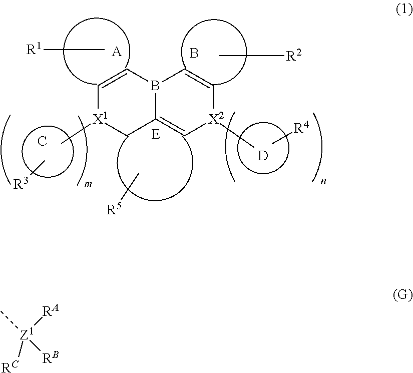
wherein in Formula (1):
the rings A, B, C, D and E each independently represent an aromatic ring or a heteroaromatic ring, and two adjacent rings are capable of being fused to form a five-membered ring or a six-membered ring containing X¹ or X²;
X¹ and X² are each independently selected from one of O, S, N, C or Si;
m is 0, 1 or 2, and n is 0, 1 or 2;
R¹, R², R³, R⁴ and R⁵ each independently represent from mono substitution to the maximum permissible substitution and are each independently selected from one or a combination of at least two of hydrogen, C₁ to C₁₀ chain alkyl, C₃ to C₁₀ cycloalkyl, C₁ to C₁₀ alkoxy, halogen, cyano, nitro, hydroxyl, ester, silicyl, amino, substituted or unsubstituted C₆ to C₃₀ arylamino, substituted or unsubstituted C₃ to C₃₀ heteroarylamino, substituted or unsubstituted C₆ to C₃₀ aryl or substituted or unsubstituted C₃ to C₃₀ heteroaryl, and at least one of R¹, R², R³, R⁴ and R⁵ is Formula (G);
wherein in Formula (G):
Z¹ is selected from C or Si;
R^{A}, R^{B} and R^{C} are each independently selected from one of C₁ to C₁₀ chain alkyl, C₃ to C₁₀ cycloalkyl, substituted or unsubstituted C₆ to C₃₀ aryl or substituted or unsubstituted C₃ to C₃₀ heteroaryl, at least one of R^{A}, R^{B} or R^{C} is substituted or unsubstituted C₆ to C₃₀ aryl or substituted or unsubstituted C₃ to C₃₀ heteroaryl, and at least one of R^{A}, R^{B} or R^{C} is C₁ to C₁₀ chain alkyl or C₃ to C₁₀ cycloalkyl; and
when a substituent is present in R^{A}, R^{B} and R^{C}, the substituent is selected from one or a combination of at least two of halogen, cyano, carboxy, C₁ to C₁₂ alkyl, C₃ to C₁₂ cycloalkyl, C₂ to C₁₀ alkenyl, C₁ to C₆ alkoxy or thioalkoxy, C₆ to C₃₀ monocyclic aryl or fused-ring aryl or C₃ to C₃₀ monocyclic heteroaryl or fused-ring heteroaryl.

2. The organic electroluminescent device according to claim 1, wherein the fluorescent dye is selected from a compound represented by Formula (2): 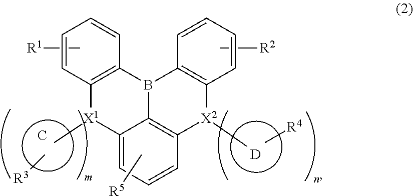
wherein the rings C, D, X¹, X², R¹, R², R³, R⁴, R⁵, m and n in Formula (2) are defined the same as those in the general Formula (1).

3. The organic electroluminescent device according to claim 1, wherein the fluorescent dye is selected from a compound represented by Formula (3): 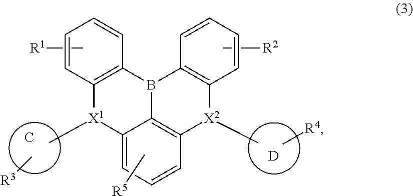
wherein the rings C, D, R¹, R², R³, R⁴, R⁵, m and n in Formula (3) are defined the same as those in the general Formula (1), and X¹ and X² are each independently selected from O, S or N, and at least one of X¹ or X² is N.

4. The organic electroluminescent device according to claim 1, wherein the fluorescent dye is selected from any one or a combination of at least two of compounds represented by the following Formulas (I), (II), (III), (IV), (V), (VI), (VII) or (VIII): 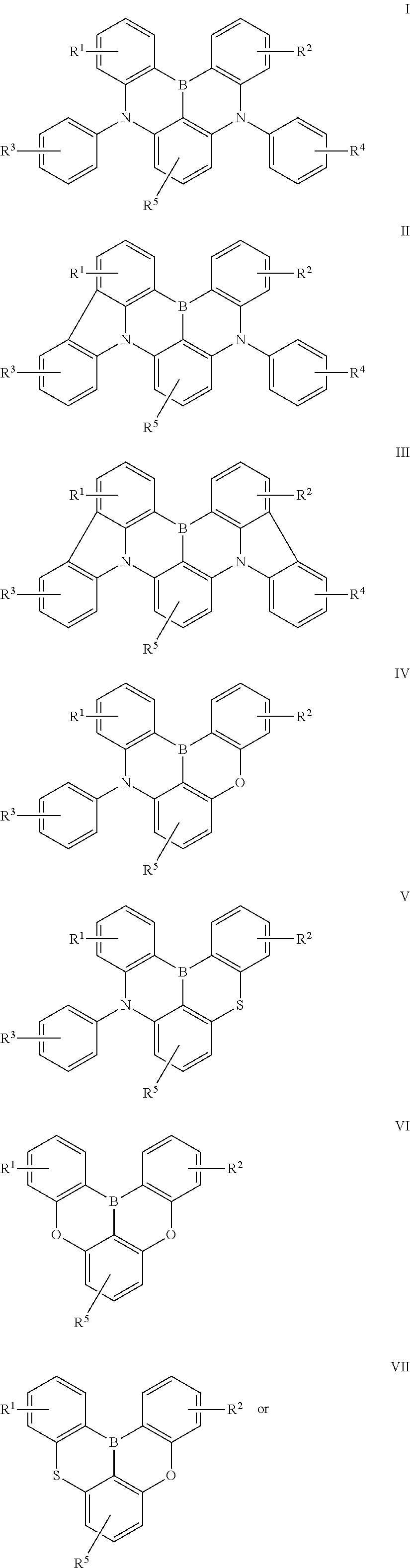 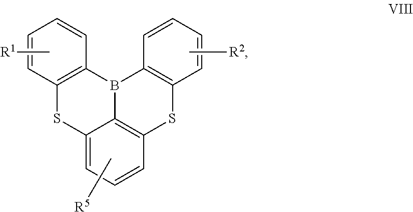
wherein R¹, R², R³, R⁴ and R⁵ are defined the same as those in the general Formula (1).

5. The organic electroluminescent device according to claim 1, wherein the fluorescent dye is selected from any one or a combination of at least two of the compounds represented by Formulas (I), (II) or (III).

6. The organic electroluminescent device according to claim 1, wherein Formula (G) is the following Formula (G1): 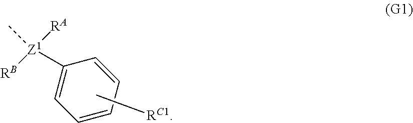
wherein in Formula (G1):
at least one of R^{A} or R^{B} is C₁ to C₁₀ chain alkyl or C₃ to C₁₀ cycloalkyl; and
R^{C1} is selected from one of hydrogen, C₁ to C₁₀ chain alkyl, C₃ to C₁₀ cycloalkyl, C₁ to C₁₀ alkoxy, substituted or unsubstituted C₆ to C₃₀ arylamino, substituted or unsubstituted C₃ to C₃₀ heteroarylamino, substituted or unsubstituted C₆ to C₃₀ aryl or substituted or unsubstituted C₃ to C₃₀ heteroaryl.

7. The organic electroluminescent device according to claim 1, wherein Formula (G) is one of the following Formulas a, b, c or d: 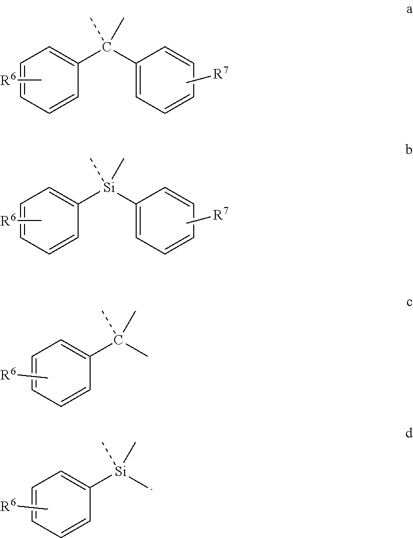
wherein R⁶ and R⁷ are each independently selected from one or a combination of at least two of hydrogen, deuterium, halogen, C₁ to C₁₀ chain alkyl or C₃ to C₁₀ cycloalkyl.

8. The organic electroluminescent device according to claim 1, wherein the fluorescent dye is selected from any one or a combination of at least two of the following compounds M1 to M144:

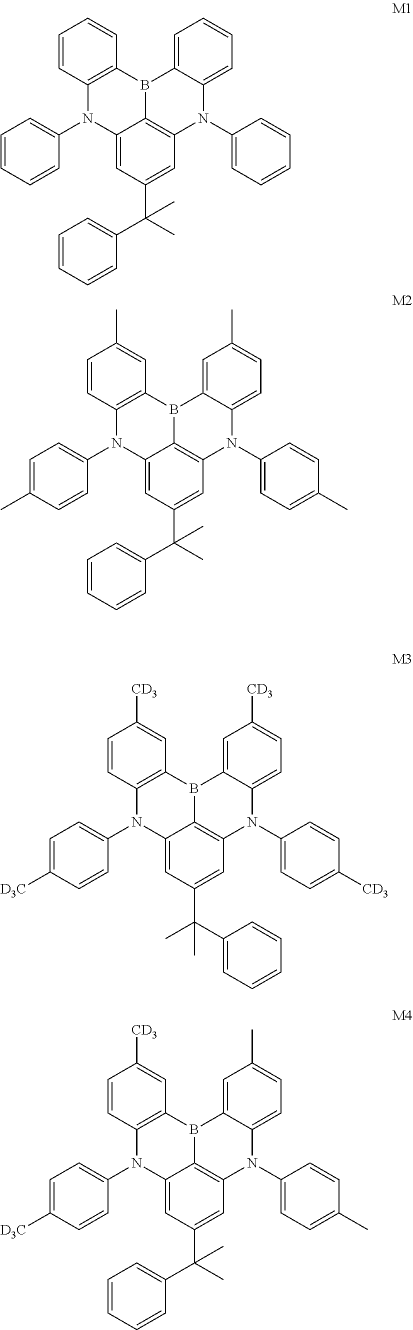

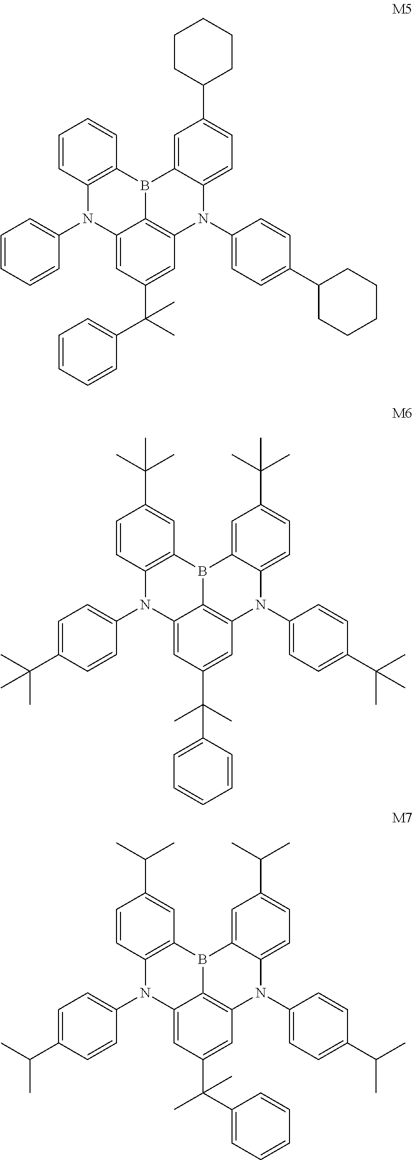

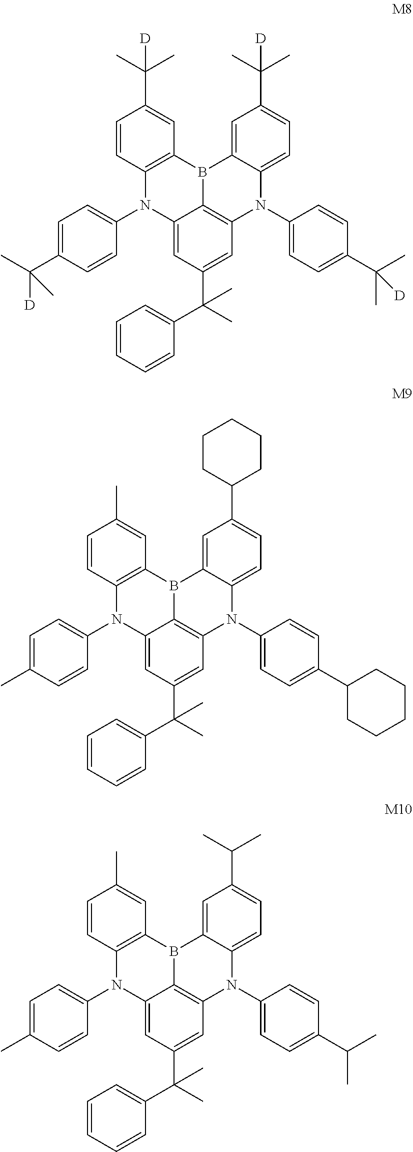

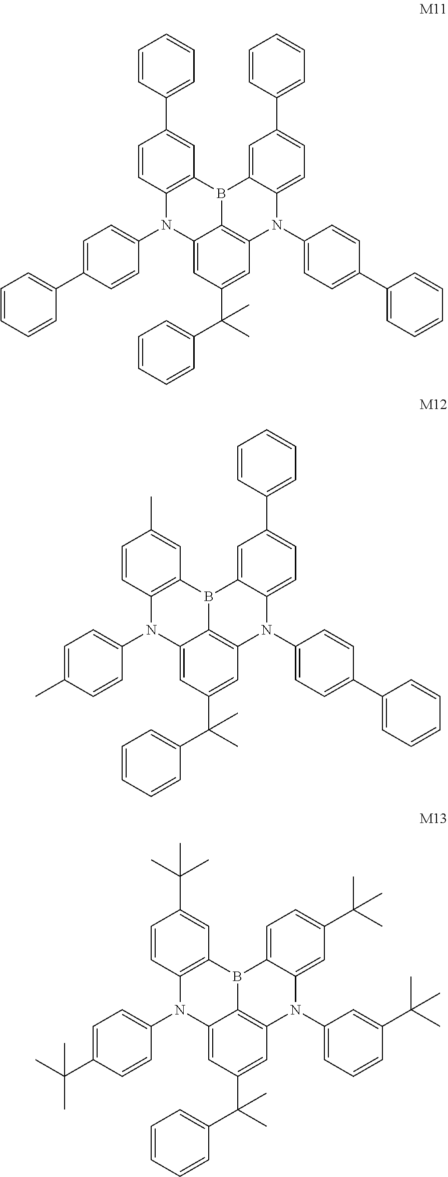 [SMILES: CC(C)(c1ccccc1)c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1 ; Cc1ccc(N2c3ccc(C)cc3B3c4cc(-c5ccccc5)ccc4N(c4ccc(-c5ccccc5)cc4)c4cc(C(C)(C)c5ccccc5)cc2c43)cc1 ; CC(C)(C)c1ccc(N2c3ccc(C(C)(C)C)cc3B3c4ccc(C(C)(C)C)cc4N(c4cccc(C(C)(C)C)c4)c4cc(C(C)(C)c5ccccc5)cc2c43)cc1]

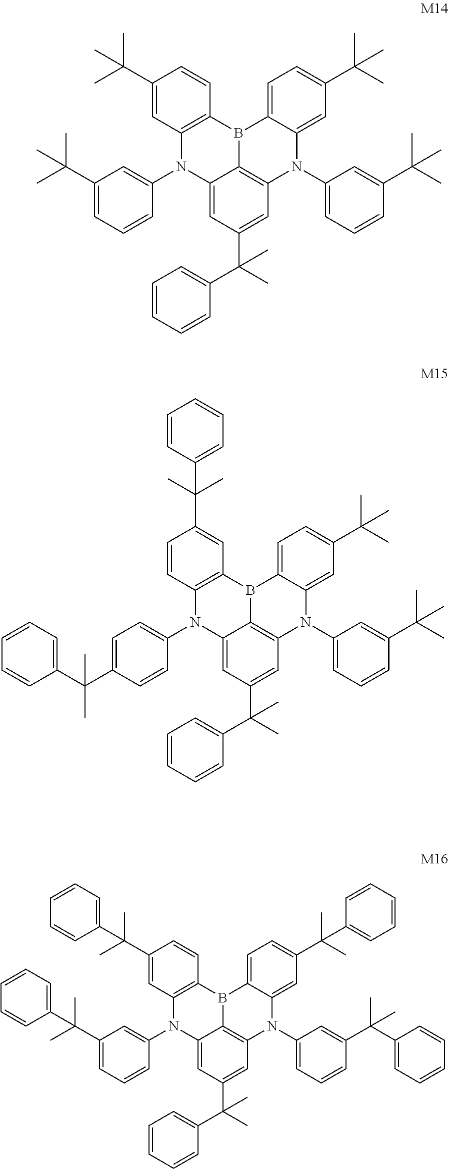 [SMILES: CC(C)(C)c1cccc(N2c3cc(C(C)(C)C)ccc3B3c4ccc(C(C)(C)C)cc4N(c4cccc(C(C)(C)C)c4)c4cc(C(C)(C)c5ccccc5)cc2c43)c1 ; CC(C)(C)c1cccc(N2c3cc(C(C)(C)C)ccc3B3c4cc(C(C)(C)c5ccccc5)ccc4N(c4ccc(C(C)(C)c5ccccc5)cc4)c4cc(C(C)(C)c5ccccc5)cc2c43)c1 ; CC(C)(c1ccccc1)c1cccc(N2c3cc(C(C)(C)c4ccccc4)ccc3B3c4ccc(C(C)(C)c5ccccc5)cc4N(c4cccc(C(C)(C)c5ccccc5)c4)c4cc(C(C)(C)c5ccccc5)cc2c43)c1]

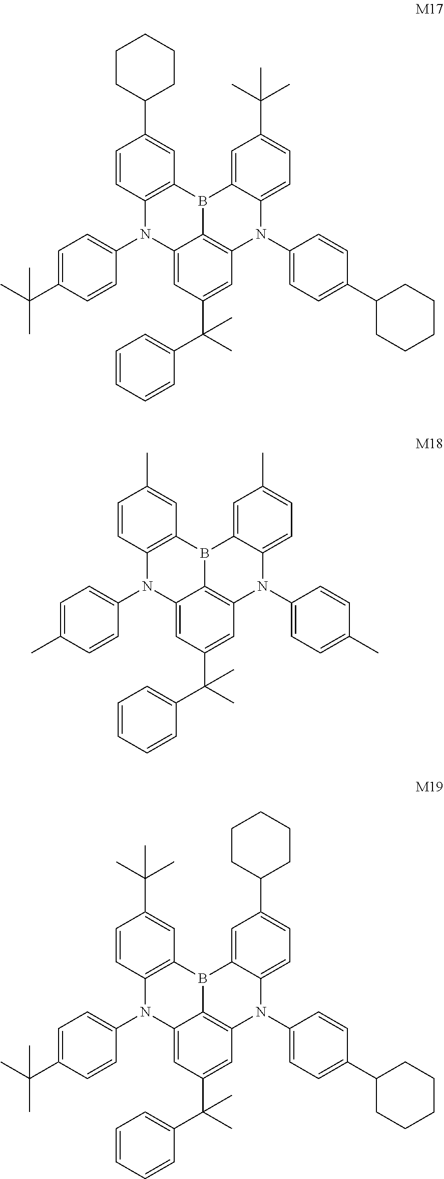

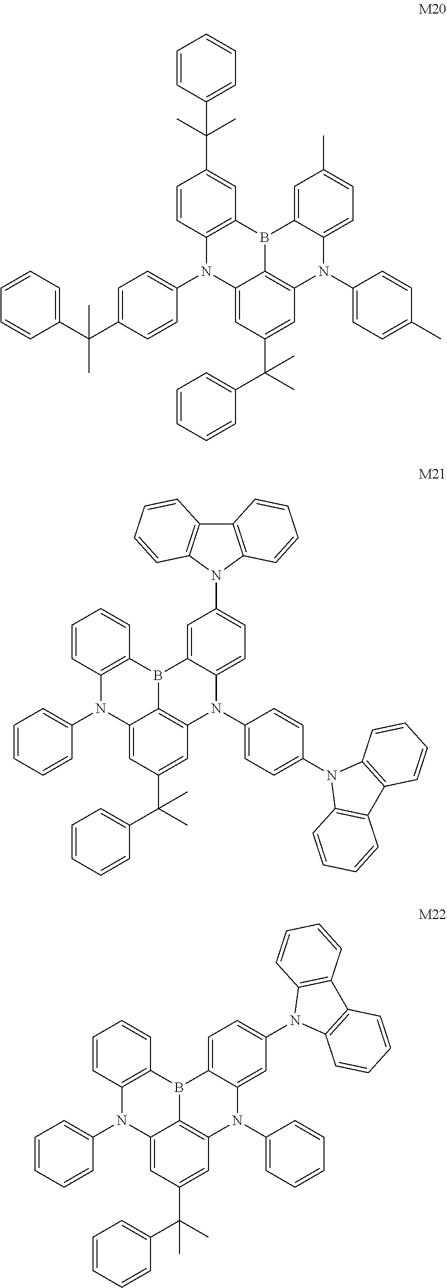 [SMILES: Cc1ccc(N2c3ccc(C)cc3B3c4cc(C(C)(C)c5ccccc5)ccc4N(c4ccc(C(C)(C)c5ccccc5)cc4)c4cc(C(C)(C)c5ccccc5)cc2c43)cc1 ; CC(C)(c1ccccc1)c1cc2c3c(c1)N(c1ccc(-n4c5ccccc5c5ccccc54)cc1)c1ccc(-n4c5ccccc5c5ccccc54)cc1B3c1ccccc1N2c1ccccc1 ; CC(C)(c1ccccc1)c1cc2c3c(c1)N(c1ccccc1)c1cc(-n4c5ccccc5c5ccccc54)ccc1B3c1ccccc1N2c1ccccc1]

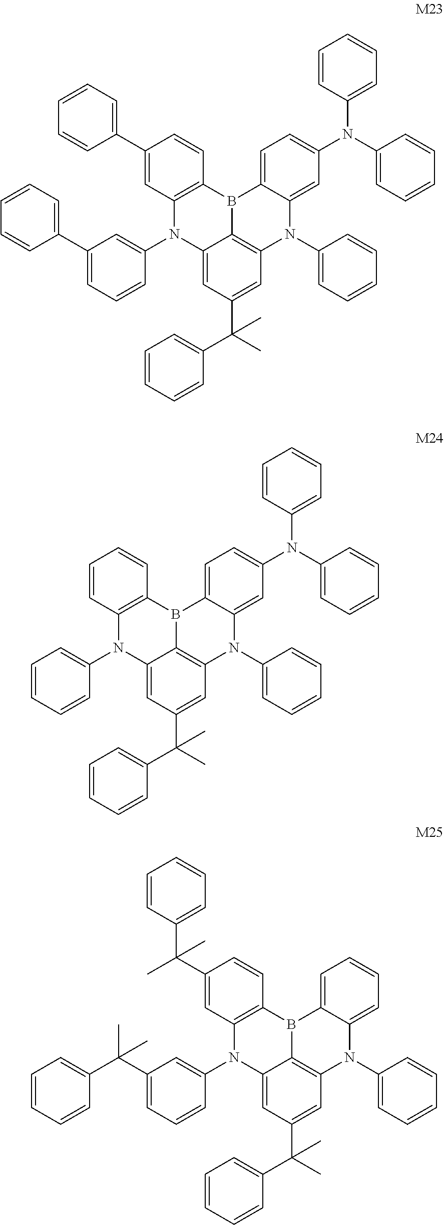 [SMILES: CC(C)(c1ccccc1)c1cc2c3c(c1)N(c1ccccc1)c1cc(N(c4ccccc4)c4ccccc4)ccc1B3c1ccc(-c3ccccc3)cc1N2c1cccc(-c2ccccc2)c1 ; CC(C)(c1ccccc1)c1cc2c3c(c1)N(c1ccccc1)c1cc(N(c4ccccc4)c4ccccc4)ccc1B3c1ccccc1N2c1ccccc1 ; CC(C)(c1ccccc1)c1cccc(N2c3cc(C(C)(C)c4ccccc4)ccc3B3c4ccccc4N(c4ccccc4)c4cc(C(C)(C)c5ccccc5)cc2c43)c1]

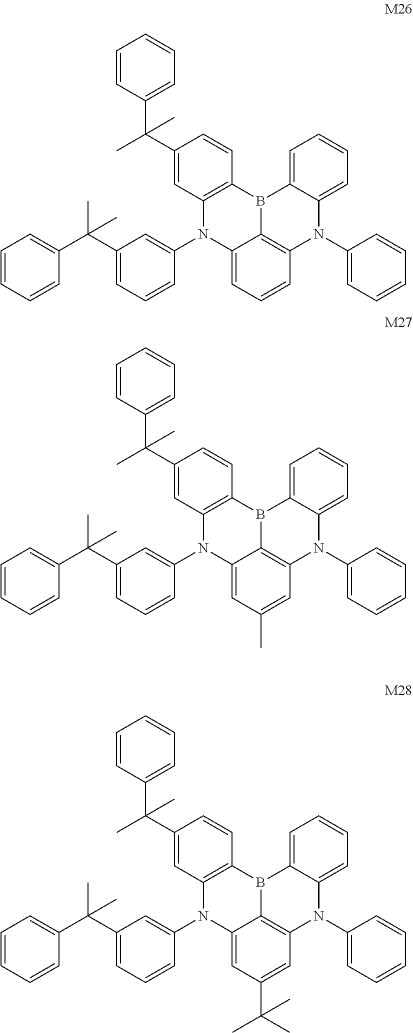 [SMILES: CC(C)(c1ccccc1)c1cccc(N2c3cc(C(C)(C)c4ccccc4)ccc3B3c4ccccc4N(c4ccccc4)c4cccc2c43)c1 ; Cc1cc2c3c(c1)N(c1cccc(C(C)(C)c4ccccc4)c1)c1cc(C(C)(C)c4ccccc4)ccc1B3c1ccccc1N2c1ccccc1 ; CC(C)(C)c1cc2c3c(c1)N(c1cccc(C(C)(C)c4ccccc4)c1)c1cc(C(C)(C)c4ccccc4)ccc1B3c1ccccc1N2c1ccccc1]

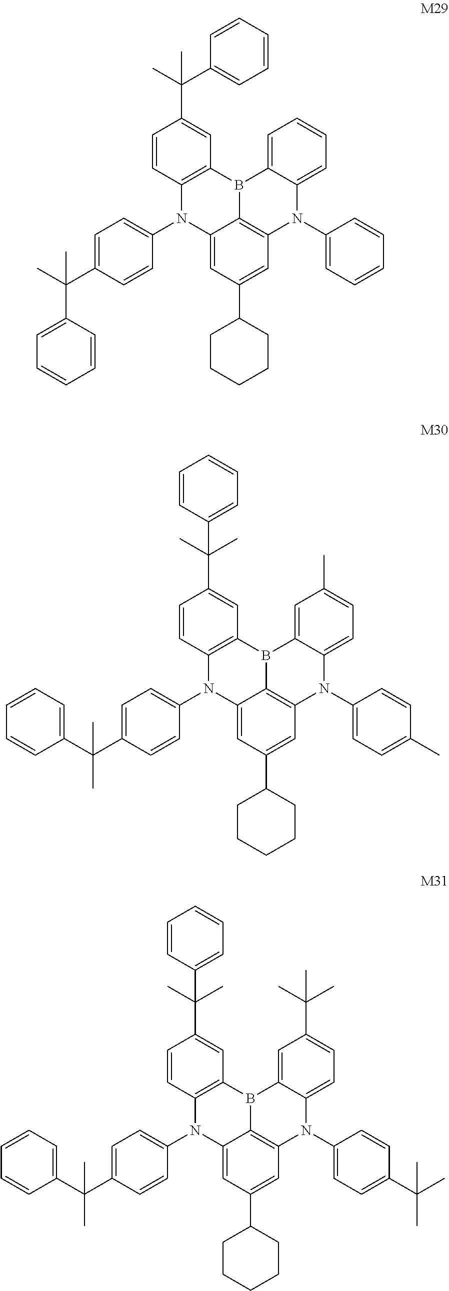 [SMILES: CC(C)(c1ccccc1)c1ccc(N2c3ccc(C(C)(C)c4ccccc4)cc3B3c4ccccc4N(c4ccccc4)c4cc(C5CCCCC5)cc2c43)cc1 ; Cc1ccc(N2c3ccc(C)cc3B3c4cc(C(C)(C)c5ccccc5)ccc4N(c4ccc(C(C)(C)c5ccccc5)cc4)c4cc(C5CCCCC5)cc2c43)cc1 ; CC(C)(C)c1ccc(N2c3ccc(C(C)(C)C)cc3B3c4cc(C(C)(C)c5ccccc5)ccc4N(c4ccc(C(C)(C)c5ccccc5)cc4)c4cc(C5CCCCC5)cc2c43)cc1]

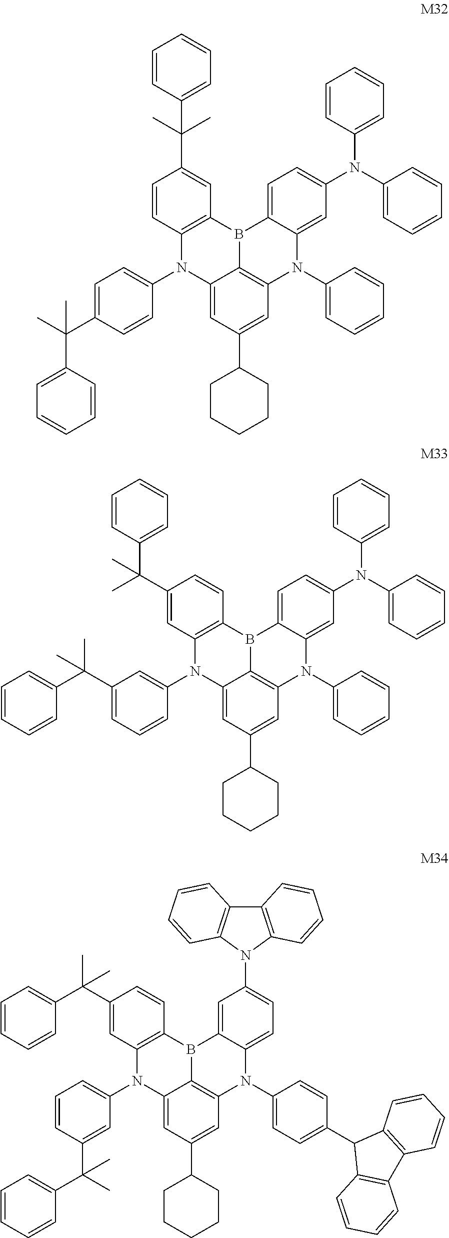 [SMILES: CC(C)(c1ccccc1)c1ccc(N2c3ccc(C(C)(C)c4ccccc4)cc3B3c4ccc(N(c5ccccc5)c5ccccc5)cc4N(c4ccccc4)c4cc(C5CCCCC5)cc2c43)cc1 ; CC(C)(c1ccccc1)c1cccc(N2c3cc(C(C)(C)c4ccccc4)ccc3B3c4ccc(N(c5ccccc5)c5ccccc5)cc4N(c4ccccc4)c4cc(C5CCCCC5)cc2c43)c1 ; CC(C)(c1ccccc1)c1cccc(N2c3cc(C(C)(C)c4ccccc4)ccc3B3c4cc(-n5c6ccccc6c6ccccc65)ccc4N(c4ccc(C5c6ccccc6-c6ccccc65)cc4)c4cc(C5CCCCC5)cc2c43)c1]

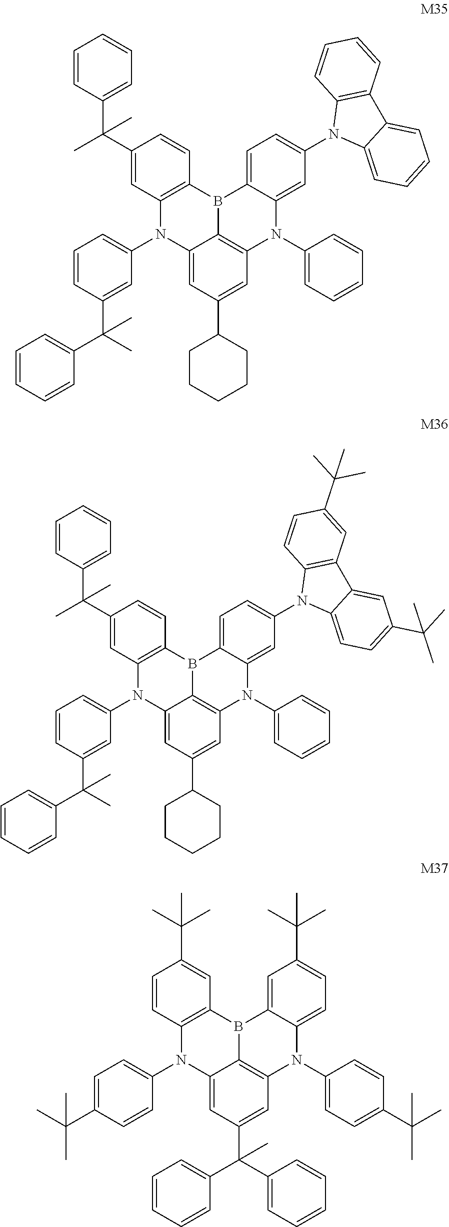

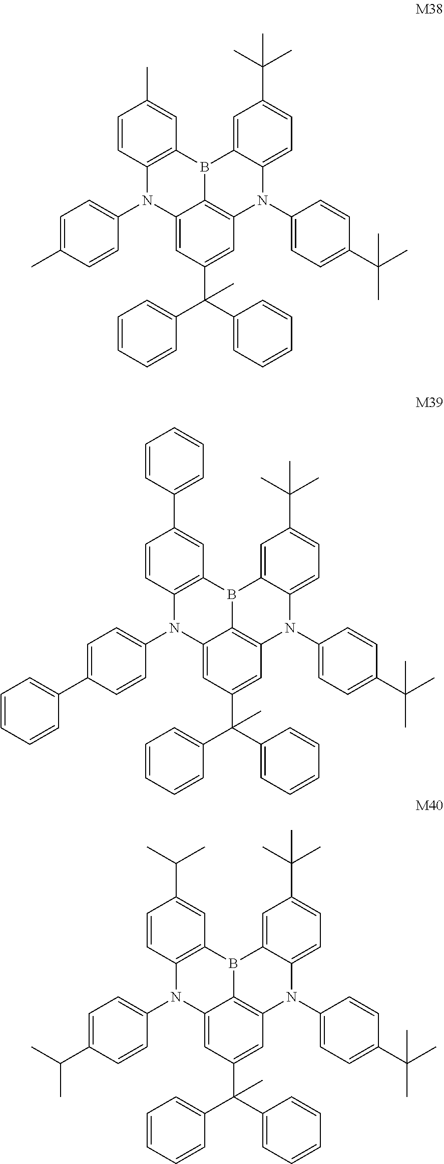

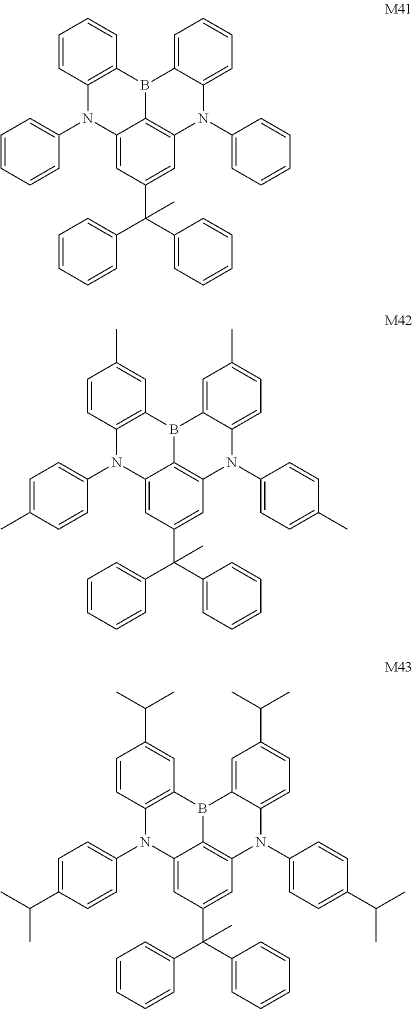

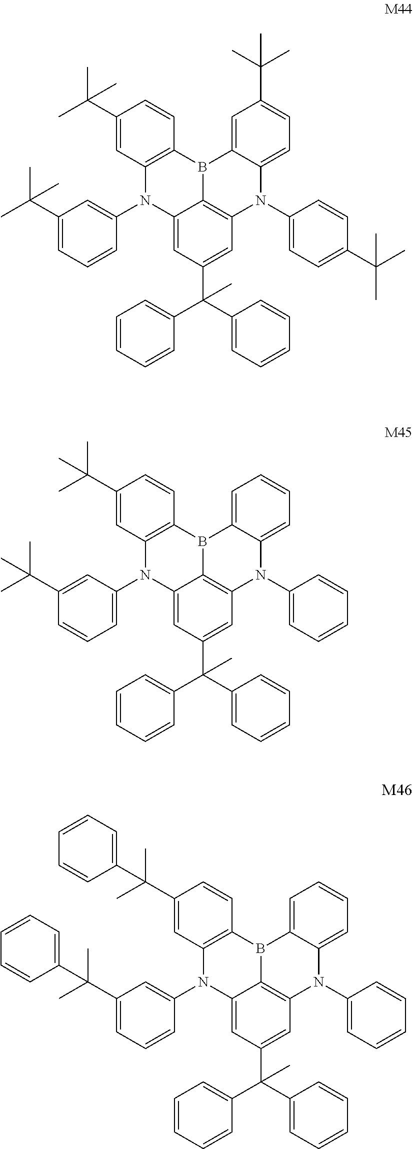

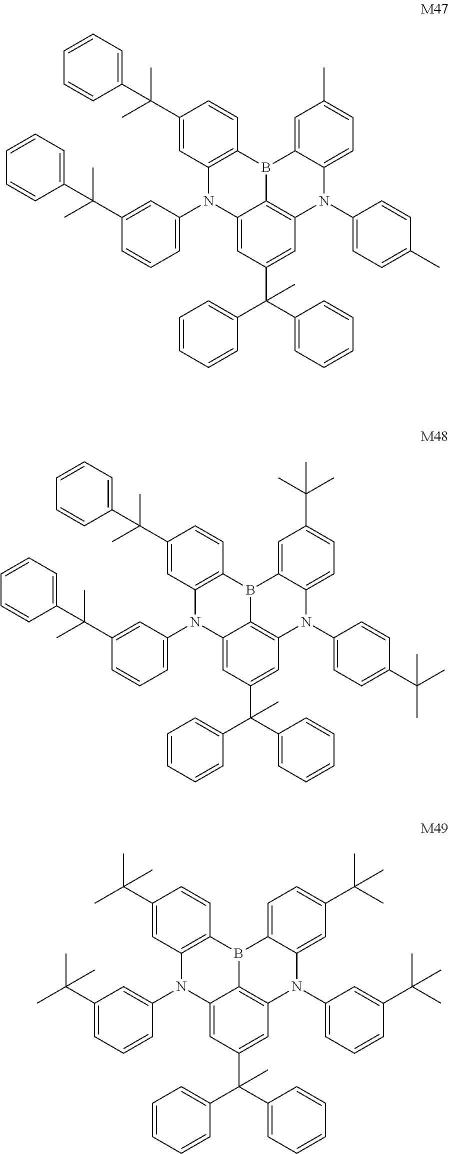

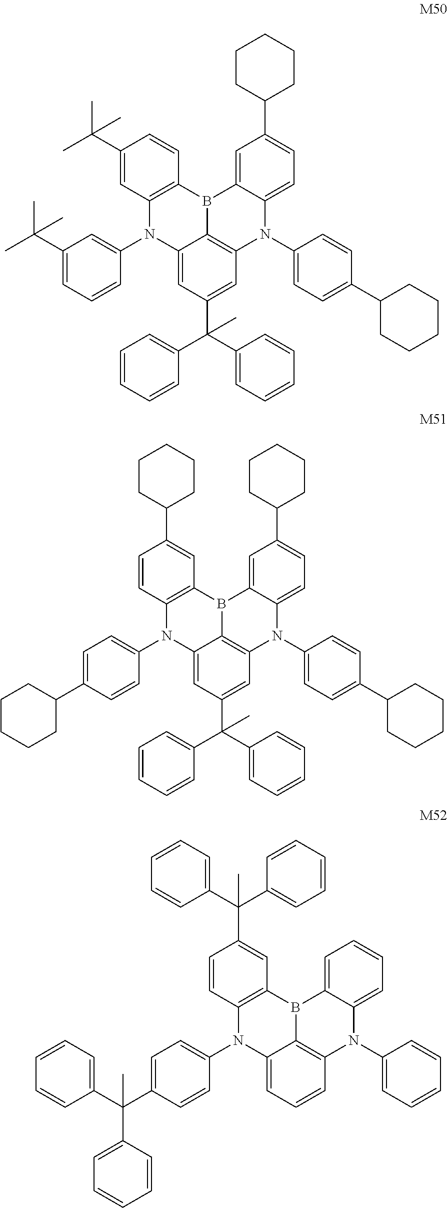

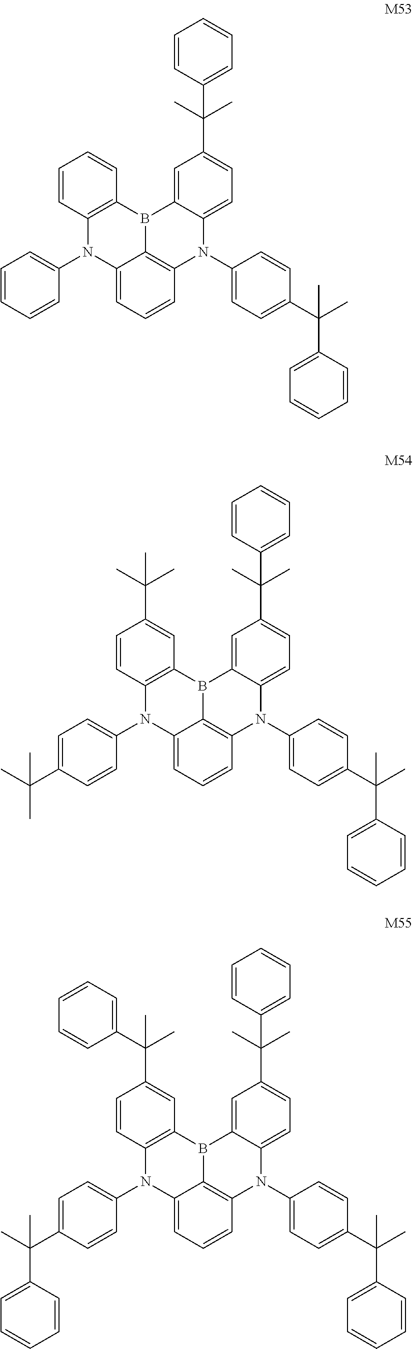 [SMILES: CC(C)(c1ccccc1)c1ccc(N2c3ccc(C(C)(C)c4ccccc4)cc3B3c4ccccc4N(c4ccccc4)c4cccc2c43)cc1 ; CC(C)(C)c1ccc(N2c3ccc(C(C)(C)C)cc3B3c4cc(C(C)(C)c5ccccc5)ccc4N(c4ccc(C(C)(C)c5ccccc5)cc4)c4cccc2c43)cc1 ; CC(C)(c1ccccc1)c1ccc(N2c3ccc(C(C)(C)c4ccccc4)cc3B3c4cc(C(C)(C)c5ccccc5)ccc4N(c4ccc(C(C)(C)c5ccccc5)cc4)c4cccc2c43)cc1]

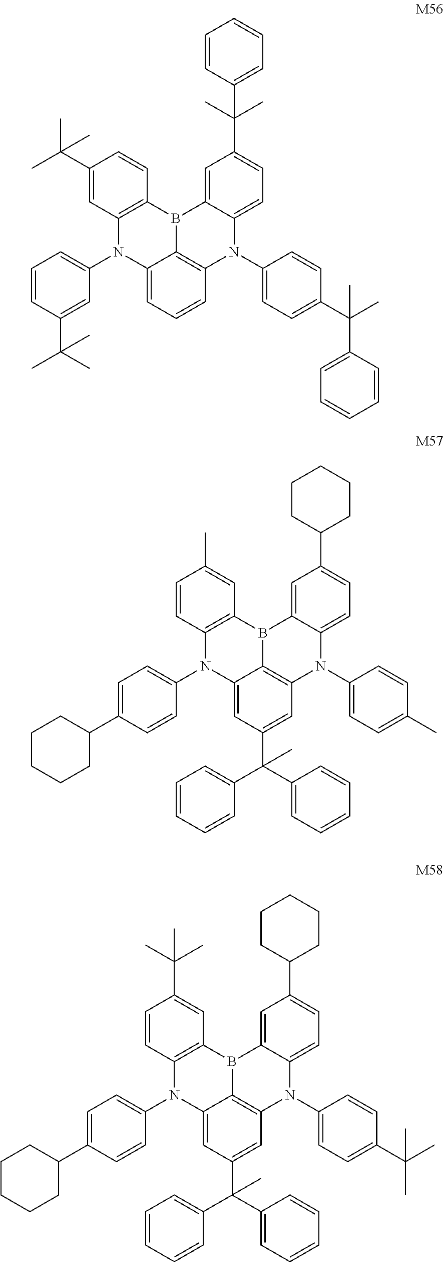 [SMILES: CC(C)(C)c1cccc(N2c3cc(C(C)(C)C)ccc3B3c4cc(C(C)(C)c5ccccc5)ccc4N(c4ccc(C(C)(C)c5ccccc5)cc4)c4cccc2c43)c1 ; Cc1ccc(N2c3ccc(C4CCCCC4)cc3B3c4cc(C)ccc4N(c4ccc(C5CCCCC5)cc4)c4cc(C(C)(c5ccccc5)c5ccccc5)cc2c43)cc1 ; CC(C)(C)c1ccc(N2c3ccc(C4CCCCC4)cc3B3c4cc(C(C)(C)C)ccc4N(c4ccc(C5CCCCC5)cc4)c4cc(C(C)(c5ccccc5)c5ccccc5)cc2c43)cc1]

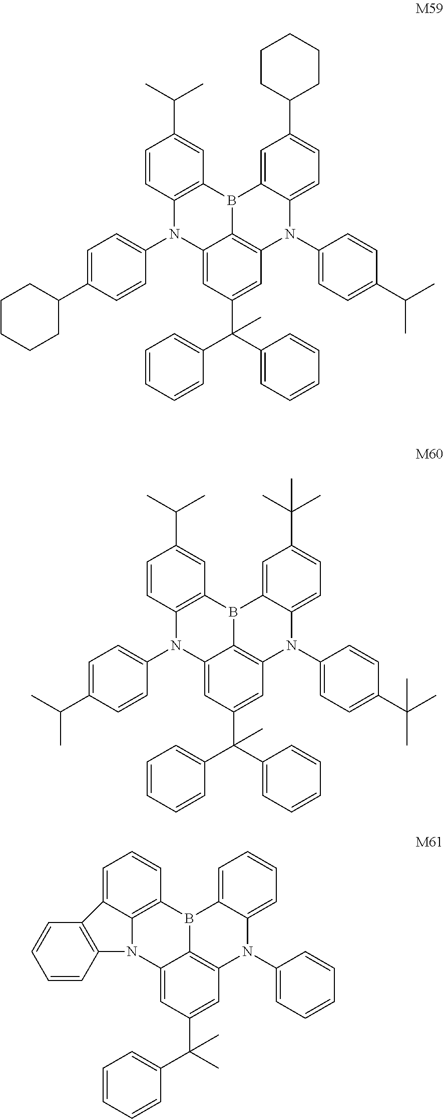

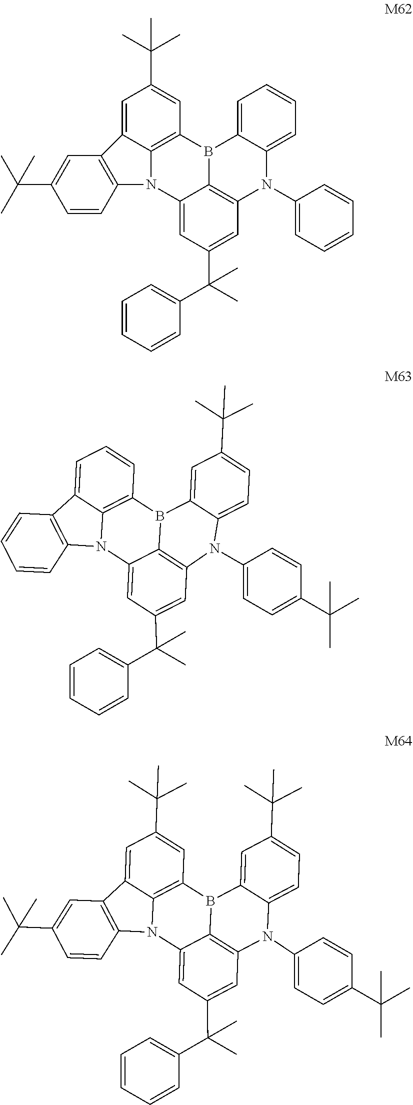

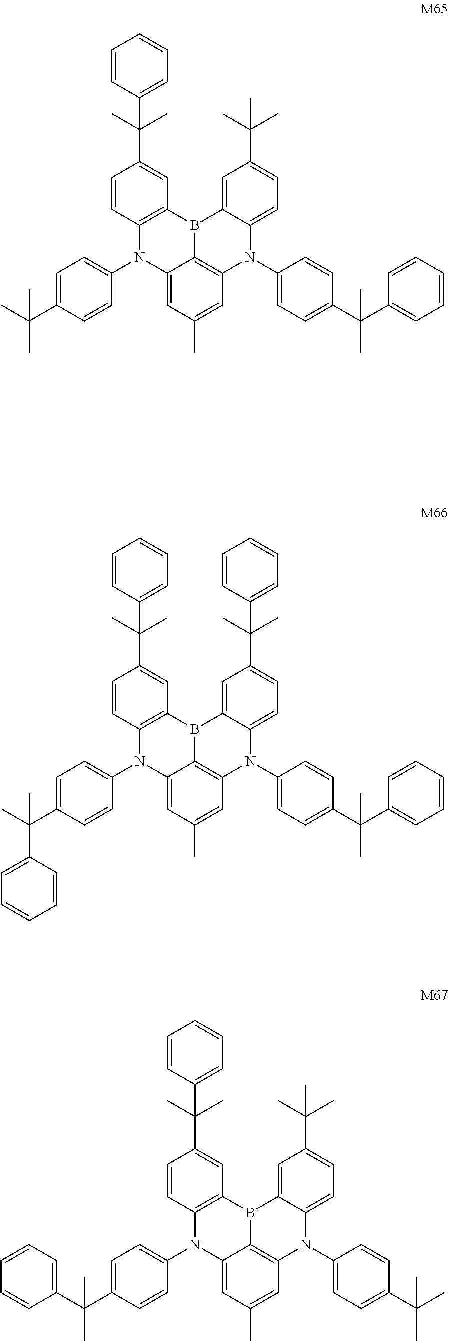 [SMILES: Cc1cc2c3c(c1)N(c1ccc(C(C)(C)C)cc1)c1ccc(C(C)(C)c4ccccc4)cc1B3c1cc(C(C)(C)C)ccc1N2c1ccc(C(C)(C)c2ccccc2)cc1 ; Cc1cc2c3c(c1)N(c1ccc(C(C)(C)c4ccccc4)cc1)c1ccc(C(C)(C)c4ccccc4)cc1B3c1cc(C(C)(C)c3ccccc3)ccc1N2c1ccc(C(C)(C)c2ccccc2)cc1 ; Cc1cc2c3c(c1)N(c1ccc(C(C)(C)c4ccccc4)cc1)c1ccc(C(C)(C)c4ccccc4)cc1B3c1cc(C(C)(C)C)ccc1N2c1ccc(C(C)(C)C)cc1]

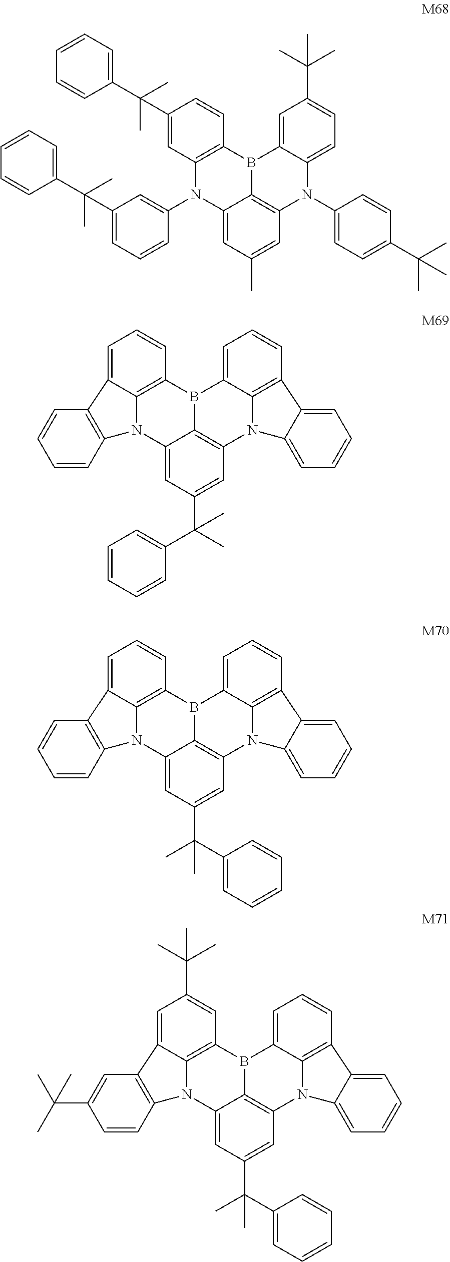

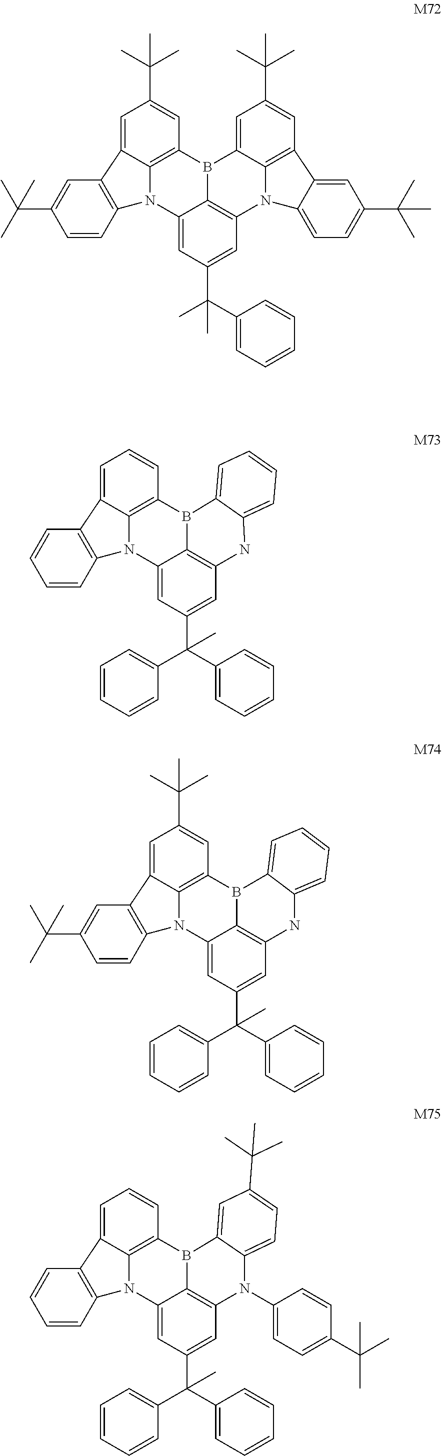

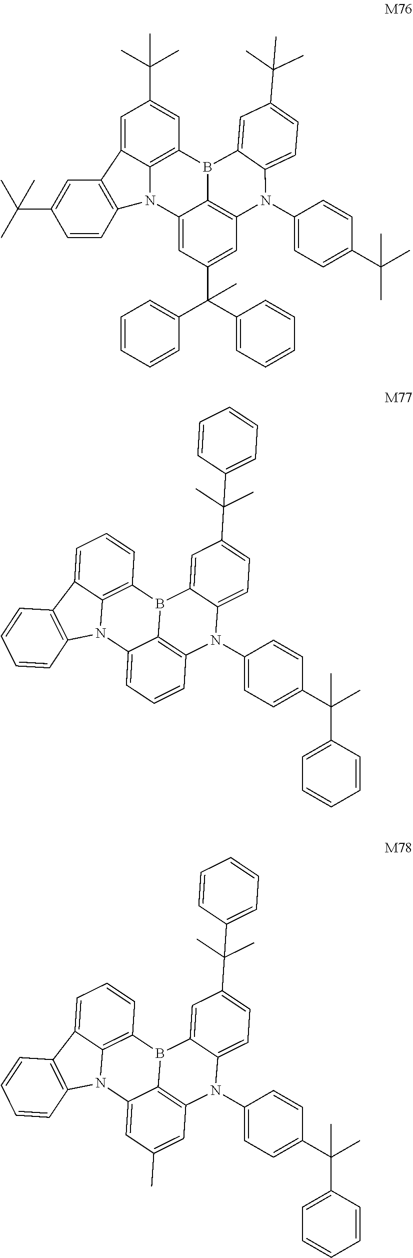 [SMILES: CC(C)(C)c1ccc(N2c3ccc(C(C)(C)C)cc3B3c4c2cc(C(C)(c2ccccc2)c2ccccc2)cc4-n2c4ccc(C(C)(C)C)cc4c4cc(C(C)(C)C)cc3c42)cc1 ; CC(C)(c1ccccc1)c1ccc(N2c3ccc(C(C)(C)c4ccccc4)cc3B3c4c2cccc4-n2c4ccccc4c4cccc3c42)cc1 ; Cc1cc2c3c(c1)-n1c4ccccc4c4cccc(c41)B3c1cc(C(C)(C)c3ccccc3)ccc1N2c1ccc(C(C)(C)c2ccccc2)cc1]

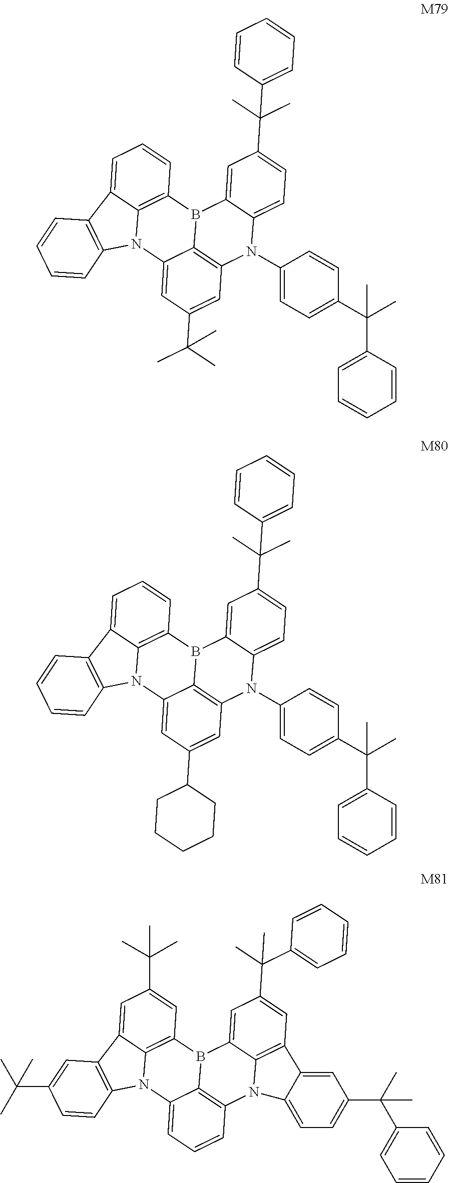 [SMILES: CC(C)(C)c1cc2c3c(c1)-n1c4ccccc4c4cccc(c41)B3c1cc(C(C)(C)c3ccccc3)ccc1N2c1ccc(C(C)(C)c2ccccc2)cc1 ; CC(C)(c1ccccc1)c1ccc(N2c3ccc(C(C)(C)c4ccccc4)cc3B3c4c2cc(C2CCCCC2)cc4-n2c4ccccc4c4cccc3c42)cc1 ; CC(C)(C)c1ccc2c(c1)c1cc(C(C)(C)C)cc3c1n2-c1cccc2c1B3c1cc(C(C)(C)c3ccccc3)cc3c4cc(C(C)(C)c5ccccc5)ccc4n-2c13]

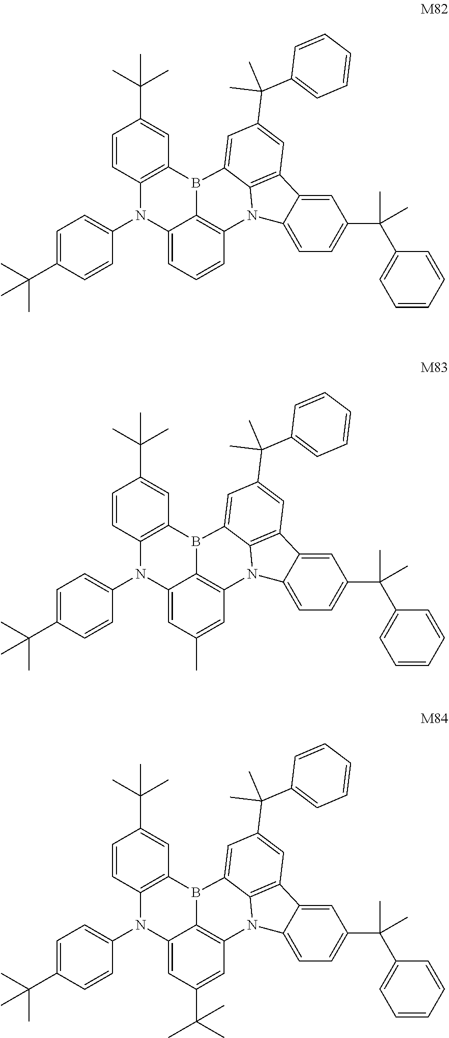 [SMILES: CC(C)(C)c1ccc(N2c3ccc(C(C)(C)C)cc3B3c4c2cccc4-n2c4ccc(C(C)(C)c5ccccc5)cc4c4cc(C(C)(C)c5ccccc5)cc3c42)cc1 ; Cc1cc2c3c(c1)-n1c4ccc(C(C)(C)c5ccccc5)cc4c4cc(C(C)(C)c5ccccc5)cc(c41)B3c1cc(C(C)(C)C)ccc1N2c1ccc(C(C)(C)C)cc1 ; CC(C)(C)c1ccc(N2c3ccc(C(C)(C)C)cc3B3c4c2cc(C(C)(C)C)cc4-n2c4ccc(C(C)(C)c5ccccc5)cc4c4cc(C(C)(C)c5ccccc5)cc3c42)cc1]

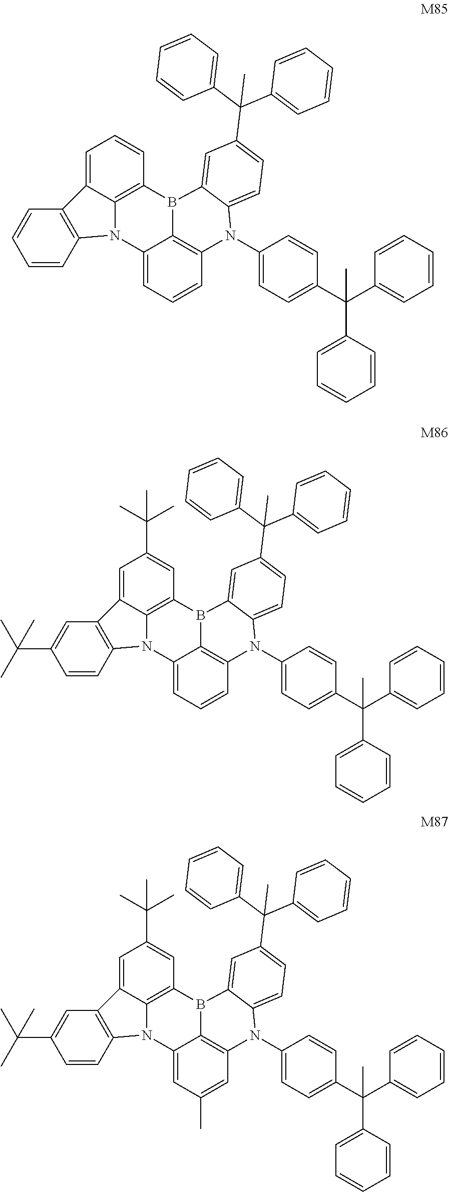 [SMILES: CC(c1ccccc1)(c1ccccc1)c1ccc(N2c3ccc(C(C)(c4ccccc4)c4ccccc4)cc3B3c4c2cccc4-n2c4ccccc4c4cccc3c42)cc1 ; CC(C)(C)c1ccc2c(c1)c1cc(C(C)(C)C)cc3c1n2-c1cccc2c1B3c1cc(C(C)(c3ccccc3)c3ccccc3)ccc1N2c1ccc(C(C)(c2ccccc2)c2ccccc2)cc1 ; Cc1cc2c3c(c1)-n1c4ccc(C(C)(C)C)cc4c4cc(C(C)(C)C)cc(c41)B3c1cc(C(C)(c3ccccc3)c3ccccc3)ccc1N2c1ccc(C(C)(c2ccccc2)c2ccccc2)cc1]

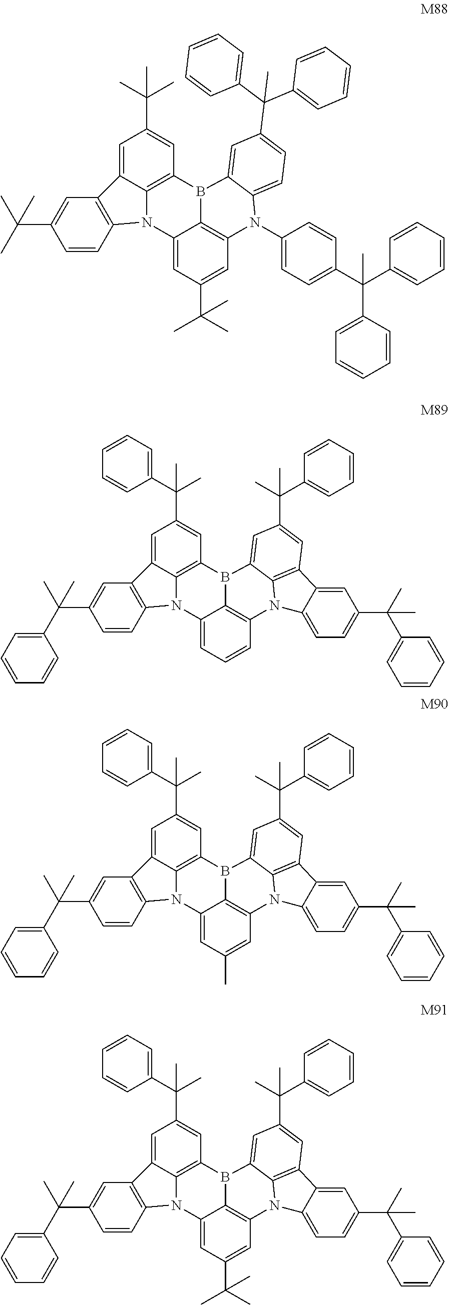

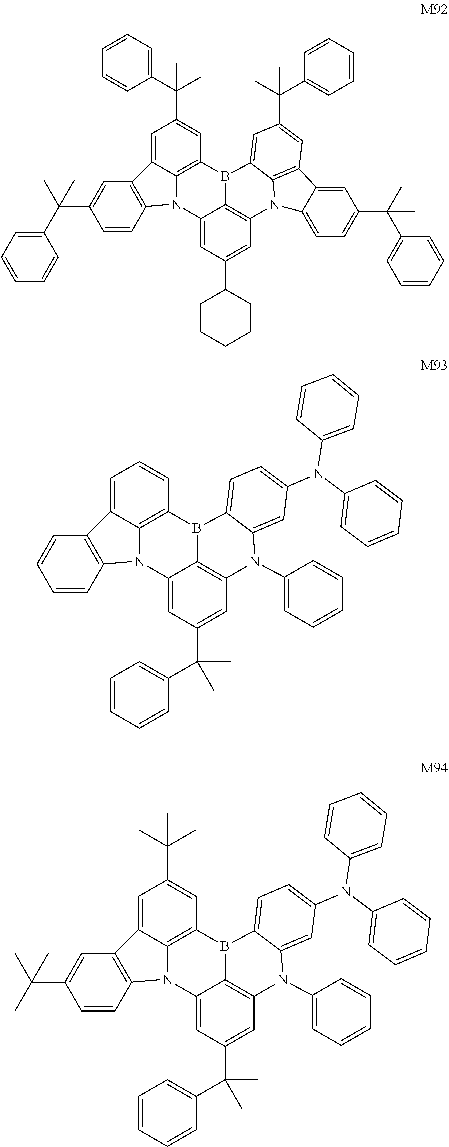 [SMILES: CC(C)(c1ccccc1)c1ccc2c(c1)c1cc(C(C)(C)c3ccccc3)cc3c1n2-c1cc(C2CCCCC2)cc2c1B3c1cc(C(C)(C)c3ccccc3)cc3c4cc(C(C)(C)c5ccccc5)ccc4n-2c13 ; CC(C)(c1ccccc1)c1cc2c3c(c1)-n1c4ccccc4c4cccc(c41)B3c1ccc(N(c3ccccc3)c3ccccc3)cc1N2c1ccccc1 ; CC(C)(C)c1ccc2c(c1)c1cc(C(C)(C)C)cc3c1n2-c1cc(C(C)(C)c2ccccc2)cc2c1B3c1ccc(N(c3ccccc3)c3ccccc3)cc1N2c1ccccc1]

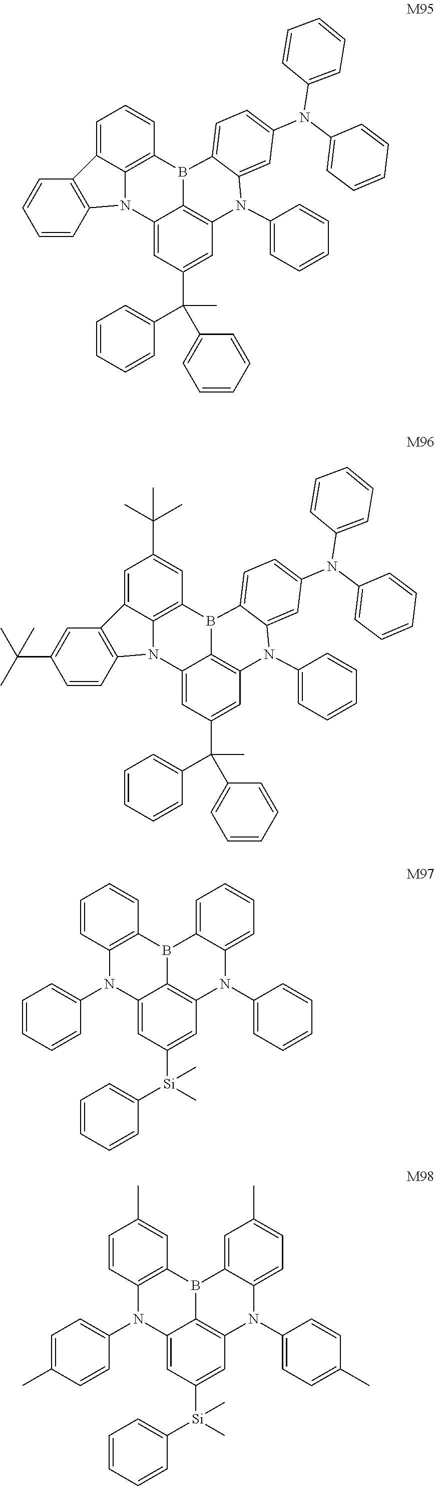

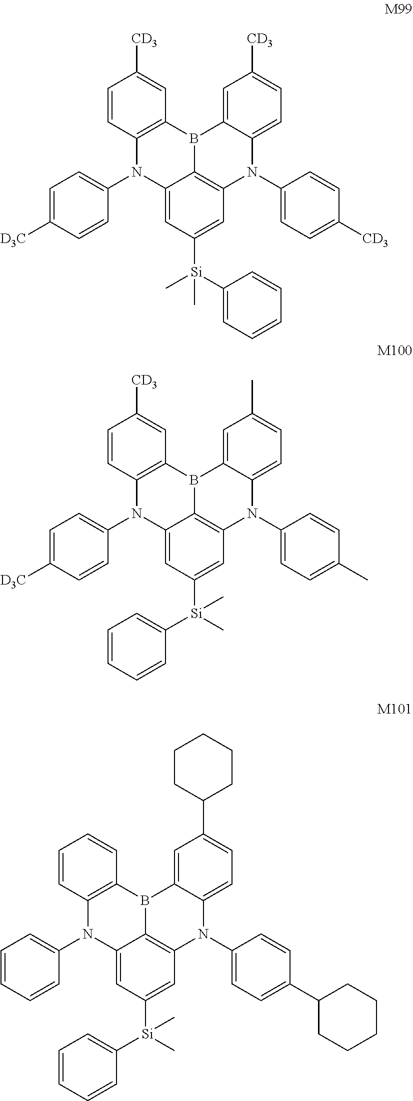

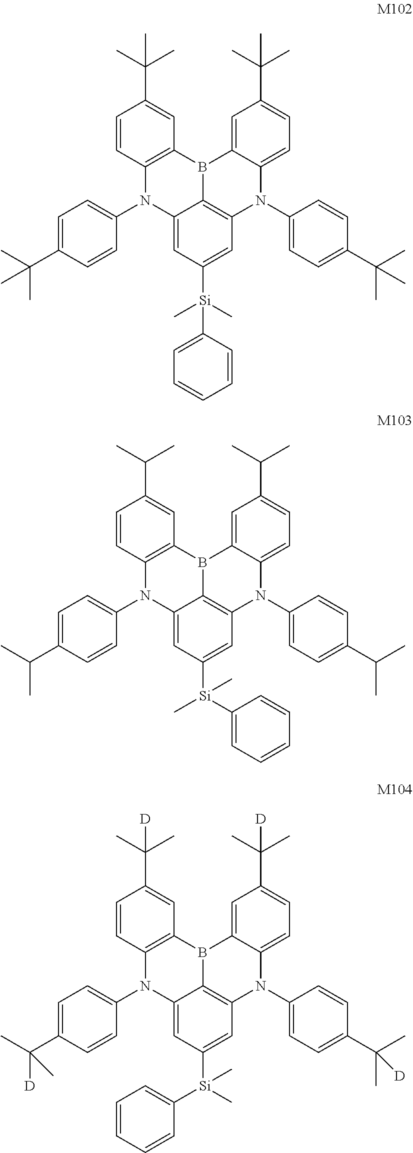

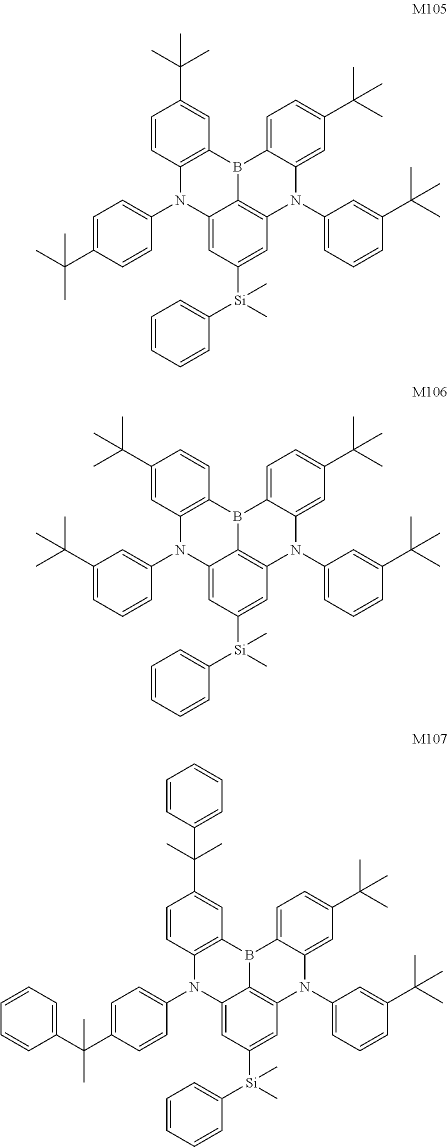

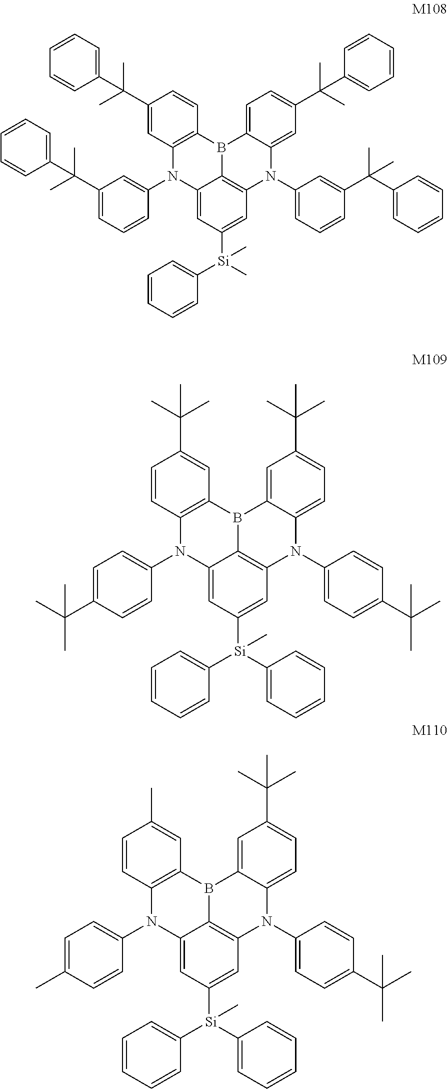

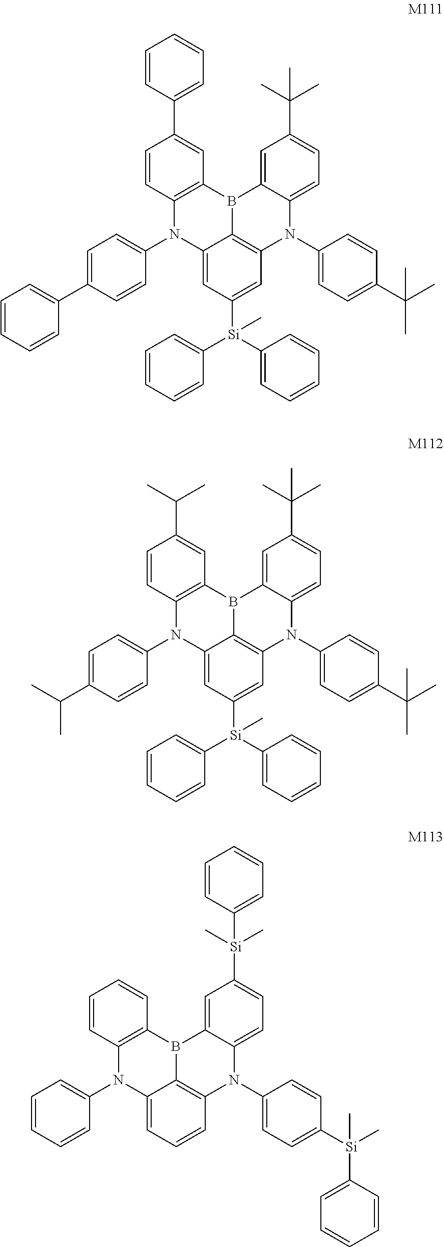

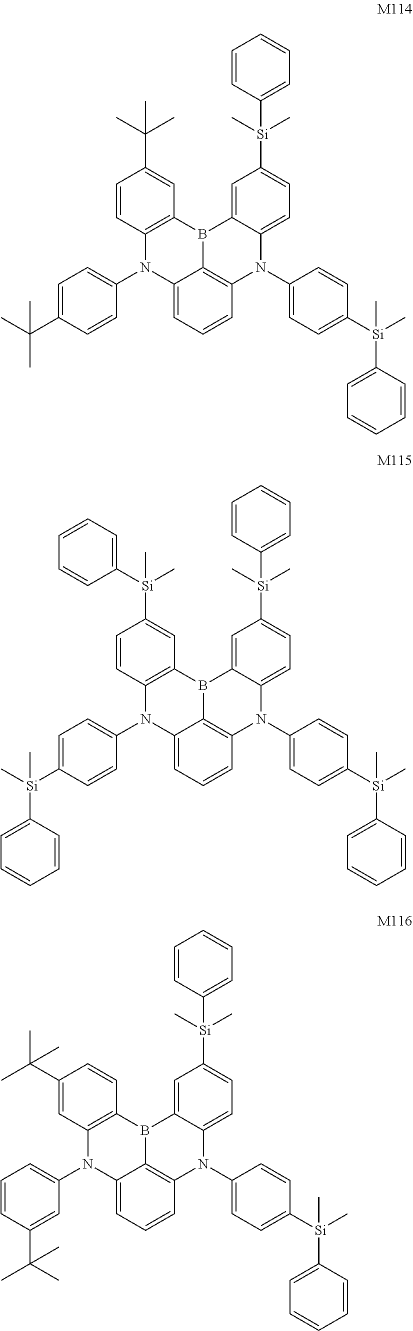 [SMILES: CC(C)(C)c1ccc(N2c3ccc(C(C)(C)C)cc3B3c4cc([Si](C)(C)c5ccccc5)ccc4N(c4ccc([Si](C)(C)c5ccccc5)cc4)c4cccc2c43)cc1 ; C[Si](C)(c1ccccc1)c1ccc(N2c3ccc([Si](C)(C)c4ccccc4)cc3B3c4cc([Si](C)(C)c5ccccc5)ccc4N(c4ccc([Si](C)(C)c5ccccc5)cc4)c4cccc2c43)cc1 ; CC(C)(C)c1cccc(N2c3cc(C(C)(C)C)ccc3B3c4cc([Si](C)(C)c5ccccc5)ccc4N(c4ccc([Si](C)(C)c5ccccc5)cc4)c4cccc2c43)c1]

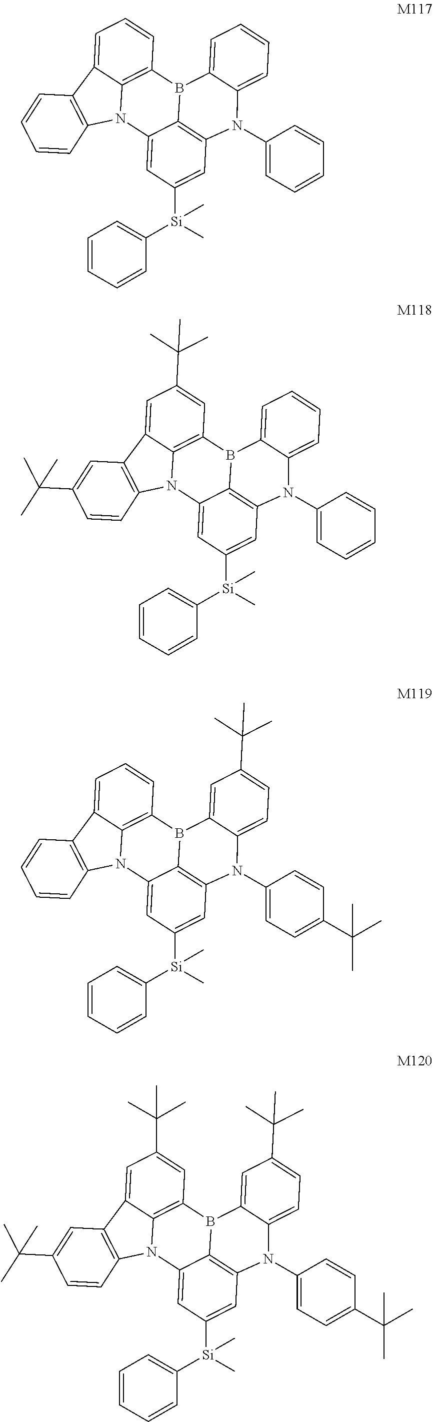

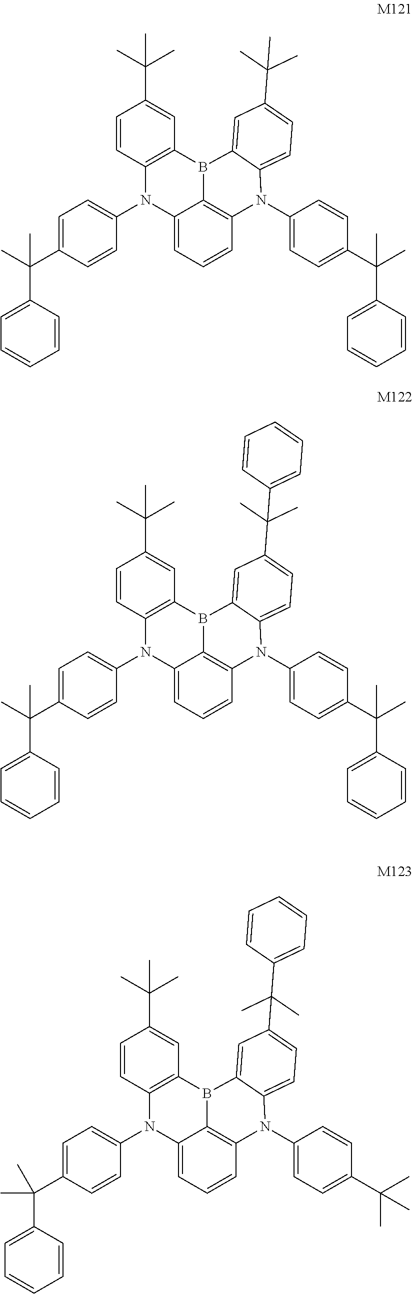 [SMILES: CC(C)(C)c1ccc2c(c1)B1c3cc(C(C)(C)C)ccc3N(c3ccc(C(C)(C)c4ccccc4)cc3)c3cccc(c31)N2c1ccc(C(C)(C)c2ccccc2)cc1 ; CC(C)(C)c1ccc2c(c1)B1c3cc(C(C)(C)c4ccccc4)ccc3N(c3ccc(C(C)(C)c4ccccc4)cc3)c3cccc(c31)N2c1ccc(C(C)(C)c2ccccc2)cc1 ; CC(C)(C)c1ccc(N2c3ccc(C(C)(C)c4ccccc4)cc3B3c4cc(C(C)(C)C)ccc4N(c4ccc(C(C)(C)c5ccccc5)cc4)c4cccc2c43)cc1]

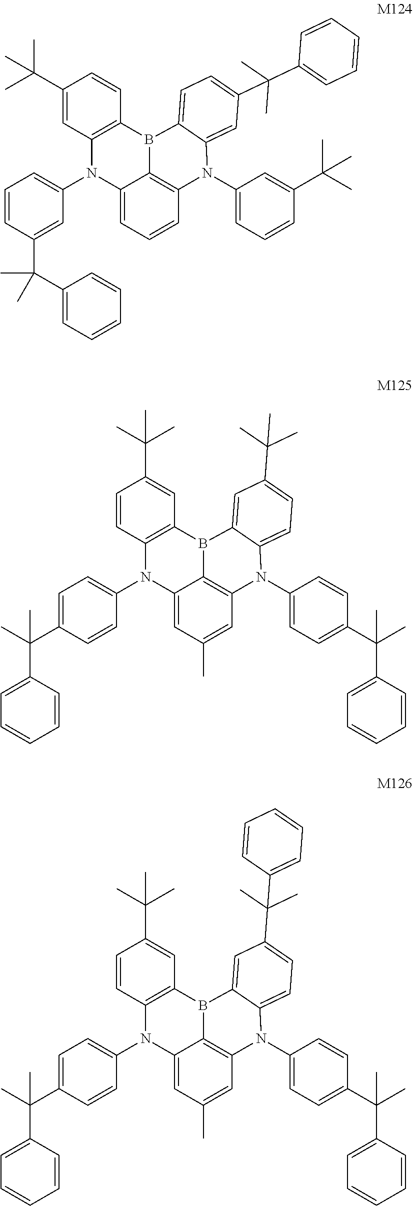 [SMILES: CC(C)(C)c1cccc(N2c3cc(C(C)(C)c4ccccc4)ccc3B3c4ccc(C(C)(C)C)cc4N(c4cccc(C(C)(C)c5ccccc5)c4)c4cccc2c43)c1 ; Cc1cc2c3c(c1)N(c1ccc(C(C)(C)c4ccccc4)cc1)c1ccc(C(C)(C)C)cc1B3c1cc(C(C)(C)C)ccc1N2c1ccc(C(C)(C)c2ccccc2)cc1 ; Cc1cc2c3c(c1)N(c1ccc(C(C)(C)c4ccccc4)cc1)c1ccc(C(C)(C)c4ccccc4)cc1B3c1cc(C(C)(C)C)ccc1N2c1ccc(C(C)(C)c2ccccc2)cc1]

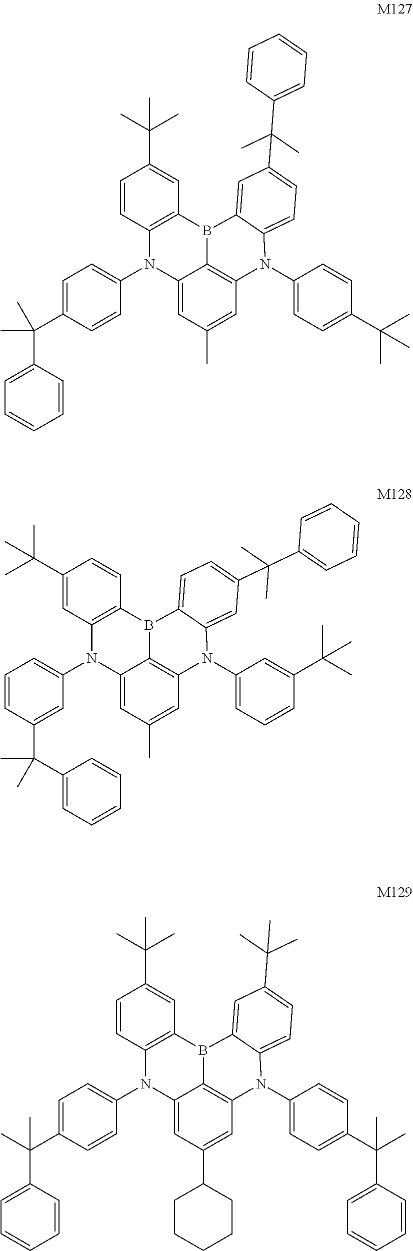

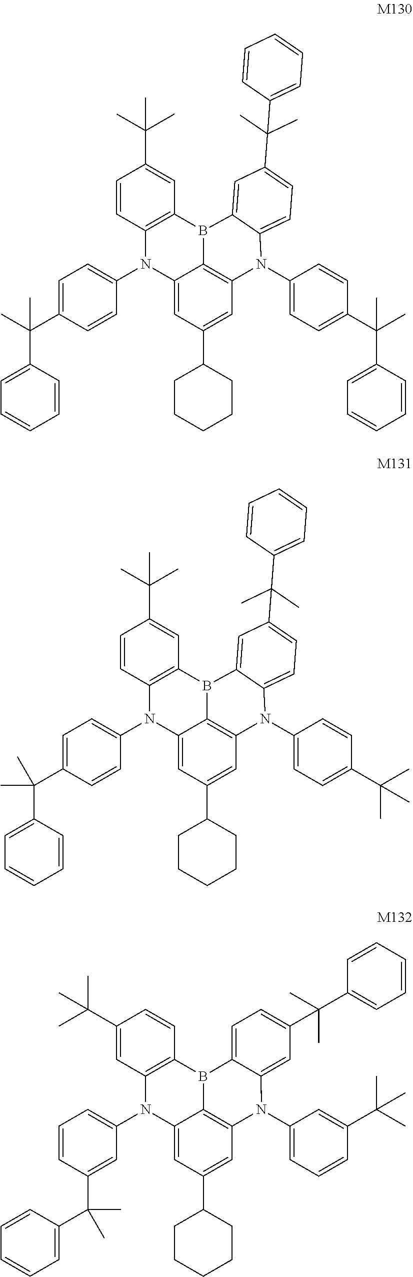 [SMILES: CC(C)(C)c1ccc2c(c1)B1c3cc(C(C)(C)c4ccccc4)ccc3N(c3ccc(C(C)(C)c4ccccc4)cc3)c3cc(C4CCCCC4)cc(c31)N2c1ccc(C(C)(C)c2ccccc2)cc1 ; CC(C)(C)c1ccc(N2c3ccc(C(C)(C)c4ccccc4)cc3B3c4cc(C(C)(C)C)ccc4N(c4ccc(C(C)(C)c5ccccc5)cc4)c4cc(C5CCCCC5)cc2c43)cc1 ; CC(C)(C)c1cccc(N2c3cc(C(C)(C)c4ccccc4)ccc3B3c4ccc(C(C)(C)C)cc4N(c4cccc(C(C)(C)c5ccccc5)c4)c4cc(C5CCCCC5)cc2c43)c1]

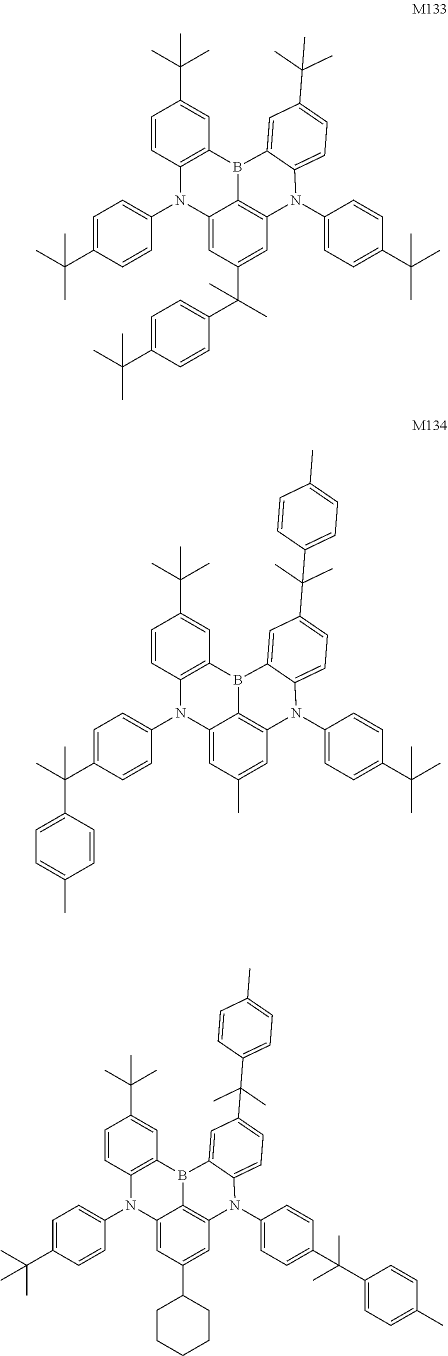

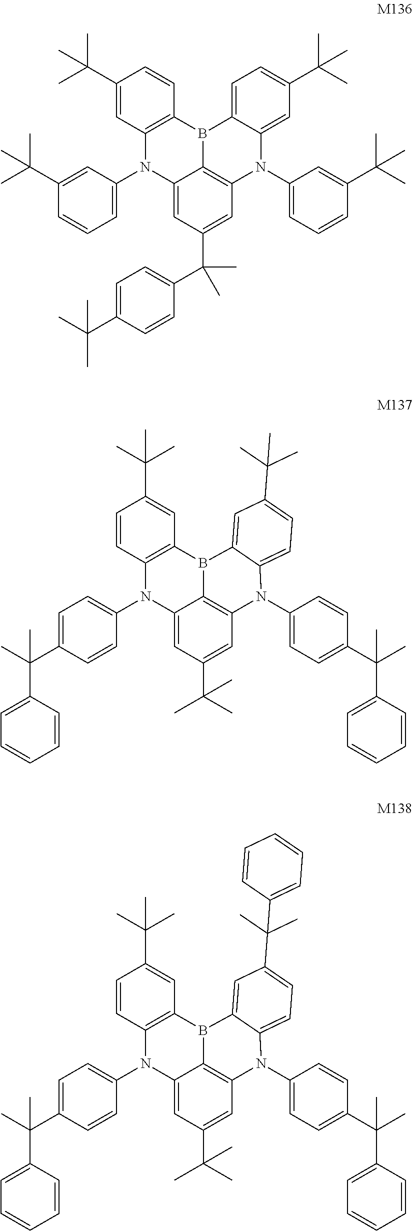

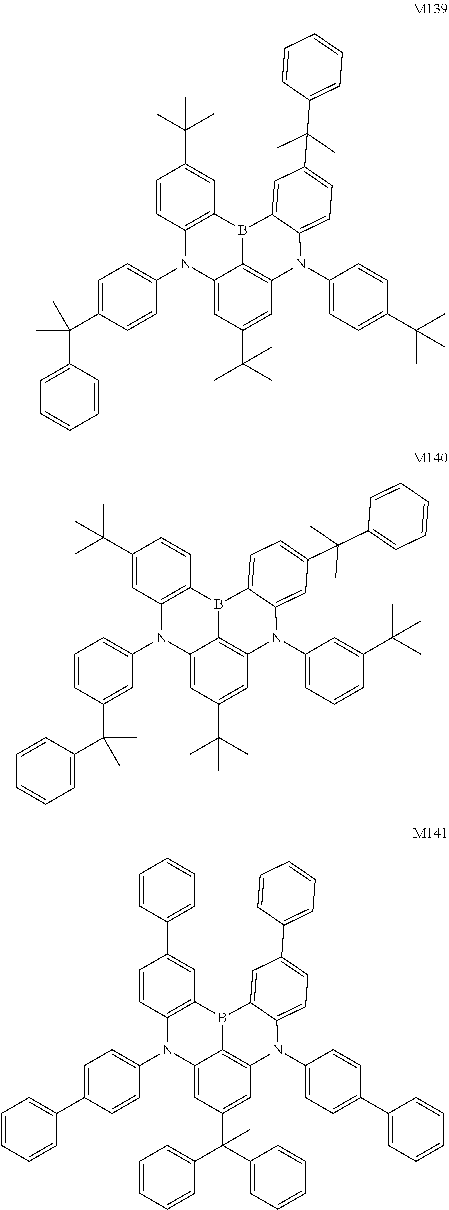 [SMILES: CC(C)(C)c1ccc(N2c3ccc(C(C)(C)c4ccccc4)cc3B3c4cc(C(C)(C)C)ccc4N(c4ccc(C(C)(C)c5ccccc5)cc4)c4cc(C(C)(C)C)cc2c43)cc1 ; CC(C)(C)c1cccc(N2c3cc(C(C)(C)c4ccccc4)ccc3B3c4ccc(C(C)(C)C)cc4N(c4cccc(C(C)(C)c5ccccc5)c4)c4cc(C(C)(C)C)cc2c43)c1 ; CC(c1ccccc1)(c1ccccc1)c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1]

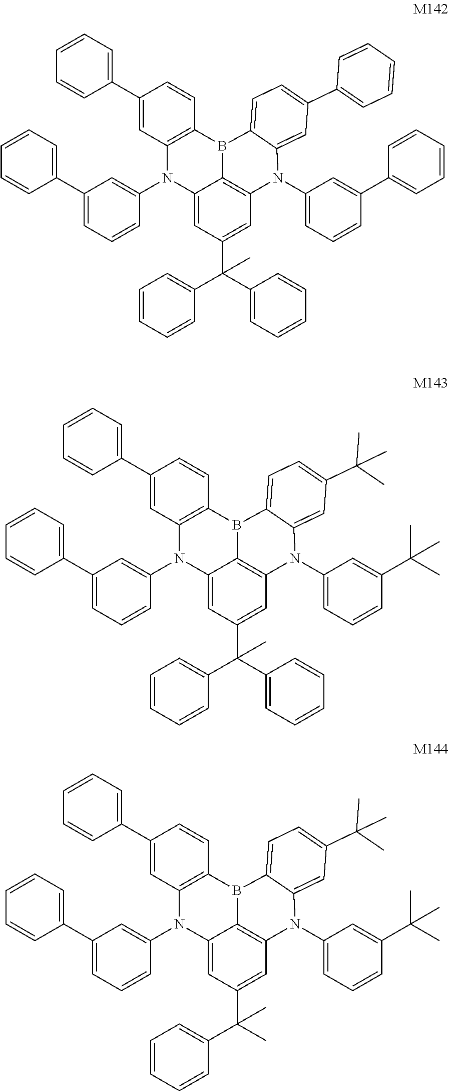 [SMILES: CC(c1ccccc1)(c1ccccc1)c1cc2c3c(c1)N(c1cccc(-c4ccccc4)c1)c1cc(-c4ccccc4)ccc1B3c1ccc(-c3ccccc3)cc1N2c1cccc(-c2ccccc2)c1 ; CC(C)(C)c1cccc(N2c3cc(C(C)(C)C)ccc3B3c4ccc(-c5ccccc5)cc4N(c4cccc(-c5ccccc5)c4)c4cc(C(C)(c5ccccc5)c5ccccc5)cc2c43)c1 ; CC(C)(C)c1cccc(N2c3cc(C(C)(C)C)ccc3B3c4ccc(-c5ccccc5)cc4N(c4cccc(-c5ccccc5)c4)c4cc(C(C)(C)c5ccccc5)cc2c43)c1]

9. The organic electroluminescent device according to claim 1, wherein the host material is selected from any one or a combination of at least two of the following compounds TDH-1 to TDH-30:

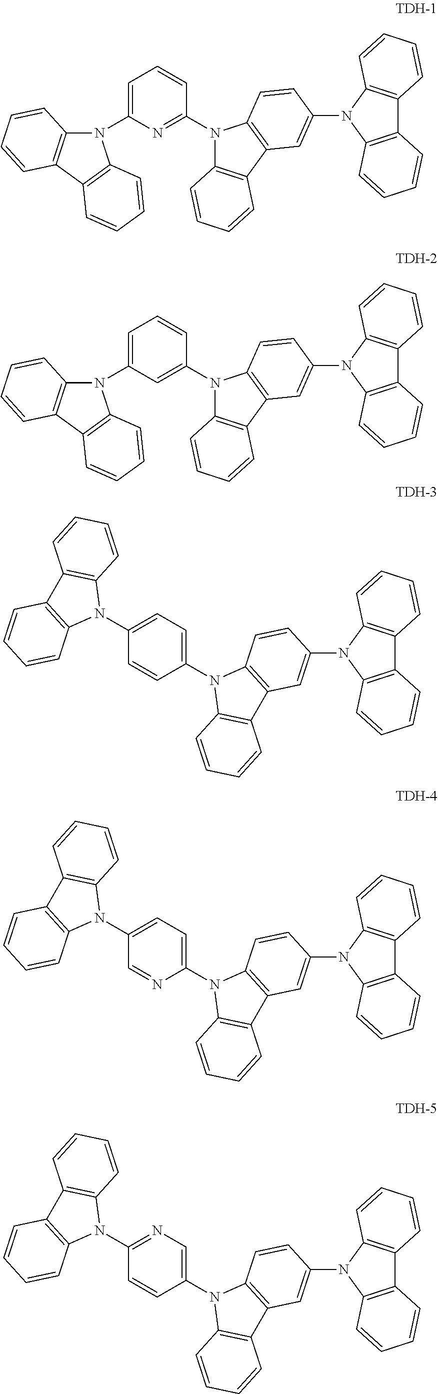

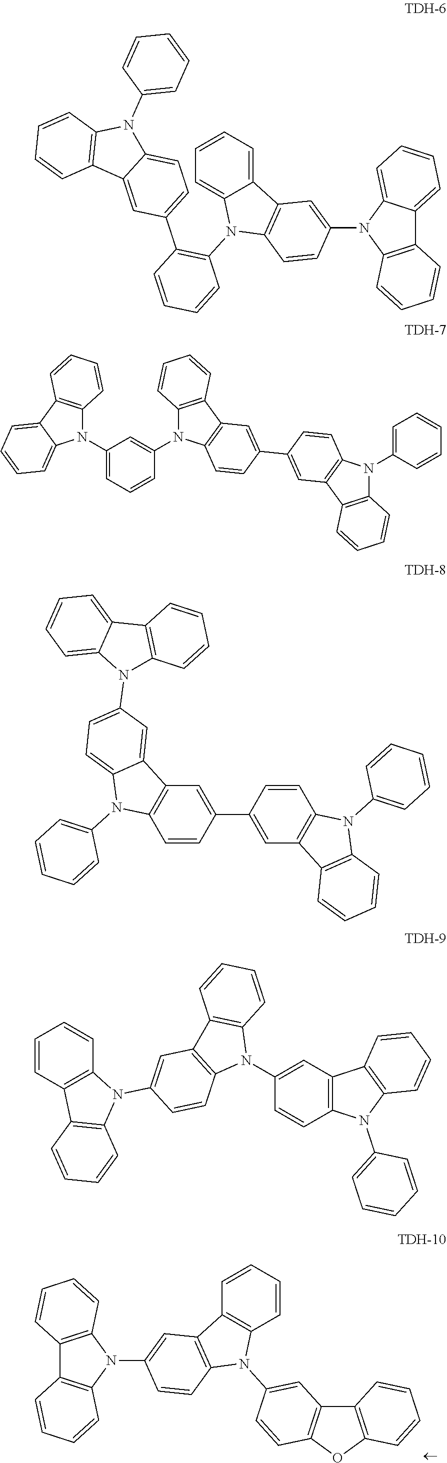

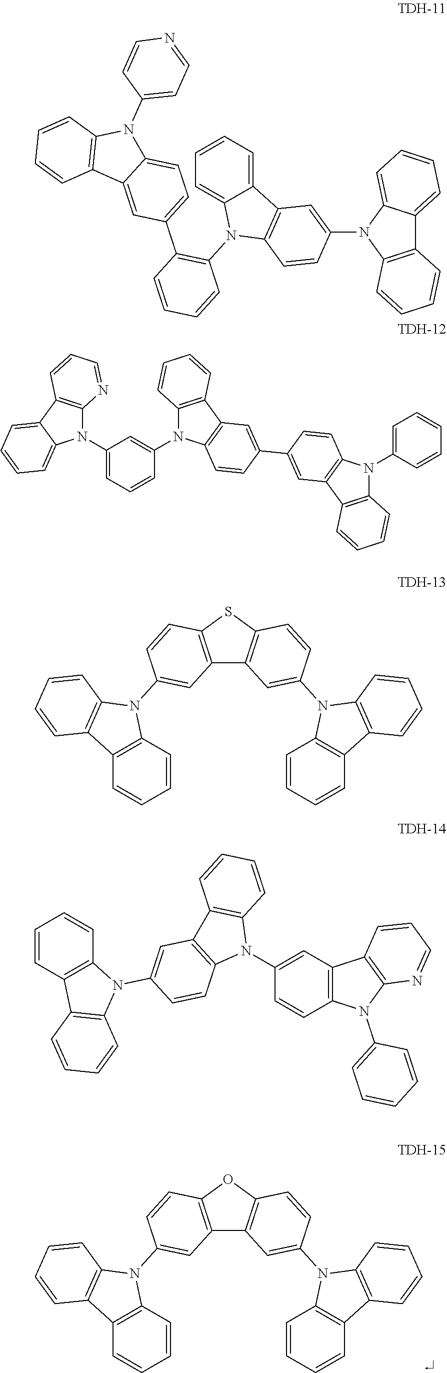

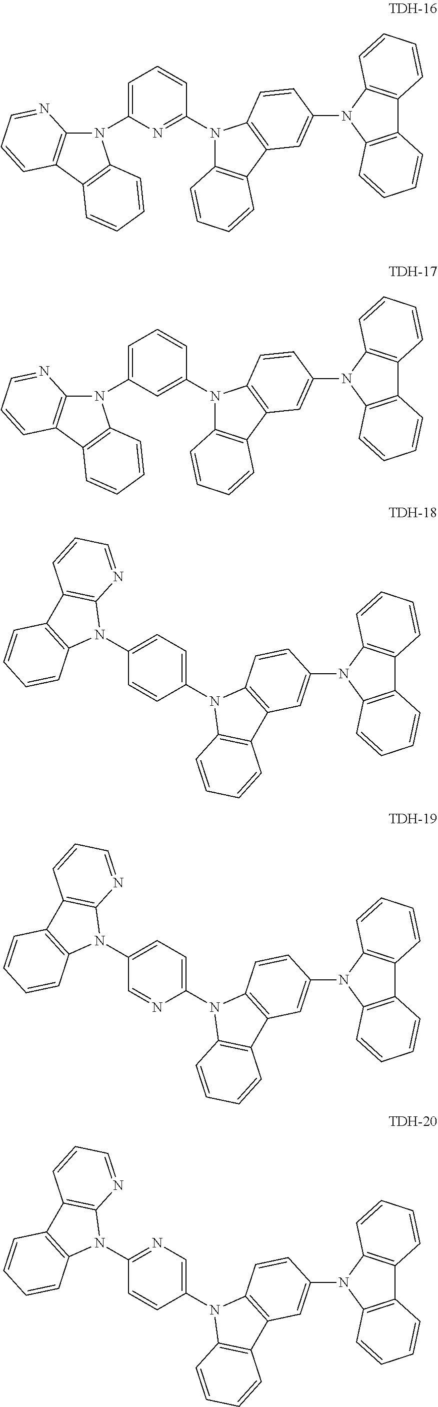 [SMILES: c1cc(-n2c3ccccc3c3cc(-n4c5ccccc5c5ccccc54)ccc32)nc(-n2c3ccccc3c3cccnc32)c1 ; c1cc(-n2c3ccccc3c3cc(-n4c5ccccc5c5ccccc54)ccc32)cc(-n2c3ccccc3c3cccnc32)c1 ; c1ccc2c(c1)c1ccccc1n2-c1ccc2c(c1)c1ccccc1n2-c1ccc(-n2c3ccccc3c3cccnc32)cc1 ; c1ccc2c(c1)c1ccccc1n2-c1ccc2c(c1)c1ccccc1n2-c1ccc(-n2c3ccccc3c3cccnc32)cn1 ; c1ccc2c(c1)c1ccccc1n2-c1ccc2c(c1)c1ccccc1n2-c1ccc(-n2c3ccccc3c3cccnc32)nc1]

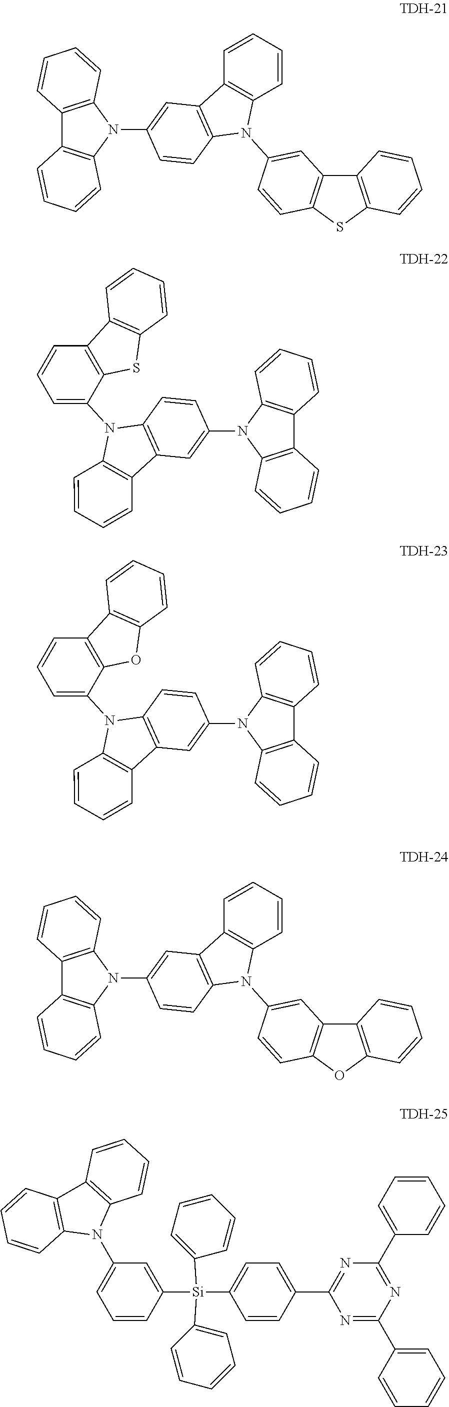

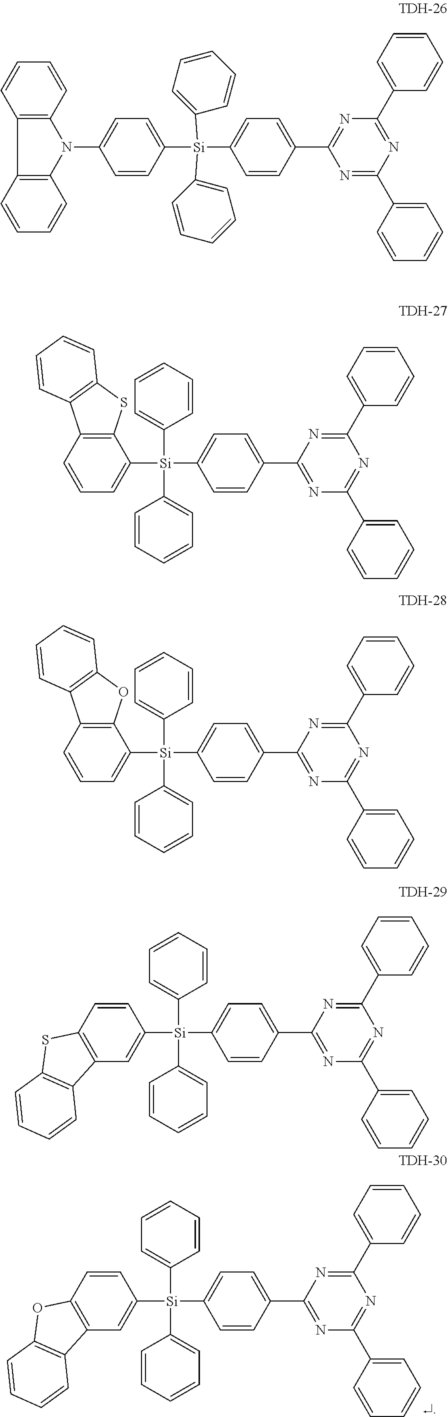

10. The organic electroluminescent device according to claim 1, wherein the TADF sensitizer is selected from any one or a combination of at least two of the following compounds TDE1 to TDE37:

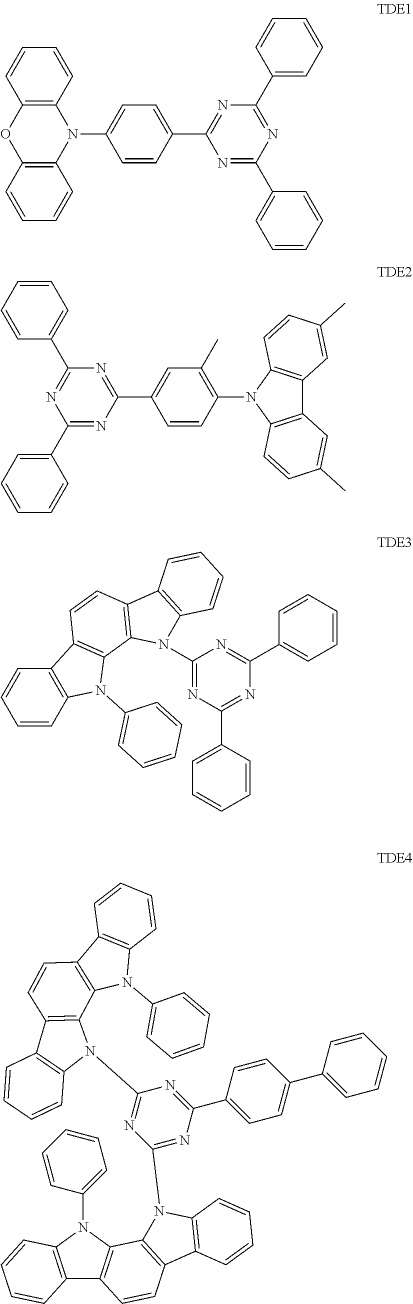 [SMILES: c1ccc(-c2nc(-c3ccccc3)nc(-c3ccc(N4c5ccccc5Oc5ccccc54)cc3)n2)cc1 ; Cc1ccc2c(c1)c1cc(C)ccc1n2-c1ccc(-c2nc(-c3ccccc3)nc(-c3ccccc3)n2)cc1C ; c1ccc(-c2nc(-c3ccccc3)nc(-n3c4ccccc4c4ccc5c6ccccc6n(-c6ccccc6)c5c43)n2)cc1 ; c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1]

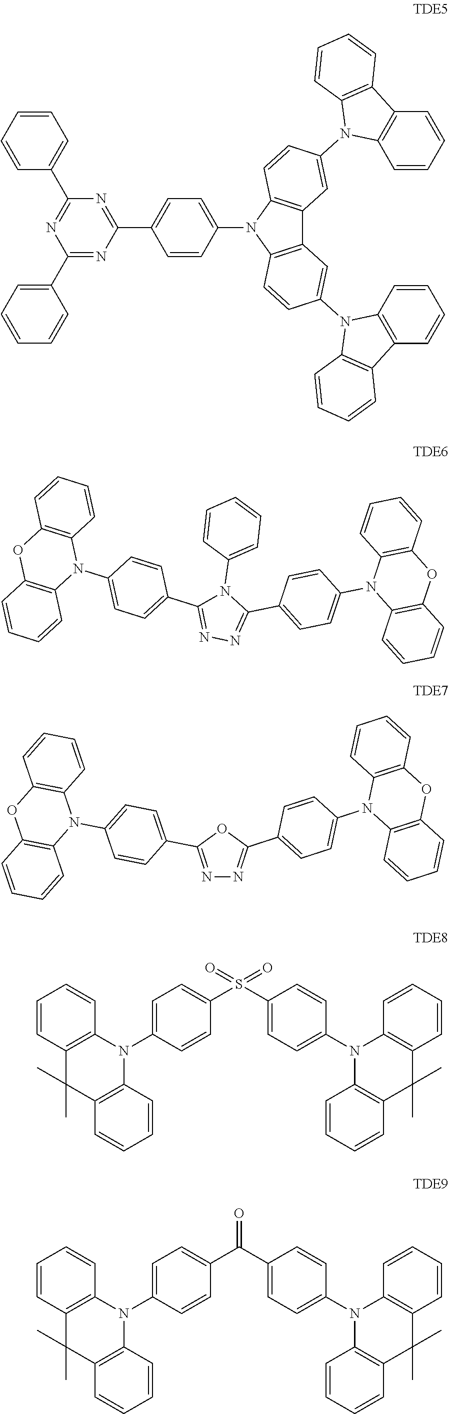 [SMILES: c1ccc(-c2nc(-c3ccccc3)nc(-c3ccc(-n4c5ccc(-n6c7ccccc7c7ccccc76)cc5c5cc(-n6c7ccccc7c7ccccc76)ccc54)cc3)n2)cc1 ; c1ccc(-n2c(-c3ccc(N4c5ccccc5Oc5ccccc54)cc3)nnc2-c2ccc(N3c4ccccc4Oc4ccccc43)cc2)cc1 ; c1ccc2c(c1)Oc1ccccc1N2c1ccc(-c2nnc(-c3ccc(N4c5ccccc5Oc5ccccc54)cc3)o2)cc1 ; CC1(C)c2ccccc2N(c2ccc(S(=O)(=O)c3ccc(N4c5ccccc5C(C)(C)c5ccccc54)cc3)cc2)c2ccccc21 ; CC1(C)c2ccccc2N(c2ccc(C(=O)c3ccc(N4c5ccccc5C(C)(C)c5ccccc54)cc3)cc2)c2ccccc21]

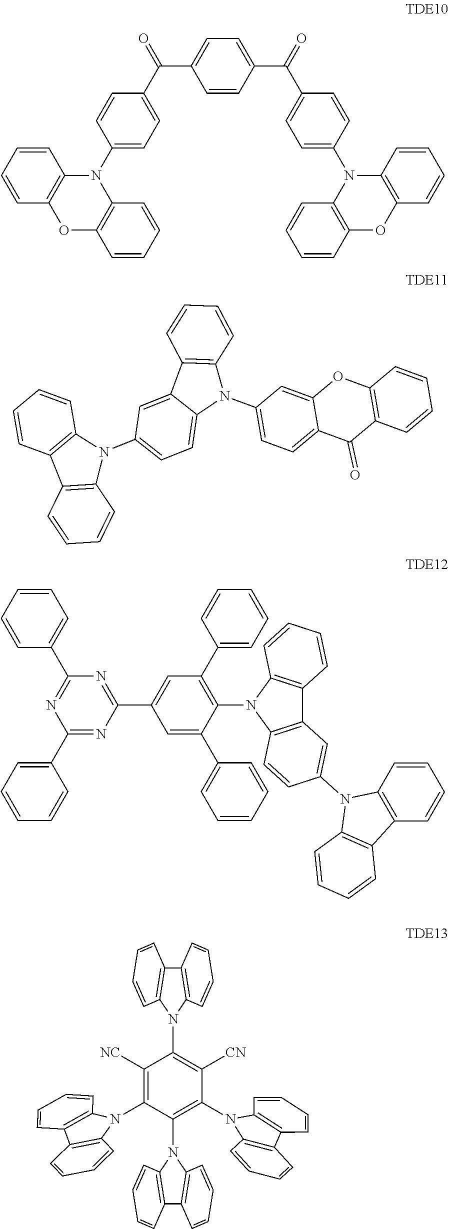 [SMILES: O=C(c1ccc(C(=O)c2ccc(N3c4ccccc4Oc4ccccc43)cc2)cc1)c1ccc(N2c3ccccc3Oc3ccccc32)cc1 ; O=c1c2ccccc2oc2cc(-n3c4ccccc4c4cc(-n5c6ccccc6c6ccccc65)ccc43)ccc12 ; c1ccc(-c2nc(-c3ccccc3)nc(-c3cc(-c4ccccc4)c(-n4c5ccccc5c5cc(-n6c7ccccc7c7ccccc76)ccc54)c(-c4ccccc4)c3)n2)cc1 ; N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21]

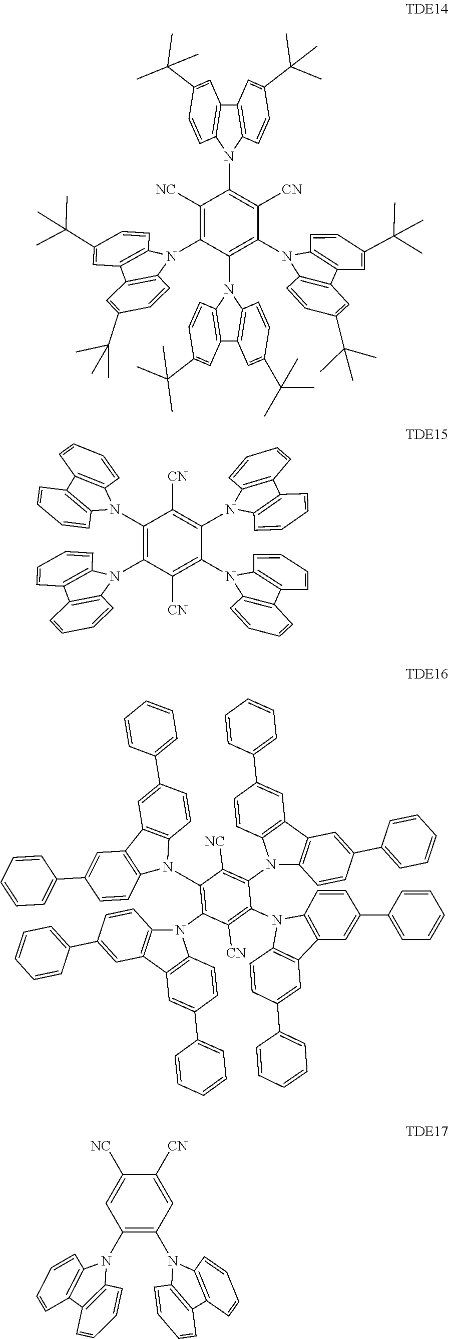

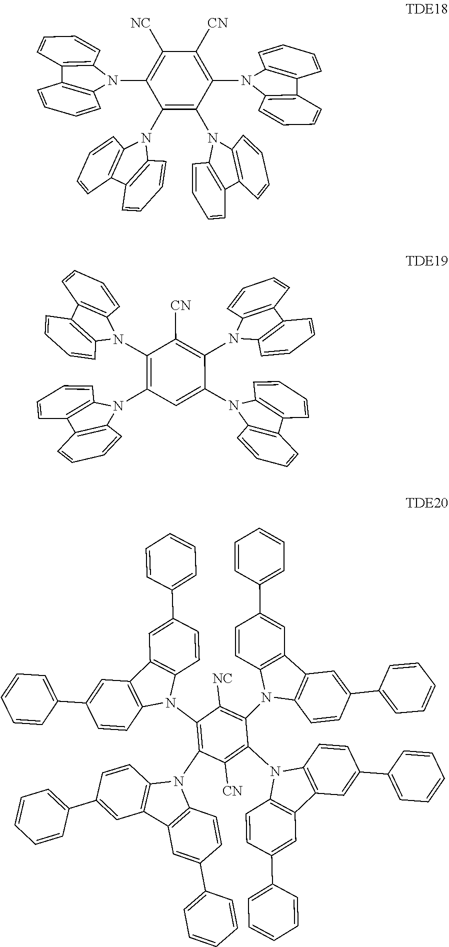

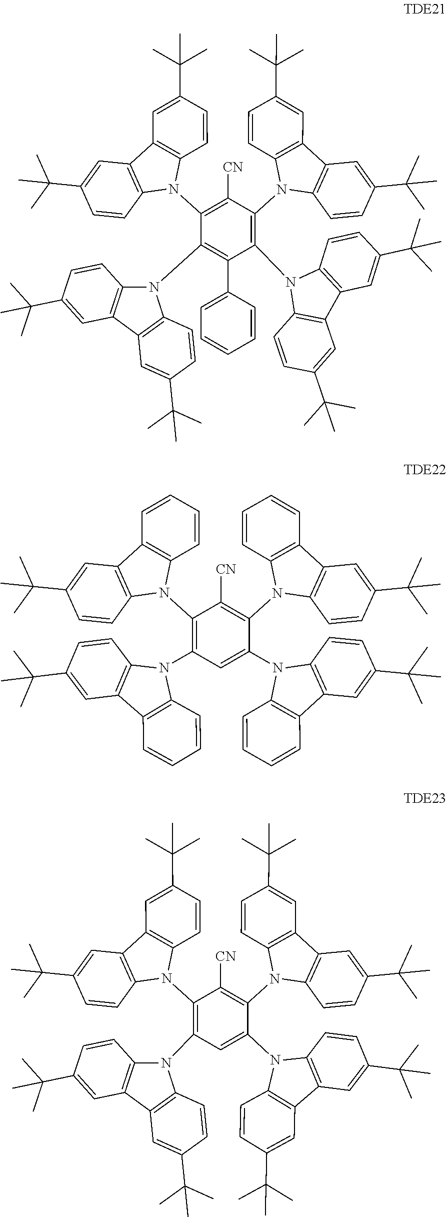

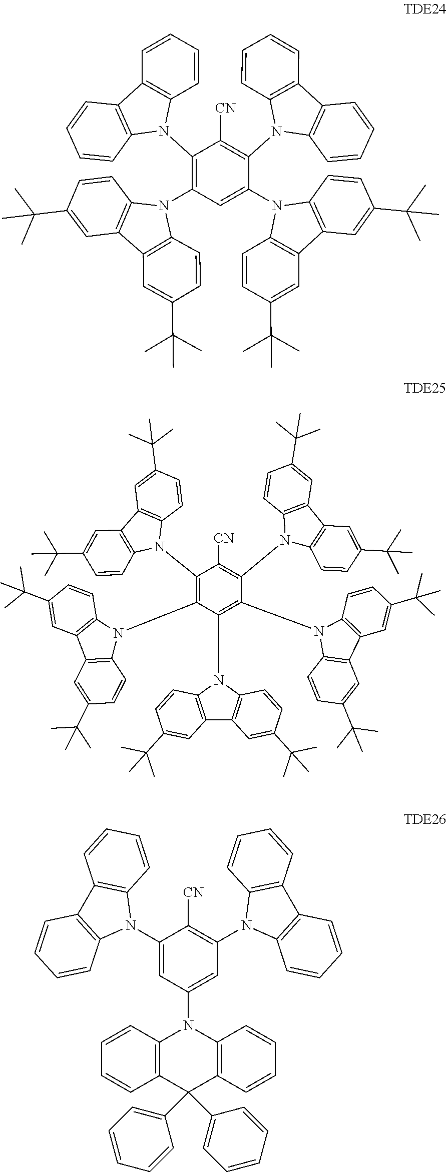

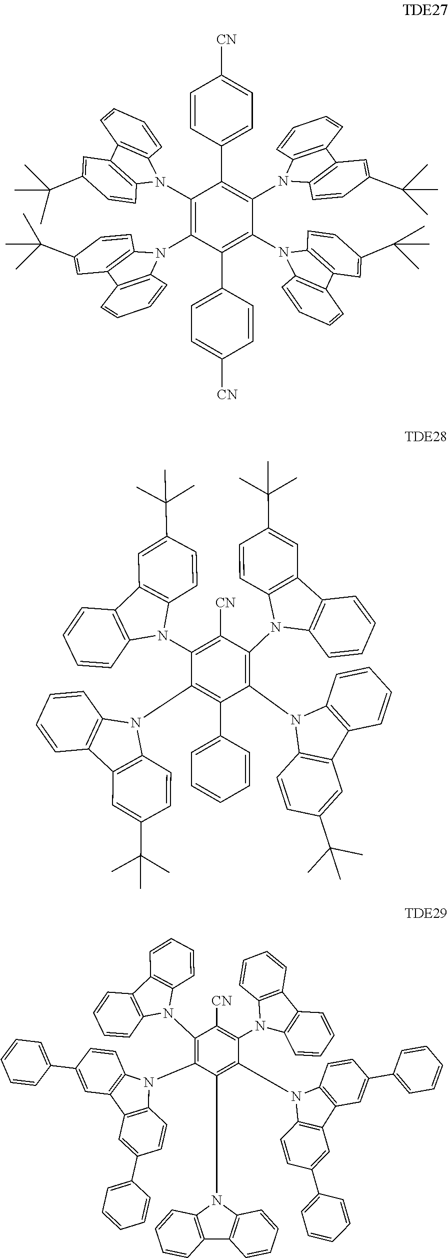

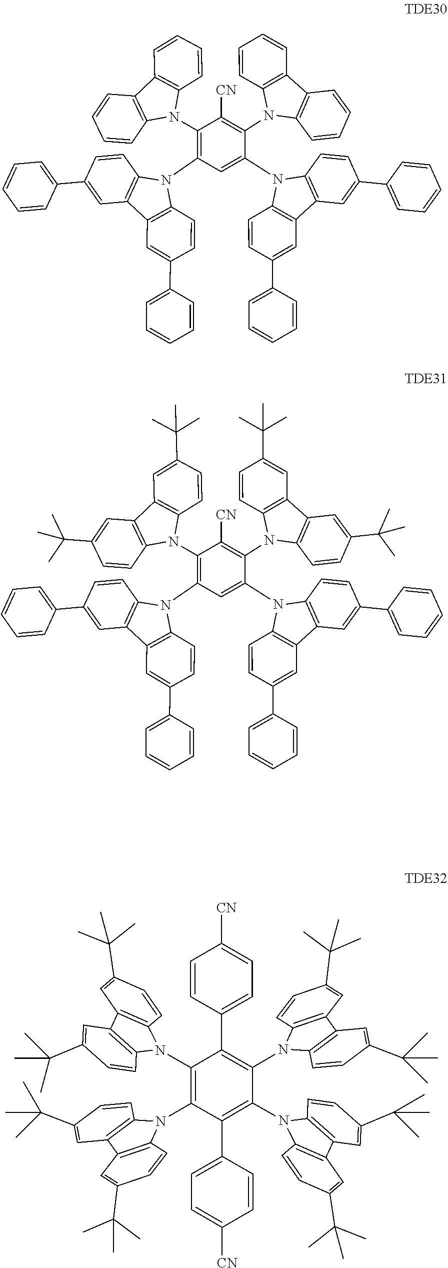

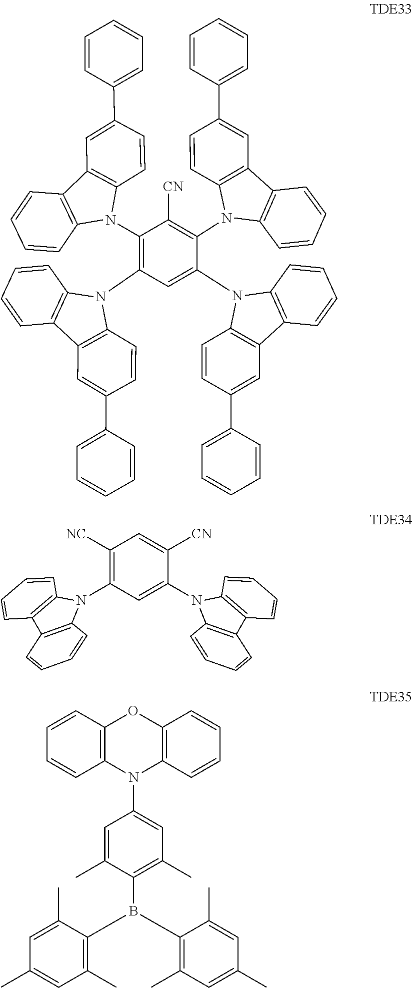

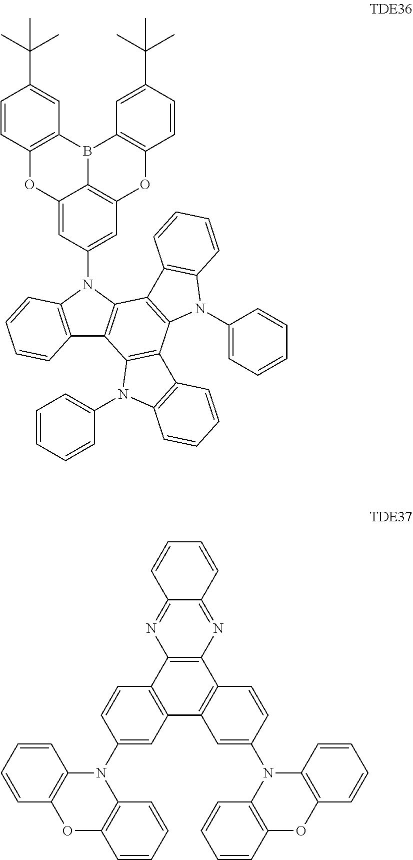 [SMILES: CC(C)(C)c1ccc2c(c1)B1c3cc(C(C)(C)C)ccc3Oc3cc(-n4c5ccccc5c5c6c(c7ccccc7n6-c6ccccc6)c6c(c7ccccc7n6-c6ccccc6)c54)cc(c31)O2 ; c1ccc2c(c1)Oc1ccccc1N2c1ccc2c(c1)c1cc(N3c4ccccc4Oc4ccccc43)ccc1c1nc3ccccc3nc21]

11. The organic electroluminescent device according to claim 1, wherein a mass of the fluorescent dye accounts for 0.1% to 10% of a total mass of the EML.

12. The organic electroluminescent device according to claim 1, wherein the organic layer further comprises any one or a combination of at least two of a hole injection layer (HIL), a hole transport layer (HTL), a hole blocking layer (HBL), an electron blocking layer (EBL), an electron transport layer (ETL) or an electron injection layer (EIL).

13. The organic electroluminescent device according to claim 1, wherein in Formula (1), when X¹ is selected from O or S, m is 0; and when X² is selected from O or S, n is 0.

14. The organic electroluminescent device according to claim 1, wherein the substituted or unsubstituted C₆ to C₃₀ aryl is a group selected from the group consisting of phenyl, biphenyl, terphenyl, naphthyl, anthryl, phenanthryl, indenyl, fluorenyl and a derivative thereof, fluoranthenyl, triphenylene, pyrenyl, perylenyl, chrysenyl and naphthacenyl.

15. The organic electroluminescent device according to claim 14, wherein the biphenyl is selected from 2-biphenyl, 3-biphenyl and 4-biphenyl; terphenyl comprises p-terphenyl-4-yl, p-terphenyl-3-yl, p-terphenyl-2-yl, m-terphenyl-4-yl, m-terphenyl-3-yl and m-terphenyl-2-yl; naphthyl comprises 1-naphthyl and 2-naphthyl; anthryl is selected from 1-anthryl, 2-anthryl and 9-anthryl; fluorenyl is selected from 1-fluorenyl, 2-fluorenyl, 3-fluorenyl, 4-fluorenyl and 9-fluorenyl; the fluorenyl derivative is selected from 9,9′-dimethylfluorene, 9,9′-spirobifluorene and benzofluorene; pyrenyl is selected from 1-pyrenyl, 2-pyrenyl and 4-pyrenyl; and naphthacenyl is selected from 1-naphthacenyl, 2-naphthacenyl and 9-naphthacenyl.

16. The organic electroluminescent device according to claim 1, wherein the substituted or unsubstituted C₃ to C₃₀ heteroaryl comprises nitrogen-containing heteroaryl, oxygen-containing heteroaryl, sulfur-containing heteroaryl.

17. The organic electroluminescent device according to claim 1, wherein the substituted or unsubstituted C₃ to C₃₀ heteroaryl comprises furanyl, thienyl, pyrrolyl, benzofuranyl, benzothienyl, isobenzofuranyl, indolyl, dibenzofuranyl, dibenzothienyl and carbazolyl and a derivative.

18. The organic electroluminescent device according to claim 17, wherein the carbazolyl derivative comprises 9-phenylcarbazole, 9-naphthylcarbazolebenzocarbazole, dibenzocarbazole or indolocarbazole.

19. The organic electroluminescent device according to claim 1, wherein the C₁ to C₁₀ chain alkyl comprises methyl, ethyl, n-propyl, n-butyl, n-hexyl, n-octyl, isopropyl, isobutyl and tert-butyl.

20. A display apparatus, comprising the organic electroluminescent device according to claim 1.
